(19) United States
(12) Patent Application Publication
(10) Pub. No.: US 2023/0392292 A1
(43) Pub. Date: Dec. 7, 2023

(54) MULTI-LAYER STACKS OF 2D MATERIALS AND/OR OTHER LAYERS AND RELATED SYSTEMS AND METHODS

(71) Applicant: The University of Chicago, Chicago, IL (US)

(72) Inventors: Jiwoong Park, Chicago, IL (US); Andrew Mannix, Palo Alto, CA (US); Andrew Ye, Chicago, IL (US)

(73) Assignee: The University of Chicago, Chicago, IL (US)

(21) Appl. No.: 18/071,339

(22) Filed: Nov. 29, 2022

Related U.S. Application Data
(60) Provisional application No. 63/284,541, filed on Nov. 30, 2021.

(51) Int. Cl. C30B 29/68; C30B 23/02; C30B 29/46; C30B 29/40; C30B 29/02; C30B 25/02

(52) U.S. Cl. CPC C30B 29/68; C30B 23/02; C30B 29/46; C30B 29/403; C30B 29/02; C30B 25/02

(57) ABSTRACT

Multi-layer materials and related systems and methods are generally described.

### RELATED APPLICATIONS

This application claims priority under 35 U.S.C. § 119(e) to U.S. Provisional Patent Application No. 63/284,541, filed Nov. 30, 2021, and entitled “Multi-Layer Stacks of 2D Materials and/or Other Layers and Related Systems and Methods,” which is incorporated herein by reference in its entirety for all purposes.

### GOVERNMENT SPONSORSHIP

This invention was made with government support under grant numbers 2025633, 2011854, and 2039380 awarded by the National Science Foundation, and grant number FA9550-18-1-0480 awarded by the Air Force office of Scientific Research. The government has certain rights in this invention.

### TECHNICAL FIELD

Multi-layer materials and related systems and methods are generally described.

### SUMMARY

The present disclosure is related to multi-layer materials and related systems and methods. The subject matter of the present disclosure involves, in some cases, interrelated products, alternative solutions to a particular problem, and/or a plurality of different uses of one or more systems and/or articles.

In one aspect, multi-layer stacks are provided. In some embodiments, the multi-layer stack comprises a first crystalline layer; a second crystalline layer; and at least eight intermediate crystalline layers between the first crystalline layer and the second crystalline layer; wherein: the first crystalline layer is substantially non-covalently associated with the intermediate crystalline layer in the stack that is adjacent to the first crystalline layer; the second crystalline layer is substantially non-covalently associated with the crystalline intermediate layer in the stack that is adjacent to the second crystalline layer; and each intermediate crystalline layer is substantially non-covalently associated with the two crystalline layers of the stack that are adjacent to that intermediate crystalline layer.

In certain aspects, methods of making multi-layer stacks are provided. In some embodiments, a method of making a multi-layer stack using an article comprising an adhesion region, an article substrate, and a release region between the adhesion region and the article substrate is provided, the method comprising: establishing contact between the adhesion region of the article and a first crystalline layer such that the first crystalline layer is adhered to the adhesion region of the article; subsequently establishing contact between the first crystalline layer and a second crystalline layer while the first crystalline layer remains adhered to the article, such that the second crystalline layer is adhered to the first crystalline layer; subsequently establishing contact between the second crystalline layer and a third crystalline layer while the first and second crystalline layers remain adhered to the article, such that the third crystalline layer is adhered to the second crystalline layer; and subsequently altering the release region such that separation is achieved between the article substrate and the first, second, and third crystalline layers.

Other advantages and novel features of the present disclosure will become apparent from the following detailed description of various non-limiting embodiments of the disclosure when considered in conjunction with the accompanying figures. In cases where the present specification and a document incorporated by reference include conflicting and/or inconsistent disclosure, the present specification shall control.

### BRIEF DESCRIPTION OF THE DRAWINGS

Non-limiting embodiments of the present disclosure will be described by way of example with reference to the accompanying figures, which are schematic and are not intended to be drawn to scale unless otherwise indicated. In the figures, each identical or nearly identical component illustrated is typically represented by a single numeral. For purposes of clarity, not every component is labeled in every figure, nor is every component of each embodiment of the disclosure shown where illustration is not necessary to allow those of ordinary skill in the art to understand the disclosure. In the figures:

FIG. 1 is a perspective view schematic illustration of a layer, in accordance with certain embodiments.

FIG. 2 is, in accordance with certain embodiments, a perspective view schematic illustration of an assembly article comprising an article substrate, an adhesive layer, and a release layer between the article substrate and the adhesive layer.

FIGS. 3A-3O are cross-sectional schematic illustrations showing a method for assembling a multi-layer stack using the assembly article illustrated in FIG. 2, according to some embodiments.

FIG. 4A is a cross-sectional schematic illustration of a multi-layer stack comprising a first layer, a second layer, and plurality of intermediate layers in between the first layer and the second layer, according to some embodiments.

FIG. 4B is a cross-sectional schematic illustration of a multi-layer stack including a first layer, a second layer, and eight intermediate layers between the first layer and the second layer, according to some embodiments.

FIG. 4C is a cross-sectional schematic illustration of a multi-layer stack including a first layer, a second layer, and twenty-three intermediate layers between the first layer and the second layer, according to some embodiments.

FIG. 4D is a top view schematic illustration of a multi-layer stack in which layers have been rotated such that their edges are arranged at a fixed angle relative to one another, according to some embodiments.

FIG. 4E is a cross-sectional schematic illustration of a multi-layer stack including a first layer, a second layer, and a plurality of intermediate layers between the first layer and the second layer, wherein at least some of the intermediate layers have facial surface areas that are smaller than a facial surface area of the largest layer of the multi-layer stack, according to some embodiments.

FIG. 4F is a cross-sectional schematic illustration of a multi-layer stack including a first layer, a second layer, and a plurality of intermediate layers between the first layer and the second layer, wherein at least some of the intermediate layers have facial surface areas that are larger than the facial surface areas of the first and second layers of the multi-layer stack, according to some embodiments.

FIG. 5A is a perspective view schematic illustration of a patterning substrate as it patterns a surface of a layer, according to some embodiments.

FIG. 5B is, in accordance with some embodiments, a bottom view schematic illustration of a patterning substrate illustrating the distribution of adhesive over the bottom surface of the patterning substrate.

FIGS. 6A-6C are schematic illustrations of a robotic 4D layer assembly and images of the resulting multi-layer stacks, in accordance with certain embodiments. FIG. 6A shows a 4D layer assembly concept diagram. FIG. 6B shows the production of multi-layer stacks by (i) wafer-scale growth; (ii) layer patterning to produce multiple, smaller layers (also referred to herein as “pixels”); (iii) and automated layer assembly by a robotic instrument. FIG. 6C shows corresponding micrographs of vacuum assembly robot-manufactured Van der Waals (vdW) solids demonstrating layer number, composition, lateral position, and interlayer twist angle control (all scale bars 50 micrometers).

FIGS. 7A-7E are, in accordance with certain embodiments, schematic illustrations showing automated vacuum assembly of van der Waals heterostructures and images of the resulting heterostructures. FIG. 7A shows a diagram of a Vacuum Assembly Robot (VAR) for vdW heterostructure fabrication. FIG. 7B shows a schematic of a multilayer article (also referred to herein as a “stamp”) comprising an adhesion region, where the multilayer article mediates programmed adhesion and deposition via thermal and/or UV light activation of the release layer to generate rapid decomposition. Details of stamp polymers are included in Example 1 (Methods). FIG. 7C shows a process flow chart demonstrating steps for (i) assembly of heterostructures and (ii) deposition of heterostructures onto a receiving substrate. FIG. 7D shows a schematic of template strip lithography (TSL) process. FIG. 7E shows stitched optical micrographs from a 13×13 mm² chip of square, rectangle, triangle, and tiled WS₂ layers produced by TSL, scale bar 1 mm, in which the inset is an optical micrograph of an individual square layer (scale bar 50 micrometers).

FIGS. 8A-8H are, in accordance with certain embodiments, optical images and plots characterizing N-layer stacked MoS₂. FIG. 8A shows a white light optical micrograph of one-layer (1L) through 16-layer (16L) MoS₂ grid structures (scale bar 50 micrometers) placed onto a uniform background monolayer of MoS₂, such that different spatial regions of the structure have well-defined MoS₂ thicknesses between 1 and 17 layers. FIG. 8B shows a schematic of structured layer assembly to realize a 16-tile grid structure. FIG. 8C shows in situ micrographs of designed heterostructure fabrication, where images were taken when the stamp was in contact with substrate. FIG. 8D shows cross-sectional STEM images of 4L, 8L, and 15L MoS₂ extracted from the design shown in FIG. 8B, demonstrating atomically-resolved thickness control (all scale bars 10 nm).

FIG. 8E shows hyperspectral microscope transmission and reflection images near the onset of A-exciton absorption (680 nm), demonstrating uniformly increasing contrast for individual layers. FIG. 8F shows absorbance spectra acquired from FIG. 8A via hyperspectral microscopy. FIG. 8G shows plotted curve fits of excitonic peak positions from optical spectroscopy data (open symbols PL, closed symbols absorbance) with bulk 2H-MoS₂ absorbance peaks extracted from literature. FIG. 8H shows photoluminescence spectra of 1L through 17L MoS₂ acquired from FIG. 8A.

FIGS. 9A-9C show, in accordance with certain embodiments, reconstruction in twisted 4-layer WS₂. FIG. 9A shows a TEM diffraction pattern acquired from a 4L structure of WS₂ with 4.2°±0.2° twist angle between adjacent layers (with the inset being a schematic showing method of twisted heterostructure manufacture from single crystal of monolayer WS₂, with optical micrograph of single-crystal WS₂ triangle (scale bar 100 micrometers)). FIG. 9B shows magnified views of superlattice peaks for (i) first-, (ii) second-, and (iii) third-order sets of diffraction spots, showing prominent satellite peaks associated with interlayer atomic reconstruction. FIG. 9C shows a dark-field TEM image with the objective aperture placed over a set of second-order Bragg peaks, showing evidence of atomic reconstruction (scale bar 40 nm) with larger “fishnet” domains attributed to the ˜4° twist angle between the innermost layers, and high frequency stripes corresponding to the ˜12° twist angle between the outermost layers.

FIGS. 10A-10C are related, in accordance with certain embodiments, to exfoliated heterostructure fabrication and cryogenic spectroscopy benchmarks. FIG. 10A shows a brightfield reflection optical micrograph with differential interference contrast of a stacked hBN/WSe₂/hBN exfoliation-based heterostructure, with individual layers accented for clarity. FIG. 10B shows an AFM topograph acquired in the dashed-line box in FIG. 10A, showing a monolayer region of WSe₂ prior to heterostructure assembly. FIG. 10C shows photoluminescence (PL) spectra acquired from a monolayer region at 7 K, showing neutral and charged exciton resonances. The left inset in FIG. 10C shows the result of Lorentzian curve fitting for the neutral exciton resonance in PL spectra for VAR (left curve) and manual (right curve) stacked samples. These results show fitted full widths at half maximum of 5.5 meV for the VAR sample at 7 K, versus 4.4 meV for the manual sample at 4 K. The right inset in FIG. 10C shows a differential reflectance spectrum acquired with the VAR-sample PL spectrum.

FIG. 11 shows, in accordance with certain embodiments, a photograph of the Vacuum Assembly Robot (left-hand side) and a schematic illustration of the internals of the VAR (right-hand side). The two actuation stages in the right-side schematic are located inside the vacuum chamber and the camera is located outside the chamber, looking through the top viewport.

FIGS. 12A-12C show, in accordance with certain embodiments, representative in situ optical microscope images of a polymer stamp before and after contact with a 100×100 micrometer monolayer sample. The color contrast between FIG. 12A (in which the stamp is above the layer surface), FIG. 12B (in which the stamp is in contact with the layer surface), and FIG. 12C (in which the layer has been lifted from the underlying substrate) can be used to determine the status of the contact between the stamp and the layer and between the layer and the underlying substrate.

FIGS. 13A-13D are optical images showing the pick-up of incrementally larger Au layers, and an in situ view of the assembly of a staircase-like gold structure from 50 nm thick lithographically-patterned Au layers. FIG. 13A shows the pickup of the first layer, FIG. 13B shows the pickup of the second layer (to form a two-layer stack), FIG. 13C shows the pickup of the third layer, and FIG. 13D shows the pickup of the fourth layer. Images were taken when the stamp was in contact with the substrate. It is likely that cold-welding is the primary source of adhesion between Au layers.

FIGS. 14A-14B, in accordance with certain embodiments, show the pickup and flatness of thin film samples on a stamp. FIG. 14A shows a brightfield optical micrograph of 31-nm thick hBN flake after being picked up by a stamp. FIG. 14B shows an AFM topography image obtained from region indicated in FIG. 14A, showing a clean and featureless surface.

FIG. 15 is an image of an 80-layer MoS₂ structure. This was assembled operator-free overnight, highlighting the reliability and autonomy of the robotic 4D layer stacking system. The scale bar is 50 micrometers.

FIGS. 16A-16B are images showing the yield of TSL patterning process, in accordance with certain embodiments. FIG. 16A shows a brightfield optical micrograph of monolayer MoS₂ patterned by TSL into (75 micrometers)² square “pixel” layers on a 300 micrometers by 300 micrometers grid. Yield is calculated as the ratio between usable layers versus the total number of layers in the accessible region (enclosed by the dotted white line). From this image, 8 bad layers are observed out of 690, indicating 99% yield. FIG. 16B shows a magnified region demonstrating layer shapes.

FIGS. 17A-17E are, in accordance with some embodiments, images showing the topography of predecessor monolayers. FIG. 17A shows an AFM topography image of an entirety of a (50 micrometers)² square of MoS₂, patterned by TSL, on SiO₂. FIGS. 17B, 17C, and 17E are higher resolution AFM topography images of a slightly overgrown MoS₂ bilayer region nucleated near grain boundaries from in a TSL patterned sample and unpatterned sample, respectively. FIG. 17D shows a Line profile of monolayer step thickness between a patterned square and substrate (bottom curve), and a bilayer region from FIG. 17B (top curve) and from FIG. 17C (middle curve). FIG. 17E shows an AFM topography image of a highly monolayer unpatterned region.

FIGS. 18A-18D show, in accordance with certain embodiments, Laser Confocal Scanning Microscopy (LCSM) images of VAR Assembled MoS₂ Stacks. FIG. 18A shows a white light micrograph of 1-, 2-, and 3-layer thick stacks of MoS₂ adjacently placed on onto MoS₂ covered SiO₂ (300 nm)/Si (labeled as BG). Stacks are made from (50 micrometers)² squares patterned by TSL. FIG. 18B shows a higher magnification white light micrograph of each individual stack. FIG. 18C shows LCSM intensity of each individual stack, all displayed with the same color scale. The inset is a magnified view of the box in the middle image, which shows inhomogeneities characteristic of 2L+BG and 3L+BG. FIG. 18D shows histograms of confocal intensity for each stack, normalized to their max values. The standard deviation of the signal increased with layer count as imperfections in the surface increase with layer count. However, the full width at half maximum indicates that the majority of the area within samples remain uniform, as the inhomogeneity manifests as a small tail on the left half of the histogram.

FIGS. 19A-19F show, in accordance with some embodiments, Raman mapping of a MoS₂/WSe₂ Heterostructure. FIG. 19A shows an assembly schematic of layer stacking sequence. FIG. 19B shows a white-light micrograph of assembled structure.

FIG. 19C shows a top-down schematic of compositions in different spatial regions of this vdW solid, where A is MoS₂ and B is WSe₂. FIGS. 19C-19F show Raman mapping acquired over the entire heterostructure (120 micrometers)² and in the corner of the sample (light grey outline, (50 micrometers)²), showing integrated intensity for the WSe₂ (FIG. 19D), MoS₂ (FIG. 19E), and the combined overlay (FIG. 19F). The left inset shows Raman mapping of MoS₂ and WSe₂ source layers, respectively. All Raman map color scales are normalized to values [0,1] relative to the maximum intensity within each individual map. A minor effect was noted from beam drift through the duration of the mapping acquisition.

FIG. 20 shows, in accordance with some embodiments, Transfer Matrix Method Transmittance and Reflectance Optical Response of a 16L MoS₂ on 330-micrometer sapphire. Using slightly modified values of the optical constants of a monolayer MoS₂ film (as described in the Methods section of Example 1) in an N-layer transfer matrix extrapolation calculation, the experimental measurements of reflectance and transmittance can be closely matched.

FIG. 21 shows, in accordance with certain embodiments, a plot of integrated PL peak area vs. layer number for MoS₂ 16L stacked sample. The integrated PL peak area is directly proportional to the quantum emission efficiency; the decrease in the A peak from 1 layer to 2 layer is in line with the expected direct-indirect optical transition between monolayer to multilayer TMDs. The deviation for the 6-layer data points is due to an outlier spectrum with ˜25% higher PL intensity.

FIGS. 22A-22C are images characterizing monolayer WS₂. FIG. 22A shows a real space TEM overview of the monolayer single crystal triangle, outlined by the dashed triangle. FIG. 22B shows a real space TEM taken at the square outline in FIG. 22A. FIG. 22C shows a SAED pattern of monolayer WS₂ suspended over a hole, acquired using the selected area aperture from the region outlined in the circle of FIG. 22B. From this pattern and the 21 other diffraction patterns acquired from this triangle, the triangle island sample is uniformly single crystalline over (10-100 micrometers)² of area.

FIG. 23 is, in accordance with some embodiments, a plot showing open-loop calibration of a VAR rotation actuator. There is a linear relationship between the number steps taken by the integrated AG-PR100V6 piezo rotation actuator and the angle by which the actuator rotates. However, the actuator exhibits deviation in rotation amount on the order of 0.2° to 0.3°, consistent with the order of angular fluctuation between the three angles in the twisted 4L WS₂ structure. This could be improved by adding closed-loop feedback into the current rotation actuator, or by replacing it with an encoded actuator.

FIG. 24 is, in accordance with some embodiments, a multi-slice quantum mechanical electron diffraction simulation of a rigid 4.2° twisted 4L WS₂ lattice. Relative intensity percentage lower than 1% is chosen to be below the threshold of detector visibility.

FIGS. 25A-25D are, in accordance with some embodiments, images and a plot related to intensity line cuts between the main and satellite peaks of the 4.2°±0.20 twisted 4L WS₂ SAED pattern. The first (FIG. 25A), second (FIG. 25B), and third (FIG. 25C) Bragg clusters show similar relative intensities (FIG. 25D) between the main peaks and the first satellite peaks, between 1-2%.

FIGS. 26A-26B show, in accordance with certain embodiments, thermomechanical effects upon 2D-stamp interactions. FIG. 26A shows a schematic plot of temperature versus time for constant temperature pickup of a monolayer of MoS₂, with glass transitions T_{g} for polymer layer C (Adhesion, typically PBzMA) and layer B (Release, typically PCPC with PAG added). The T_{g} for layer A (Support, typically LOR10B, not shown on plot) at ˜180° C. is much larger than the operation temperature for stacking (left). Shown on right is an AFM topography image for monolayer MoS₂ picked up at constant temperature and adhered to stamp. The inset shows the experimental setup. FIG. 26B shows temperature versus time for an actively cooled sample (left). Shown on right is an AFM topography image for monolayer MoS₂ on stamp following pickup via active thermoelectric cooler-assisted temperature cycling (contact at 145° C., cooling to 80° C. before lifting), showing suppressed wrinkle formation due to decreased free-space thermal contraction.

FIGS. 27A-27C are, in accordance with some embodiments, brightfield optical micrographs of parallel assembly of multiple MoS₂ layers using an 800-micrometer diameter stamp. Images are taken from the VAR in situ microscope before contact (FIG. 27A), while in contact (FIG. 27B), and after being lifted up (FIG. 27C).

### DETAILED DESCRIPTION

Van der Waals (vdW) solids can be engineered with atomically-precise vertical composition through the assembly of layered 2D materials (2DMs). In doing so, the structure-defined interlayer interactions result in novel phenomena, including superconductivity, exciton bands, and 2D Hubbard physics. Such phenomena have been observed in vdW heterostructures and moiré superlattices produced using an artisanal method of assembling micromechanically-exfoliated flakes. However, further engineering and application of vdW solids requires a scalable and rapid production method to precisely design and control composition and structure over all three spatial dimensions (x, y, z) and interlayer rotation (θ).

One aspect of the present disclosure is related to methods of making multi-layer stacks. In some embodiments, the methods use a multi-region assembly article that includes an article substrate, an adhesion region, and a release region between the article substrate and the adhesion region. The assembly article can be used, for example, as a stamp, whereby the adhesion region can be contacted, sequentially, with multiple layers to form a stack of the layers on the adhesion region. Once the multi-layer structure has been assembled on the stamp, the stamp can be transferred to a target substrate, the release region can be at least partially decomposed, and the multi-layer structure can be transferred from the stamp to the target substrate. In certain embodiments, the method can be automated, for example, using robotic systems.

The present disclosure is also directed to multi-layer stacks of materials. Advantageously, certain of the methods described herein can be used to rapidly produce multi-layer stacks of layers of material with one, more, or all of the following properties: a large number of layers, one, more, or all of which can be very thin and/or made of single crystalline material; precise geometric control; a low number (or no) defects within the layers; and/or a high degree of variation in inter-layer chemical composition.

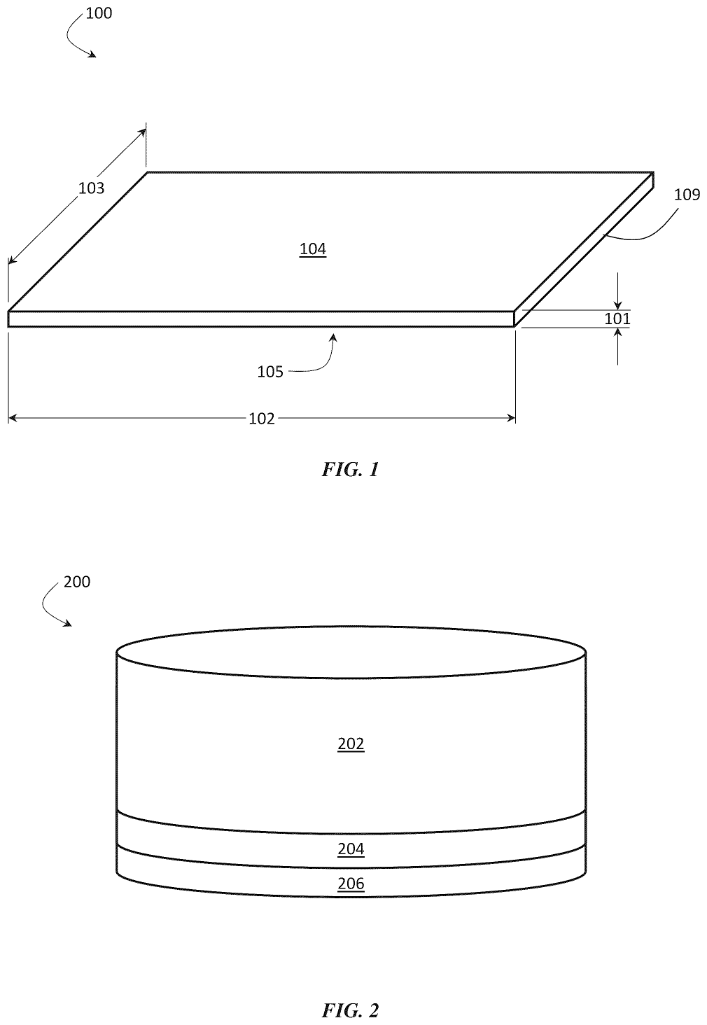

Various of the embodiments described herein are related to methods of manipulating layers and articles comprising multiple layers arranged in a stack. A “layer,” as that term is used herein, can include an arrangement of material having a thickness, a first lateral dimension that is perpendicular to the thickness of the layer and that has a length that is at least 3 times the thickness of the layer, and a second lateral dimension that is perpendicular to both the thickness of the layer and the first lateral dimension of the layer and that has a length that is at least 3 times the thickness of the layer. One example of a layer is illustrated schematically in FIG. 1. In FIG. 1, layer 100 comprises thickness 101, first lateral dimension (a width) 102, and second lateral dimension (a depth) 103. Layer 100 comprises two facial surfaces, each defined by the first and second lateral dimensions: top facial surface 104 and bottom facial surface 105 (which is not visible in FIG. 1). While the layer in FIG. 1 is illustrated as having rectangular facial surfaces, the layers contemplated herein can have any of a variety of other geometric configurations. For example, in some embodiments, the facial surface(s) of the layer(s) may be circular, elliptical, triangular, irregular, or any other suitable shape.

As noted above, one aspect of the present disclosure relates to methods of making multi-layer stacks. The method can employ, in some embodiments, an article comprising an adhesion region, an article substrate, and a release region between the adhesion region and the article substrate. Such an article is also sometimes referred to herein, for ease of reference, as an “assembly article.” One example of such an assembly article is illustrated schematically in FIG. 2. In FIG. 2, assembly article 200 comprises article substrate 202, adhesion region 206, and release region 204 between substrate 202 and adhesion region 206. As illustrated in FIG. 2, assembly article 200 is in the shape of a cylinder, but other shapes are also possible. In addition, each region of the assembly article can have a different shape or configuration. In some embodiments, the adhesion region is in the form of a layer, such as a thin film. In certain embodiments, the release region is in the form of a layer, such as a thin film.

The assembly article can be in the form of a stamp, in certain embodiments. In some such embodiments, the assembly article can be used to assemble layers in a multi-layer stack by being stamped onto the layers, picking up each layer off of a layer substrate in sequence to form the multi-layer stack.

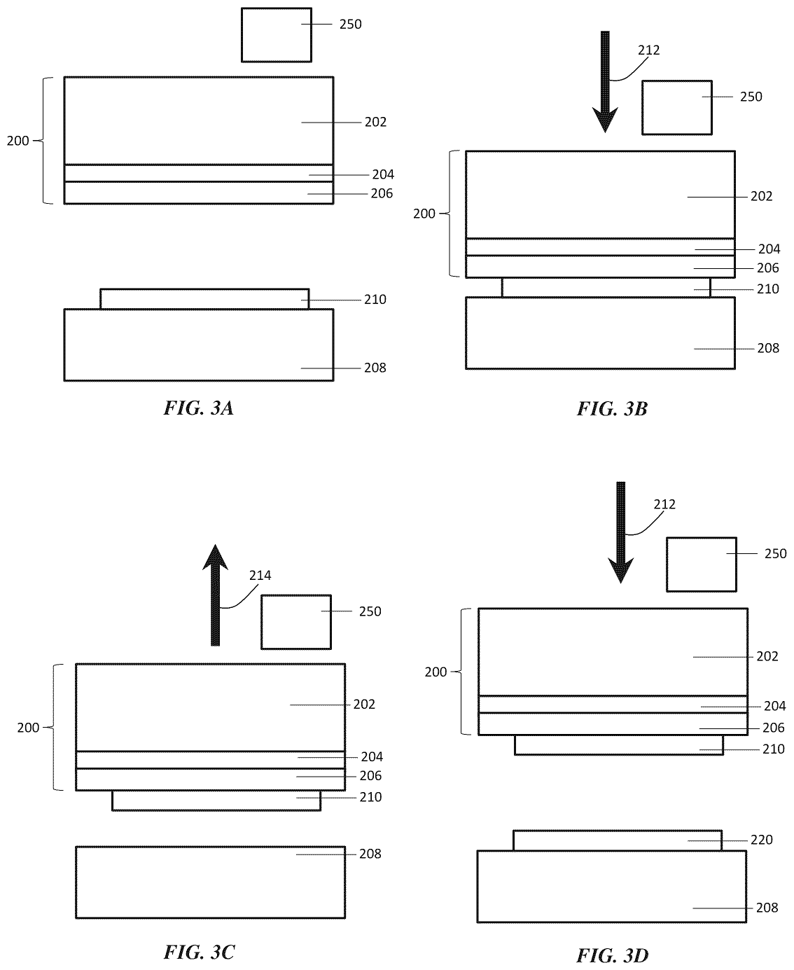

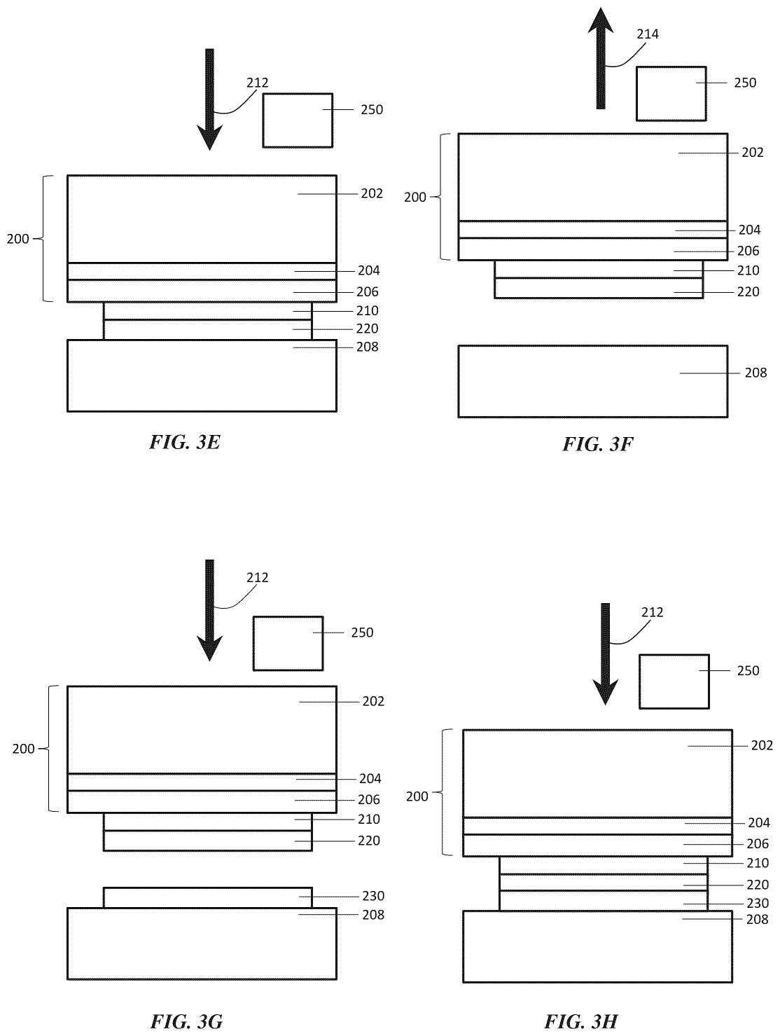

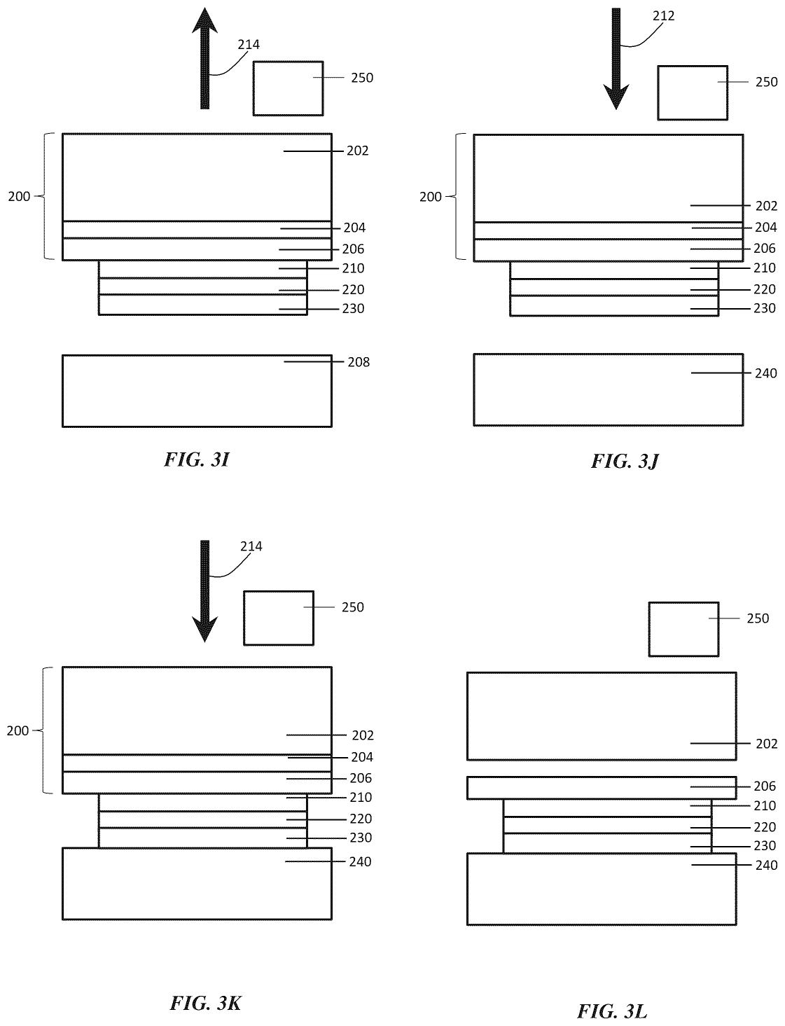

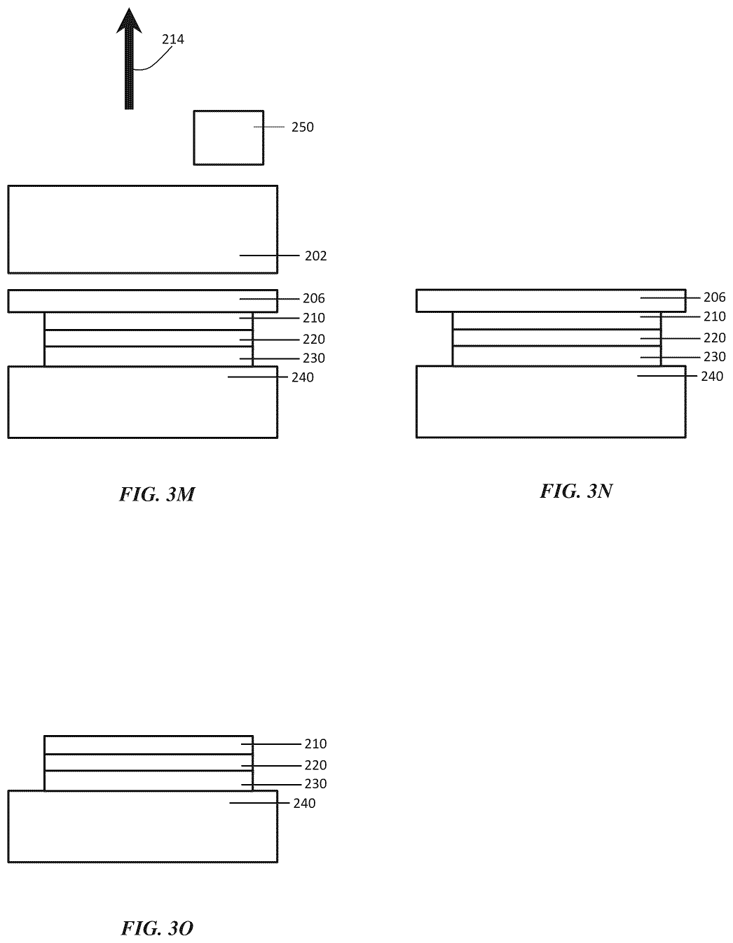

FIGS. 3A-3O are cross-sectional schematic illustrations showing a non-limiting example of a method of making a multi-layer stack using an assembly article, in accordance with certain embodiments. The method comprises, in some embodiments, establishing contact between the adhesion region of the assembly article and a first layer (e.g., a crystalline layer) such that the first layer is adhered to the adhesion region of the assembly article. For example, in FIG. 3A, first layer 210 is positioned on a surface of a support substrate 208. In FIG. 3B, article 200 is moved in the direction of arrow 212 toward layer 210 and support substrate 208 such that adhesion region 206 of article 200 contacts layer 210. In some embodiments, adhesion between adhesion region 206 and layer 210 is achieved simply by establishing contact between the two.

Adhesion between two materials (e.g., between the adhesion region and a layer, or between two immediately adjacent layers) refers to an arrangement in which the two materials are in contact and remain in contact due to adhesive forces between the two materials. Adhesive forces may include, for example, intermolecular forces between two materials (e.g., electrostatic forces such as ionic interactions, hydrogen bonding, dipole-dipole interactions, and/or Van der Waals forces). In some embodiments, the adhesive force comprises a Van der Waals (vdW) force.

Adhesion between adhesion region 206 and layer 210 may also involve, in some embodiments, heating the adhesion region (e.g., directly or indirectly, such as via support substrate 208 and layer 210) such that the adhesion region softens. The heating of the adhesion region can comprise heating the adhesion region to a temperature that is above the glass transition temperature of a material from which the adhesion region is made. Softening the adhesion region can increase the area over which the adhesion region and the first layer contact each other. In some embodiments, after the adhesion region has been heated, softened, and contacted with the first layer, the adhesion region can be cooled (e.g., to a temperature below the glass transition temperature of a material from which the adhesion region is made).

After the first layer has been adhered to the adhesion region, in accordance with certain embodiments, the assembly article and the support substrate can be moved away from each other. As would be appreciated by those of ordinary skill in the art, two objects can be “moved away from” each other (or “moved toward” each other) by moving one of the objects while keeping the other object stationary or by moving both objects. While the movement of objects relative to each other is described as being accomplished, in several instances described herein, by moving one object and keeping the other object stationary, it should be understood that the present disclosure is not so limited, and that the movement of either object relative to the other (or the movement of both objects) is also contemplated. In some embodiments, it is preferred that the relative motion between the assembly article and the layers that are to be incorporated into the multi-layer stack is achieved by moving the assembly article while keeping the layers substantially stationary.

In some embodiments, the adhesive forces between the adhesion region and the first layer are greater than the adhesive forces between the first layer and the support substrate such that, as the assembly article and the support substrate are moved away from each other, the assembly article is accompanied by the first layer. For example, in FIG. 3C, assembly article 200 and layer 210 (which is adhered to adhesion region 206) are both moved away from support substrate 208 in the direction of arrow 214, such that first layer 210 remains attached to article 200 via adhesive region 206.

In some embodiments, the method further comprises subsequently establishing contact between the first layer and a second layer (e.g., a second crystalline layer), while the first layer remains adhered to the article, such that the second layer is adhered to the first layer. For example, as shown in FIGS. 3D-3E, assembly article 200 (with first layer 210 adhered to the underside of assembly article 200 via adhesion region 206) is moved toward second layer 220 positioned on support substrate 208 until contact between first layer 210 and second layer 220 is achieved. As shown in FIGS. 3D-3E, support substrate 208 is the same support substrate that was used to support first layer 210 prior to the adhesion of first layer 210 on assembly article 200, but in other embodiments, a different support substrate can be used.

In some embodiments, by establishing contact between the first layer and the second layer, the first layer adheres to the second layer. The adhesion between the first layer and the second layer can involve any of a variety of inter-layer forces. In some embodiments, adhesion between the first layer and the second layer is achieved via one or more intermolecular forces (e.g., electrostatic forces such as ionic interactions, hydrogen bonding, dipole-dipole interactions, Van der Waals (VdW) forces). In some embodiments, the adhesive force between the first layer and the second layer comprises a Van der Waals force. In some embodiments, the two layers can be metallically bonded to each other.

After the second layer is adhered to the first layer, the article and the support substrate can be moved away from each other such that the first layer and the second layer remain associated with the article (and not the support substrate). In some such embodiments, the adhesive forces between the first layer and the second layer are greater than the adhesive forces between the second layer and the support substrate such that, as the assembly article and the support substrate are moved away from each other, the assembly article and the first layer are accompanied by the second layer. For example, in FIG. 3F, article 200 is moved in the direction of arrow 214 such that the article 200 moves away from receiving substrate 208. The first layer 210 remains adhered to adhesion region 206 of article 200, and the second layer 220 remains adhered to the first layer 210. Thus, both layers 210 and 220 are transported along with article 200 as it is moved away from support substrate 208.

In some embodiments, the method further comprises subsequently establishing contact between the second layer and a third layer (e.g., a third crystalline layer), while the first layer and the second layer remain adhered to the article, such that the third layer is adhered to the second layer. For example, as shown in FIGS. 3G-3H, assembly article 200 (with first layer 210 adhered to the underside of assembly article 200 via adhesion region 206 and second layer 220 adhered to the underside of first layer 210) is moved toward third layer 230 positioned on support substrate 208 until contact between second layer 220 and third layer 230 is achieved. As shown in FIGS. 3G-3H, support substrate 208 is the same support substrate that was used to support first layer 210 prior to the adhesion of first layer 210 on assembly article 200 and is the same support substrate that was used to support second layer 220 prior to the adhesion of second layer 220 on first layer 210, but in other embodiments, a different support substrate can be used.

In some embodiments, by establishing contact between the second layer and the third layer, the second layer adheres to the third layer. As in the case between the first layer and the second layer, the adhesion between the second layer and the third layer can involve any of a variety of inter-layer forces (e.g., one or more intermolecular forces, such as electrostatic forces including, but not limited to ionic interactions, hydrogen bonding, dipole-dipole interactions, Van der Waals (VdW) forces, and the like). In some embodiments, the adhesive force between the second layer and the third layer comprises Van der Waals forces.

After the third layer is adhered to the second layer, the assembly article and the support substrate can be moved away from each other such that the first layer, the second layer, and the third layer accompany the assembly article. In some such embodiments, the adhesive forces between the second layer and the third layer are greater than the adhesive forces between the third layer and the support substrate such that, as the assembly article, the first layer, and the second layer are moved away from the support substrate, the assembly article, the first layer, and the second layer are accompanied by the third layer. For example, in FIG. 31, article 200 is moved in the direction of arrow 214 such that article 200 moves away from receiving substrate 208. First layer 210 remains adhered to adhesion region 206 of article 200, second layer 220 remains adhered to first layer 210, and third layer 230 remains adhered to second layer 220. Thus, layers 210, 220, and 230 are transported along with article 200 as it is moved away from support substrate 208.

This process of establishing contact between an exposed layer (adhered to the assembly article and/or the multi-layer stack) and an additional layer may be repeated any number of times to add any number of layers to the multi-layer stack. In some embodiments, the process is used to create multi-layer stacks having at least 10 layers; at least 15 layers, at least 20 layers, at least 25 layers; at least 30 layers, at least 35 layers, at least 40 layers, at least 45 layers, at least 50 layers; at least 100 layers; at least 500 layers; at least 1,000 layers; or more.

In some embodiments, the multi-layer stack can be separated from the assembly article substrate. This can be useful, for example, when transferring the multi-layer stack to a target substrate.

In some embodiments, the method further comprises altering the release region such that separation is achieved between the article substrate and the first, second, and third layers. For example, as shown in FIGS. 3J-3K, article 200 is lowered, in the direction of arrow 214, toward receiving substrate 240. In FIG. 3K, third layer 230 contacts receiving substrate. In embodiments in which more than three layers have been assembled in the multi-layer stack, the last of the layers that has been added will typically be the layer contacting the target substrate.

In some embodiments, the release region is at least partially removed such that separation between the adhesion region and the article substrate is achieved. As shown in FIG. 3L, for example, release region 204 has been removed such that separation between assembly article substrate 202 and adhesion region 206 (as well as first layer 210, second layer 220, and third layer 230) is achieved. In FIG. 3L, first layer 210, second layer 220, and third layer 230 remain on receiving substrate 240 and are no longer attached to assembly article substrate 202 such that when article substrate is moved in the direction of arrow 214 in FIG. 3M, first layer 210, second layer 220, and third layer 230 remain on target substrate 240.

Removal of the release region (or a portion of the release region) can be achieved by any of a variety of suitable mechanisms. In some embodiments, at least a portion of the release region is degraded or disintegrated. Other methods of removing at least a portion of the release region are described in more detail below.

In some embodiments, at least a portion of the adhesion region remains on the first layer after the separation is achieved between the article substrate and the first, second, and third layers. For example, as shown in FIG. 3M, adhesion region 206 remains adhered to the first layer 210 while article substrate 202 is moved away from first layer 210, second layer 220, and third layer 230. As shown in FIG. 3N, adhesion region 206 remains above first layer 210 after deposition of the multi-layer stack on target substrate 240.

In some embodiments, the method further comprises removing at least some (e.g., at least 50 wt %, at least 75 wt %, at least 90 wt %, at least 95 wt %, at least 99 wt %, or all) of the portion of the adhesion region that remains on the first layer after separation is achieved between the article substrate and the first, second, and third layers. In FIG. 30, for example, the adhesion region that remained on first layer 110 in FIG. 3N is no longer present.

As mentioned above, the assembly article may comprise a substrate. The substrate can be made of any of a variety of suitable materials. In some embodiments, the substrate of the assembly article comprises a polymer (e.g., an organic polymer or an inorganic polymer), such as polydimethylsiloxane (PDMS). Additional non-limiting examples of suitable materials from which the assembly article substrate can be made include inorganic materials, such as metals, ceramics, and/or glasses. In some embodiments, the substrate comprises a flexible elastomeric polymer (e.g., PDMS or similar polymers), a flexible polymeric thin film (e.g., polyimide), and/or a flexible inorganic thin film (e.g., SiO₂, metal). In certain embodiments, the substrate material is selected such that the assembly article has the ability to conform to the underlying 2D material surface and to accommodate mismatch in angular tilt between the plane of the assembly article surface and the plane of the surfaces of the layers that are being manipulated. In some embodiments, the substrate comprises a domain (e.g., a thin film) that is has low adhesion to the layers that are being manipulated. In some such embodiments, the adhesion region (e.g., a thin film) of the assembly article is positioned over the domain of the substrate having low adhesion to the layers that are being manipulated.

As described above, the assembly article may comprise an adhesion region. The adhesion region may be configured to adhere to a layer (e.g., a first crystalline layer) upon contacting the layer during assembly of the multi-layer stack.

Generally, the material from which the adhesion region is made will be selected such that the adhesion region is capable of adhering to the first layer of the multi-layer stack. The adhesion region may, generally, comprise any of a variety of suitable materials. In some embodiments, the adhesion region comprises a chemical species including benzyl moieties, which may facilitate adhesion to an immediately adjacent material (e.g., an immediately adjacent crystalline layer). For example, in one embodiment, the adhesion region comprises poly(benzyl methacrylate) (PBzMA). Non-limiting examples of other materials from which the adhesion region may be made include polymers (e.g., poly (methyl methacrylate (PMMA), poly propylene carbonate, poly cyclohexene carbonate, poly (cyclohexene propylene carbonate) (PCPC), poly (propylene-co-cyclohexene carbonate), polystyrene, bisphenol-A polycarbonate, polycaprolactone, poly vinyl acetate, and the like), amorphous glass formers (e.g., α,α,α′-Tris(4-hydroxyphenyl)-1-ethyl-4-isopropylbenzene), metal (e.g., gold, indium) and/or other inorganic compounds. In some embodiments, the adhesion region comprises a thermoplastic polymer thin film, an organic thin film, a metallic thin film, and/or an inorganic thin film. In accordance with certain embodiments, the material from which the adhesion region is made can be selected to have a relatively high degree of adhesion to the layers that are being manipulated, relative to the degree of adhesion between the substrate and the layers that are being manipulated.

The adhesion region may be arranged in any of a variety of forms. In some embodiments, the adhesion region is in the form of a layer. In some embodiments, the adhesion region is in the form of a thin film.

As described above, the assembly article may comprise a release region between the assembly article substrate and the adhesion region. The release region may be configured to decompose or otherwise degrade upon exposure to a stimulus (e.g., heat, light, etc.). Alteration of the release region may be achieved in any of a variety of suitable ways. In some embodiments, altering the release region comprises thermally decomposing the release region. For example, in some embodiments, the release region may be exposed to heat (e.g., by transferring heat from a region adjacent to the release region to the release region, by generating heat within the release region by exposing the release region to electromagnetic radiation, by resistively heating the release region, or by any other suitable method), which may decompose the release region and allow for separation of the assembly article substrate from the adhesion region. In some embodiments, the release region comprises an ultraviolet (UV) degradable chemical species, such that upon application of UV radiation, the release region is decomposed, and the assembly article substrate is separated from the adhesion region. Non-limiting examples of other materials from which the release region may be made and that can be altered to achieve separation between the assembly article substrate and the adhesion region include, but are not limited to, other materials (e.g., polymers) where chemical degradation can be initiated via thermal or photolytic means (e.g., poly-phthalaldehyde), molecular glass formers, as well as organic or inorganic materials exhibiting a chemical change or phase transition which leads to a rapid loss of structural integrity or adhesive force. In some embodiments, the release region comprises a polymer that has chains that can be degraded by a photo-acid-generator.

The release region may be of any of a variety of suitable thicknesses. In some embodiments, a thickness of the release region is greater than or equal to 100 nm, greater than or equal to 250 nm, greater than or equal to 500 nm, greater than or equal to 750 nm, or greater than or equal to 1 micron. In some embodiments, the thickness of the release region is less than or equal to 1 micron, less than or equal to 750 nm, less than or equal to 500 nm, less than or equal to 250 nm, or less than or equal to 100 nm. Combinations of the above-referenced ranges are also possible (e.g., greater than or equal to 100 nm and less than or equal to 1 micron). Other ranges are possible.

In some embodiments, a sensor can be used to determine when contact has been established between the adhesion region and a layer of the multi-layer stack and/or between a layer of the multi-layer stack and a layer on a supporting substrate that is going to be added to the multi-layer stack. The ability to accurately determine once contact has been established between the assembly article and a layer and/or between a layer on the assembly article and the next layer that is to be added can allow one to avoid applying excessive force to the layers (e.g., the next layer that is to be added and/or to the layer(s) that have already been added to the stack), allowing one to assemble a multi-layer stack including a large number of layers without introducing cracks, warping, holes, or other defects into the multi-layer stack.

Accordingly, certain embodiments comprise using a sensor to measure a characteristic of electromagnetic radiation that travels through the assembly article, the characteristic being indicative of contact between the adhesion region and the first layer. In some such embodiments, the method further comprises increasing the distance between the article and a support substrate on which the first layer is positioned based at least in part on the measurement of the characteristic. For example, referring to FIGS. 3A-3C, sensor 250 can be positioned, in some embodiments, such that sensor 250 is capable of determining a characteristic (e.g., a wavelength, wavelength distribution, or another characteristic) of electromagnetic radiation that travels through substrate 202 (and, optionally, adhesion region 206 and/or release region 204). In some embodiments, once adhesion region 206 contacts layer 210, a characteristic of the electromagnetic radiation being sensed by sensor 250 changes relative to the characteristic prior to contact between adhesion region 206 and first layer 210. This change in the characteristic of the electromagnetic radiation can indicate that contact between the adhesion region and the first layer has been achieved and that no further downward force is necessary to establish the contact. In some embodiments, based on the change in the characteristic of the electromagnetic radiation, assembly article substrate 202 and support substrate 208 can be moved away from each other, as shown in FIG. 3C. One example of this mode of operation is described in Example 1 with respect to FIGS. 12A-12C.

Certain embodiments comprise using a sensor to measure a characteristic of electromagnetic radiation that travels through the assembly article, the characteristic being indicative of contact between one layer of the multi-layer stack (e.g., first layer 210) and a subsequently-added layer of the multi-layer stack (e.g., second layer 220). In some such embodiments, the method further comprises increasing the distance between the assembly article and a support substrate on which the layer being added is positioned based at least in part on the measurement of the characteristic. For example, referring to FIGS. 3D-3F, sensor 250 can be positioned, in some embodiments, such that sensor 250 is capable of determining a characteristic (e.g., a wavelength, wavelength distribution, or another characteristic) of electromagnetic radiation that travels through substrate 202 (and, optionally, adhesion region 206 and/or release region 204). In some embodiments, once first layer 210 contacts second layer 220, a characteristic of the electromagnetic radiation being sensed by sensor 250 changes relative to the characteristic prior to contact between first layer 210 and second layer 220. This change in the characteristic of the electromagnetic radiation can indicate that contact between the first layer and the second layer has been achieved and that no further downward force is necessary to establish the contact. In some embodiments, based on the change in the characteristic of the electromagnetic radiation, assembly article substrate 202 and support substrate 208 can be moved away from each other, as shown in FIG. 3F.

Any of a variety of types of sensors may be used to detect a characteristic of the electromagnetic radiation that is transported through the assembly article. Non-limiting examples of sensors include photodetectors, photocells, charge-coupled devices (CCDs), active-pixel sensors (e.g., CMOS sensors), and the like.

In certain embodiments, the layers that are added to the multi-layer stack are formed by patterning a larger predecessor layer. Such methods may be particularly useful when working with crystalline layers. It has been found, unexpectedly, that crystalline layers having sharp, defect-free edges and accurate shapes can be formed simply by applying a patterning substrate (on which a patterned adhesive has been arranged) to the crystalline material and pulling the patterning substrate and the substrate on which the predecessor layer is positioned away from each other.

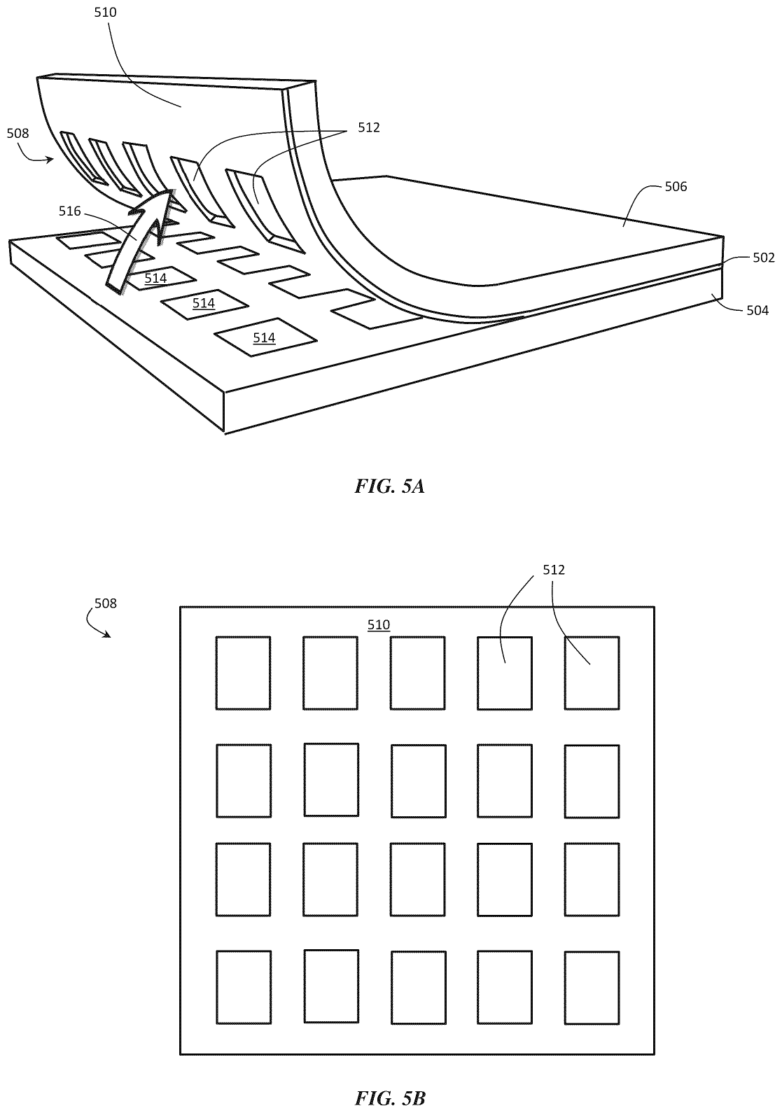

Accordingly, certain embodiments comprise, prior to establishing contact between the assembly article and the first layer, (1) establishing contact between a predecessor crystalline layer (e.g., a predecessor single-crystalline layer) and a surface of a patterning substrate, the surface of the patterning substrate comprising a first surface portion over which adhesive is present and a second surface portion over which adhesive is not present, and (2) forming the first layer by removing portions of the predecessor crystalline layer that contacted the adhesive. One example of this method is illustrated schematically in FIGS. 5A-5B. FIG. 5A is a perspective view schematic illustration showing the release of patterning substrate 506 from an underlying substrate 504 supporting predecessor layer 502, and FIG. 5B is a schematic illustration of the underside of patterning substrate 506 (on which adhesive has been patterned) prior to application of patterning substrate 506 to predecessor layer 502. In FIG. 5A, predecessor layer 502 is positioned over substrate 504. Patterning substrate 506 includes an adhesive material arranged on the underside 508 of patterning substrate 506 in a pattern, such that adhesive is present over portion 510 and is not present over portions 512. When the surface of the patterning substrate is placed in contact with the predecessor layer, the portions of the surface of the patterning substrate over which adhesive is positioned adhere to the layer while the remaining portions do not. For example, in FIG. 5A, when patterning substrate 506 is placed over predecessor layer 502, portion 510 of underside 508 (which includes adhesive) adheres to predecessor layer 502 while portions 512 of underside 508 (which do not include adhesive) do not. Subsequently, when the patterning substrate and the substrate on which the predecessor layer is positioned are moved away from each other, the portions of the predecessor layer that are in contact with the adhesive portions over the patterning substrate are removed from the support substrate, while the portions of the predecessor layer that do not contact adhesive remain on the support substrate. In FIG. 5A, for example, as patterning substrate 506 and substrate 504 are moved away from each other (e.g., by peeling patterning substrate 506 in the direction of arrow 514), layers 514 remain on substrate 504 while the rest of predecessor layer 502 accompanies patterning substrate 506. In some embodiments, the patterning substrate comprises a grid and/or an array of portions that do not adhesive positioned over them, which can be used to produce a grid and/or an array of layers from a predecessor layer.

Certain of the layers that are stacked to form multi-layer materials are referred to herein as “pixels.” The term “pixel” is used to refer to layers created from a larger, predecessor layer. Pixels can have any of a variety of suitable shapes, including rectangular (square, or non-square), triangular, circular, and the like.

Any of a variety of adhesives can be used to form layers from predecessor layers using the patterning methods described herein. Generally, the adhesive that is selected will depend upon the type of layer material that is being patterning. Non-limiting examples of adhesives that may be used to pattern layers in this way include polymers (e.g., poly(methyl methacrylate) (PMMA), poly(benzyl methacrylate) (PBzMA), polypropylene carbonate (PPC), poly (cyclohexene propylene carbonate). (PCPC), polycarbonate (PC), polycyclohexene carbonate (PCC)); metals (e.g., gold, indium); other inorganic materials; and the like. In some embodiments, the adhesive comprises a thermoplastic polymer, for example in the form of a thin film. In certain embodiments, the adhesive comprises an organic polymer, for example in the form of a thin film.

One advantage associated with certain embodiments is the ability to precisely align the edges of layers within the multi-layer stack to within tight tolerances. In some embodiments, the alignment article can be part of an automated system that is capable of precisely rotating layers prior to their deposition on the multi-layer stack. In certain embodiments, the method of forming the multi-layer stack comprises selecting an angle of alignment between (1) an edge of a layer to be added to the multi-layer stack and (2) an edge of a layer that is already present on the assembly article, and adding the layer to the assembly article such that the edge of the added layer is aligned with the edge of the layer that was already present on the assembly article to within 3° (or to within 2°, to within 10, to within 0.50, to within 0.20, to within 0.1°, to within 0.050, to within 0.01°, or to within 0.001°).

In accordance with certain embodiments, the use of the automated system can allow for the assembly of layers at a relatively fast rate. For example, in some embodiments, layers can be added to the multi-layer stack at a speed of at least 10, at least 15, at least 20, or at least 25 (and/or up to 30, up to 40, up to 50, or more) layers per hour.

In addition to inventive methods of making multi-layers stacks, the present disclosure is also directed to inventive multi-layer stacks. The inventive multi-layer stacks can be made, in some cases, using the inventive methods described herein. As noted above and elsewhere herein, one inventive aspect of the present disclosure lies in the ability to make multi-layer stacks having a large number of crystalline layers with few or no cracks, holes, or other defects.

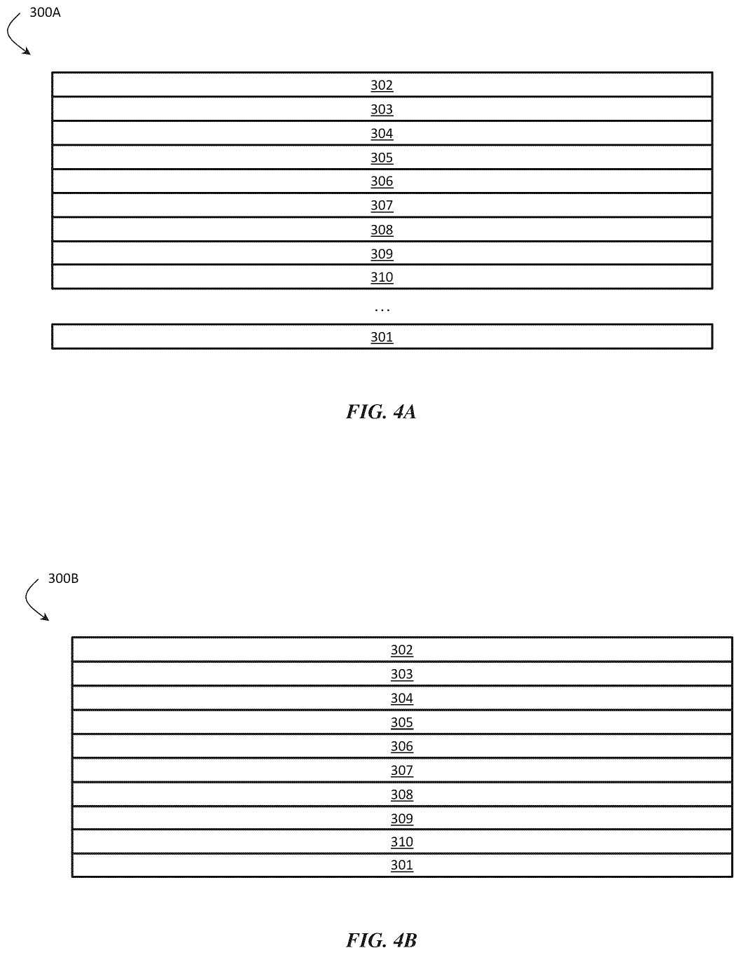

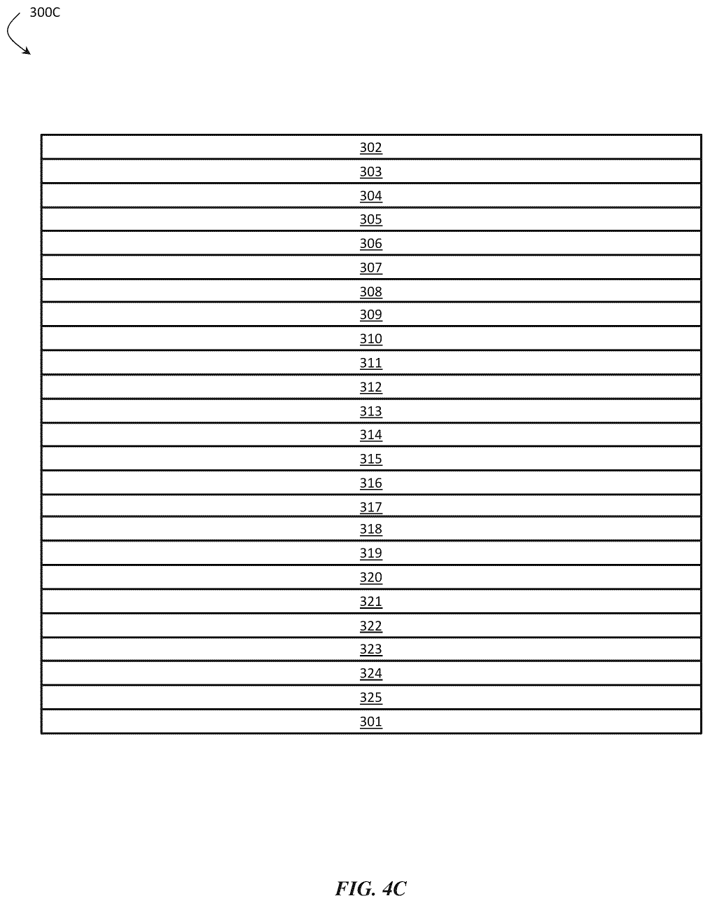

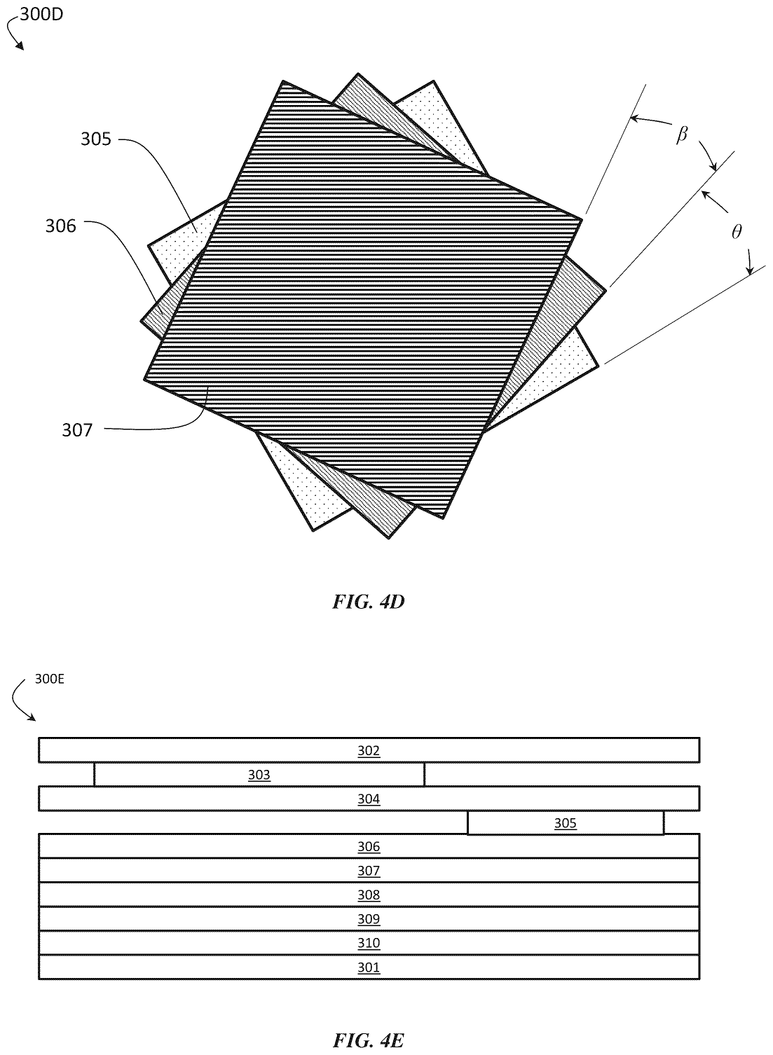

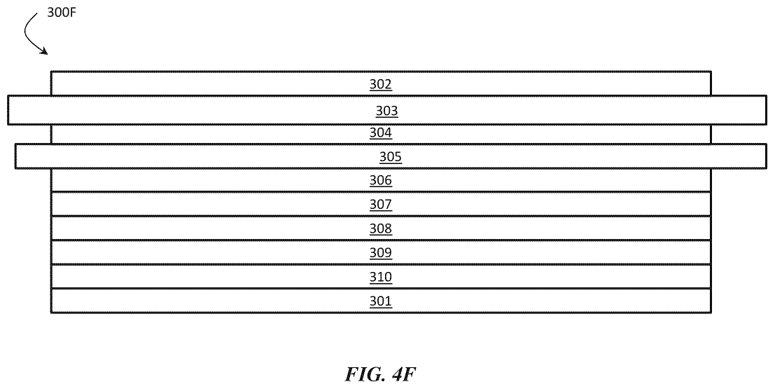

In some embodiments, the multi-layer stack comprises a first crystalline layer, a second crystalline layer, and intermediate crystalline layers between the first crystalline layer and the second crystalline layer. One example of a multi-layer stack is illustrated in FIG. 4A. In FIG. 4A, multi-layer stack 300A comprises a plurality of crystalline layers, including first crystalline layer 301, second crystalline layer 302, and at least eight intermediate crystalline layers 303-310 positioned between first crystalline layer 301 and second crystalline layer 302. In certain embodiments, the multi-layer stack comprises at relatively large number of intermediate layers, such as at least 8 intermediate layers, at least 13 intermediate layers, at least 18 intermediate layers, at least 23 intermediate layers, at least 28 intermediate layers, at least 33 intermediate layers, at least 38 intermediate layers, at least 43 intermediate layers, at least 48 intermediate layers, at least 98 intermediate layers, or more (i.e., such that the multi-layer stack comprises at least 10 total layers, at least 15 total layers, at least 20 total layers, at least 25 total layers, at least 30 total layers, at least 35 total layers, at least 40 total layers, at least 45 total layers, at least 50 total layers, at least 100 total layers, or more). One example of a multi-layer stack falling within the scope illustrated in FIG. 4A is shown in FIG. 4B. In FIG. 4B, multi-layer stack 300B consists of 10 total layers (i.e., first layer 301, second layer 302, and intermediate layers 303-310. Another example of a multi-layer stack falling within the scope illustrated in FIG. 4A is shown in FIG. 4C. In FIG. 4C, multi-layer stack 300C consists of 25 total layers (i.e., first layer 301, second layer 302, and intermediate layers 303-325).

In accordance with some embodiments, the layers of the multi-layer stack may be substantially non-covalently associated with other layers in the multi-layer stack. For example, in some embodiments, the layers of the multi-layer stack may be substantially non-covalently associated with immediately adjacent layers of the multi-layer stack. Two objects (e.g., layers) are considered to be “substantially non-covalently associated” with each other when at least the majority (and, in some embodiments, at least 75%, at least 90%, at least 95%, or at least 99%) of the interface between the two materials involves an interaction that is not a covalent bond. For example, two objects that are in contact with each other via Van der Waals forces over at least the majority of the interface between them would be said to be substantially non-covalently associated with each other. As another example, two objects that are in contact with each other via metallic bonds or ionic bonds over at least the majority of the interface between them would be said to be substantially non-covalently associated with each other.

In accordance with certain embodiments, the layers of the multi-layer stack may remain separable from other layers in the multi-layer stack (e.g., from immediately adjacent layers of the multi-layer stack). Two objects (e.g., layers) are considered to be “separable” from each other when they can be separated from each other while maintaining the structural integrity of each article. For example, two objects that can be separated without causing plastic deformation, structural failure, or the introduction of holes or other defects in either object would be considered to be separable. Layers that are adhered to each other via Van der Waals forces are examples of layers that are separable from each other.

In some embodiments, the first layer is substantially non-covalently associated with (and, in some cases, separable from) the intermediate layer in the stack that is adjacent (e.g., immediately adjacent) to the first layer. Referring to FIG. 4B, for example, in some embodiments, first layer 301 remains substantially non-covalently associated with (and, in some cases, separable from) intermediate layer 310, even when first layer 301 and intermediate layer 310 are immediately adjacent to and adhered to each other.

In certain embodiments, the second layer is substantially non-covalently associated with (and, in some cases, separable from) the intermediate layer in the stack that is adjacent (e.g., immediately adjacent) to the second layer. Referring to FIGS. 4A-4C, for example, in some embodiments, second layer 302 remains substantially non-covalently associated with (and, in some cases, separable from) intermediate layer 303, even when second layer 302 and intermediate layer 303 are immediately adjacent to and adhered to each other.

In some embodiments, each intermediate layer is substantially non-covalently associated with (and, in some cases, separable from) the two layers of the multi-layer stack that are adjacent to (e.g., immediately adjacent to) that intermediate layer. For example, referring to FIG. 4B, in some embodiments, intermediate layer 303 remains substantially non-covalently associated with (and, in some cases, separable from) layers 302 and 304, intermediate layer 304 remains substantially non-covalently associated with (and, in some cases, separable from) layers 303 and 305, intermediate layer 305 remains substantially non-covalently associated with (and, in some cases, separable from) layers 304 and 306, intermediate layer 306 remains substantially non-covalently associated with (and, in some cases, separable from) layers 305 and 307, intermediate layer 307 remains substantially non-covalently associated with (and, in some cases, separable from) layers 306 and 308, intermediate layer 308 remains substantially non-covalently associated with (and, in some cases, separable from) layers 307 and 309, intermediate layer 309 remains substantially non-covalently associated with (and, in some cases, separable from) layers 308 and 310, and intermediate layer 310 remains substantially non-covalently associated with (and, in some cases, separable from) layers 309 and 301.

Generally, whether two layers are substantially non-covalently associated with (and/or separable from) each other will depend on the types of forces that are adhering the layers together. For example, when a first crystalline layer and a second crystalline layer are adhered to each other via only Van der Waals forces, the first and second crystalline layers will be substantially non-covalently associated with (and will generally be separable from) each other. Other types of adhesive forces that can adhere two materials while maintaining their substantial non-covalent association are metallic bonding, ionic interaction forces, hydrogen bonding, and dipole-dipole interactions. In some embodiments, at least one (or at least two, at least three, at least four, at least five, or all) intermediate layer of the multi-layer stack is adhered to at least one adjacent intermediate layer (e.g., directly adjacent intermediate layer) via van der Waals interactions. In some embodiments, at least one (or at least two, at least three, at least four, at least five, or all) intermediate layer of the multi-layer stack is adhered to at least one adjacent intermediate layer (e.g., directly adjacent intermediate layer) via metallic bonding.

In some embodiments, the layers of the multi-layer stack can be arranged such that they are in direct contact with each other. For example, in some embodiments, the first layer is in direct contact with at least one of the intermediate layers, the second layer is in direct contact with at least one of the intermediate layers, and each of the intermediate layers is in direct contact with at least two of the layers of the stack. As one example, in FIG. 4B, first layer 301 is in direct contact with intermediate layer 310, second layer 302 is in direct contact with intermediate layer 303, and each of intermediate layers 303-310 is in direct contact with two of the layers of the stack. The ability to stack layers in direct contact in this manner, without introducing cracks, holes, or other defects can be achieved, for example, using the inventive layer stacking techniques described elsewhere herein.

In certain embodiments, after the multi-layer stack has been assembled, the multi-layer stack is substantially non-covalently associated with the substrate with which it is in direct contact. In certain embodiments, after the multi-layer stack has been assembled, the multi-layer stack remains separable from the substrate with which it is in direct contact.

In some embodiments, one, more, or all of the layers within the multi-layer stack have a low number of large through-thickness defects. In some embodiments, one, more, or all of the layers within the multi-layer stack have less than or equal to 1×10⁷ (or less than or equal to 1×10⁵, less than or equal to 1×10³, or less than or equal to 10) through-thickness defects having cross-sectional areas of greater than 1 square micrometer per cm² of the facial area of the layer. The cross-sectional area of a defect is measured in a direction perpendicular to the thickness of the layer. In some embodiments, at least two, at least three, at least four, at least five, at least six, at least seven, at least eight, at least nine, at least ten, at least 12, at least 15, at least 20, at least 25, at least 30, at least 35, at least 40, at least 45, at least 50, or more layers of the multi-layer stack have less than or equal to 1×10⁷ (or less than or equal to 1×10⁵, less than or equal to 1×10³, or less than or equal to 10) through-thickness defects having cross-sectional areas of greater than 1 square micrometer per cm² of the facial area of the layer.

In some embodiments, one, more, or all of the layers within the multi-layer stack have a low number of through-thickness defects of any size. In some embodiments, one, more, or all of the layers within the multi-layer stack have less than or equal to 1×10¹¹ (or less than or equal to 1×10¹⁰, less than or equal to 1×10⁹, less than or equal to 1×10⁸, less than or equal to 1×10⁷, less than or equal to 1×10⁵, less than or equal to 1×10³, or less than or equal to 10) through-thickness defects per cm² of the facial area of the layer. In some embodiments, at least two, at least three, at least four, at least five, at least six, at least seven, at least eight, at least nine, at least ten, at least 12, at least 15, at least 20, at least 25, at least 30, at least 35, at least 40, at least 45, at least 50, or more layers of the multi-layer stack have less than or equal to 1×10¹¹ (or less than or equal to 1×10¹⁰, less than or equal to 1×10⁹, less than or equal to 1×10⁸, less than or equal to 1×10⁷, less than or equal to 1×10⁵, less than or equal to 1×10³, or less than or equal to 10) through-thickness defects per cm² of the facial area of the layer.

One advantage associated with certain of the embodiments described herein is that layers with relatively large lateral dimensions can be manipulated to form multi-layer stacks with relatively large lateral dimensions. This is shown schematically, for example, in FIG. 1, in which the length of first dimension 102 is about 30 times the thickness dimension 101, and the length of second dimension 103 is substantially larger than thickness dimension 101.

The ability to manipulate relatively large layers can lead to the formation of multi-layer stacks in which the layers have relatively large first and second dimensions. For example, in some embodiments, at least one (e.g., at least one, at least two, at least three, or more) of the layers that are manipulated to form the multi-layer stack and/or of the layers within the assembled multi-layer stack have a first lateral dimension that is at least 5 times; at least 10 times; at least 100 times; at least 1000 times; at least 10,000 times; or at least 100,000 times the thickness of the layer. In some embodiments, a relatively high percentage (e.g., at least 50%, at least 60%, at least 70%, at least 80%, at least 90%, at least 95%, or all) of the layers that are manipulated to form the multi-layer stack and/or of the layers within the assembled multi-layer stack have a first lateral dimension that is at least 5 times; at least 10 times; at least 100 times; at least 1000 times; at least 10,000 times; or at least 100,000 times the thickness of the layer.

In certain embodiments, at least one (e.g., at least one, at least two, at least three, or more) of the layers that are manipulated to form the multi-layer stack and/or of the layers within the assembled multi-layer stack also have a second lateral dimension (perpendicular to the first lateral dimension) that is at least 5 times; at least 10 times; at least 100 times; at least 1000 times; at least 10,000 times; or at least 100,000 times the thickness of the layer. In some embodiments, a relatively high percentage (e.g., at least 50%, at least 60%, at least 70%, at least 80%, at least 90%, at least 95%, or all) of the layers that are manipulated to form the multi-layer stack and/or of the layers within the assembled multi-layer stack also have a second lateral dimension (perpendicular to the first lateral dimension) that is at least 5 times; at least 10 times; at least 100 times; at least 1000 times; at least 10,000 times; or at least 100,000 times the thickness of the layer.

In certain embodiments, at least one (e.g., at least one, at least two, at least three, or more) of the layers that are manipulated to form the multi-layer stack and/or of the layers within the assembled multi-layer stack have at least one lateral dimension (or have at least two perpendicular lateral dimensions) of at least 10 micrometers, at least 100 micrometers, at least 1000 micrometers, at least 1 centimeter, or at least 10 centimeters (and/or up to 50 centimeters, up to 1 meter, or more). In some embodiments, a relatively high percentage (e.g., at least 50%, at least 60%, at least 70%, at least 80%, at least 90%, at least 95%, or all) of the layers that are manipulated to form the multi-layer stack and/or of the layers within the assembled multi-layer stack have at least one lateral dimension (or have at least two perpendicular lateral dimensions) of at least 100 micrometers, at least 1000 micrometers, at least 1 centimeter, or at least 10 centimeters (and/or up to 50 centimeters, up to 1 meter, or more).

The ability to manipulate layers having relatively large lateral dimensions can lead to the production of multi-layer stacks in which individual layers within the multi-layer stack and/or the multi-layer stack itself have relatively large facial surface areas. This is shown schematically, for example, in FIG. 1, in which top facial surface 104 has a relatively large facial surface area (i.e., the geometric surface area of facial surface 104, which, in the case of FIG. 1, is calculated by multiplying the length of first dimension 102 by the length of second dimension 103).

In certain embodiments, at least one (e.g., at least one, at least two, at least three, or more) of the layers that are manipulated to form the multi-layer stack and/or of the layers within the assembled multi-layer stack have a facial surface area of at least 100 square micrometers; at least 1000 square micrometers; at least 10,000 square micrometers; at least 100,000 square micrometers; at least 0.01 square centimeters; at least 0.1 square centimeters; at least 1 square centimeters; or at least 10 square centimeters (and/or, up to 100 square centimeters; up to up to 1,000 square centimeters; up to 10,000 square centimeters, or more). In some embodiments, a relatively high percentage (e.g., at least 50%, at least 60%, at least 70%, at least 80%, at least 90%, at least 95%, or all) of the layers that are manipulated to form the multi-layer stack and/or of the layers within the assembled multi-layer stack have a facial surface area of at least 100 square micrometers; at least 1000 square micrometers; at least 10,000 square micrometers; at least 100,000 square micrometers; at least 0.01 square centimeters; at least 0.1 square centimeters; at least 1 square centimeters; or at least 10 square centimeters (and/or, up to 100 square centimeters; up to up to 1,000 square centimeters; up to 10,000 square centimeters, or more).

In some embodiments, at least one (e.g., at least one, at least two, at least three, or more) of the layers that are manipulated to form the multi-layer stack and/or of the layers within the assembled multi-layer stack are crystalline. The crystalline layers within the multi-layer stack can be single crystalline or polycrystalline. In certain embodiments, a relatively high percentage (e.g., at least 50%, at least 60%, at least 70%, at least 80%, at least 90%, at least 95%, or all) of the layers that are manipulated to form the multi-layer stack and/or of the layers within the assembled multi-layer stack are crystalline.

One advantage of certain of the methods described herein is that they can be used to arrange single crystalline materials without introducing cracks, holes, or other defects into the single crystalline materials. Accordingly, in some embodiments, at least one (e.g., at least one, at least two, at least three, or more) of the layers that are manipulated to form the multi-layer stack and/or of the layers within the assembled multi-layer stack are single crystalline. In certain embodiments, a relatively high percentage (e.g., at least 50%, at least 60%, at least 70%, at least 80%, at least 90%, at least 95%, or all) of the layers that are manipulated to form the multi-layer stack and/or of the layers within the assembled multi-layer stack are single crystalline.

In certain embodiments, at least one (e.g., at least one, at least two, at least three, or more) of the layers that are manipulated to form the multi-layer stack and/or of the layers within the multi-layer stack are thin films. As used herein, a “thin film” is a layer having a thickness of less than or equal to 1 micrometer. The thickness of a layer is generally determined as the average thickness of the layer, determined as a number average and measured across the entirety of its facial surface area. In some embodiments, a relatively high percentage (e.g., at least 50%, at least 60%, at least 70%, at least 80%, at least 90%, at least 95%, or all) of the layers that are manipulated to form the multi-layer stack and/or of the layers within the assembled multi-layer stack have a thickness of less than or equal to 1 micrometer, less than or equal to 500 nanometers, less than or equal to 100 nanometers, less than or equal to 50 nanometers, less than or equal to 10 nanometers, or less than or equal to 2 nanometers (and/or as little as 0.8 nanometers, as little as 0.5 nanometers, or less).

In some embodiments, the variation of the thickness of the layers within the multi-layer stack, across the lateral dimensions of the layers, can be very small. The variation of the thickness of a layer (T_{Var}) is expressed as a percentage and is determined as follows:

$${T}_{Var} = \frac{\overline{{Max}_{10}} - \overline{T}}{\overline{T}} \times 100 \%$$

where M̅a̅x̅₁̅₀̅ is the number averaged thickness of the ten thickest local maxima of the layer thickness and T̅ is the average thickness of the layer. In some embodiments, for at least one layer (or at least two layers, at least three layers, at least 5 layers, at least 10 layers, at least 50 layers, or more) of the multi-layer stack, the variation in the thickness of the layer is less than 10%, less than 5%, less than 2%, or less than 1%. In some embodiments, for at least 50%, at least 75%, at least 90%, at least 95%, or at least 98% of the layers of the multi-layer stack, the variation in the thickness of the layer is less than 10%, less than 5%, less than 2%, or less than 1%.

In certain embodiments, at least one (e.g., at least one, at least two, at least three, or more) of the layers that are manipulated to form the multi-layer stack and/or of the layers within the multi-layer stack are monolayers (i.e., a layer that is one molecule in thickness). In some embodiments, a relatively high percentage (e.g., at least 50%, at least 60%, at least 70%, at least 80%, at least 90%, at least 95%, or all) of the layers that are manipulated to form the multi-layer stack and/or of the layers within the multi-layer stack are monolayers.

The layers of the multi-layer stacks described herein may have a variety of suitable chemical compositions. In certain embodiments, each of the layers within the multi-layer stack has the same chemical composition. In other embodiments, at least 2 (or at least 3, at least 4, at least 5, at least 6, at least 10, or more) of the layers in the multi-layer stack have different chemical compositions.

In certain embodiments, at least one (e.g., at least one, at least two, at least three, or more) of the layers that are manipulated to form the multi-layer stack and/or of the layers within the multi-layer stack are made of two-dimensional (2D) material (i.e., a monolayer with a flat molecular structure). In some embodiments, a relatively high percentage (e.g., at least 50%, at least 60%, at least 70%, at least 80%, at least 90%, at least 95%, or all) of the layers that are manipulated to form the multi-layer stack and/or of the layers within the multi-layer stack are made of 2D material. Non-limiting examples of 2D materials include graphene, hexagonal boron nitride (hBN), BP, MoS₂, MoSe₂, WS₂, WSe₂, TiS₃, SnS, SnS₂, InSe, In₂Se₃, GaSe, GaTe, ReS₂, ReSe₂, NbSe₂, and TaS₂. In some embodiments, one or more layers of the multi-layer stack comprises a transition metal dichalcogenide (TMDC), such as MoS₂, MoSe₂, MoTe₂, WS₂, and/or WSe₂. In some embodiments, one or more layers of the multi-layer stack comprises a van der Waals material (vdW), such as graphene. In some embodiments, the multi-layer stack comprises a layer comprising a transition metal dichalcogenide, graphene, or hexagonal boron nitride. In some embodiments, at least one of the crystalline layers comprises a transition metal dichalcogenide, graphene, and/or hexagonal boron nitride.

The present disclosure is not limited to the use of 2D materials, however, and in other embodiments, other materials can be used. Examples of materials that can be used in the multi-layer stacks described herein include, but are not limited to delaminable complex oxides (e.g., through dissolvable sacrificial layers or vdW-based remote epitaxy); molecular monolayers; nanoparticle or nanoplatelet monolayers; nanowires, nanotubes, and/or nanorods (e.g., individually, or as ordered/disordered networks); polymeric thin films (e.g., via spin coating, drop casting); self-assembled organic layers (e.g., lipid monolayers, lipid bilayers); evaporated thin films (e.g., elemental thin films such as Au, Ag, Si, and the like; alloy thin films; and/or compound thin films such as SiOₓ, SiNₓ, and the like); 2D materials; and/or any combination of two or more of these materials.

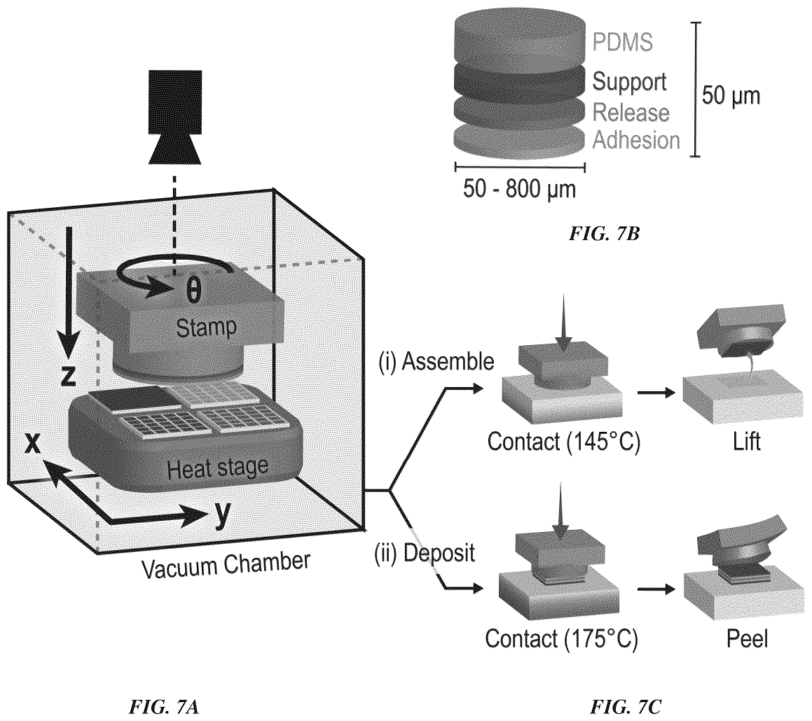

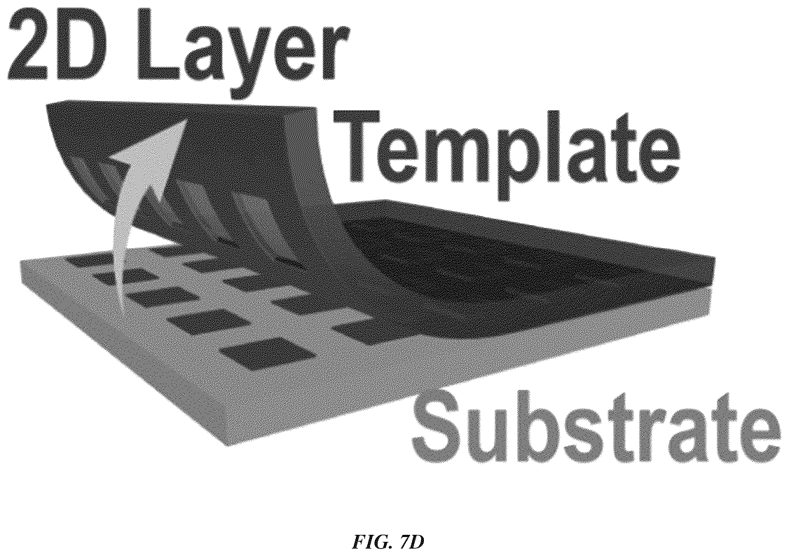

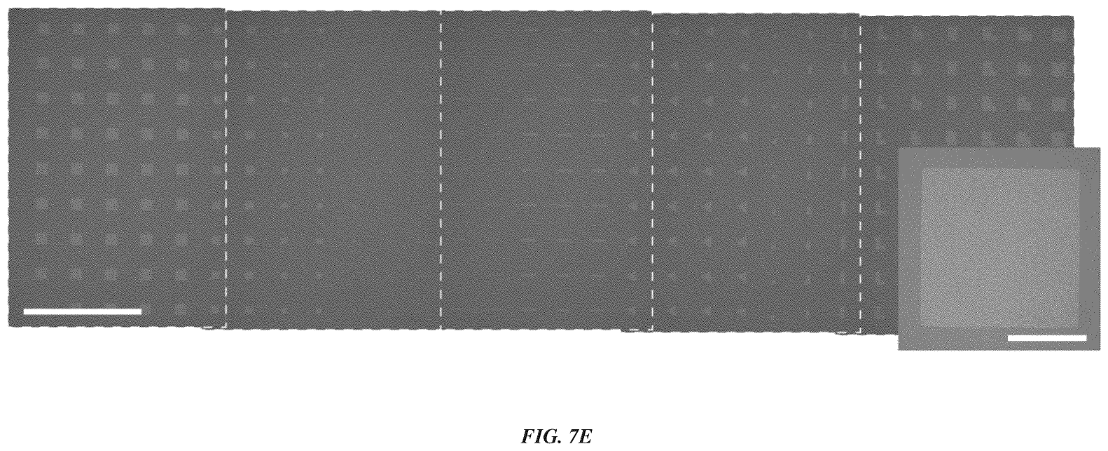

In addition to controlling the translational position (e.g., x-, y-, and/or z-coordinates) of two (or more) adjacent layers, the methods described herein may also be used to control the relative rotational positions of adjacent layers. This can be achieved, for example, by rotating the assembly article and/or the support substrate during assembly of the multi-layer structure. One example of such rotation is illustrated schematically in FIG. 7A and described below in Example 1. The ability to controllably rotate the assembly article and/or support substrate can allow one to closely control the relative rotational positions of the layers within the multi-layer stack.

In some embodiments, the multi-layer stack is arranged such that, for each of a plurality of the intermediate layers, an edge of the intermediate layer is arranged such that (1) it is within 3° of a common angle of rotation relative to the corresponding edge of a layer that is adjacent to (e.g., directly adjacent to) and on a first side of the intermediate single-crystalline layer and (2) it is within 3° of the common angle of rotation relative to the corresponding edge of a layer that is adjacent to (e.g., directly adjacent to) and on a second side, opposite the first side, of the intermediate single-crystalline layer. FIG. 4D is a top-view schematic illustration of one example of a multi-layer stack 300D in which edges of layers 305 and 306 define angle of rotation θ, and edges of layers 306 and 307 define angle of rotation β. In FIG. 4D, each of angles θ and β is about 15°, with less than 1° variation in the angle of rotation from layer to layer. Accordingly, the common angle of rotation among layers 305, 306, and 307 is 15°, and intermediate layer 306 has an edge that is arranged such that:
(1) it is within 1° of the common angle of rotation (15°) relative to the corresponding edge of a layer (i.e., layer 305) that is directly adjacent to and on a first side of layer 306; and
(2) it is within 1° of the common angle of rotation (15°) relative to the corresponding edge of a layer (i.e., layer 307) that is directly adjacent to and on a second side of layer 306 that is opposite the first side of layer 306.
   In some embodiments, the multi-layer stack is arranged such that, for at least 25%, at least 50%, at least 75%, at least 90%, or all of the intermediate layers within the multi-layer stack, an edge of the intermediate layer is arranged such that:
(1) it is within 3° (or within 2°, within 10, within 0.5°, within 0.20, within 0.1°, within 0.05°, within 0.01°, within 0.001°) of a common angle of rotation relative to the corresponding edge of a layer that is adjacent to (e.g., directly adjacent to) and on a first side of the intermediate single-crystalline layer, and
(2) it is within 3° (or within 2°, within 10, within 0.5°, within 0.2°, within 0.10, within 0.05°, within 0.01°, or within 0.001°) of the common angle of rotation relative to the corresponding edge of a layer that is adjacent to (e.g., directly adjacent to) and on a second side, opposite the first side, of the intermediate single-crystalline layer.

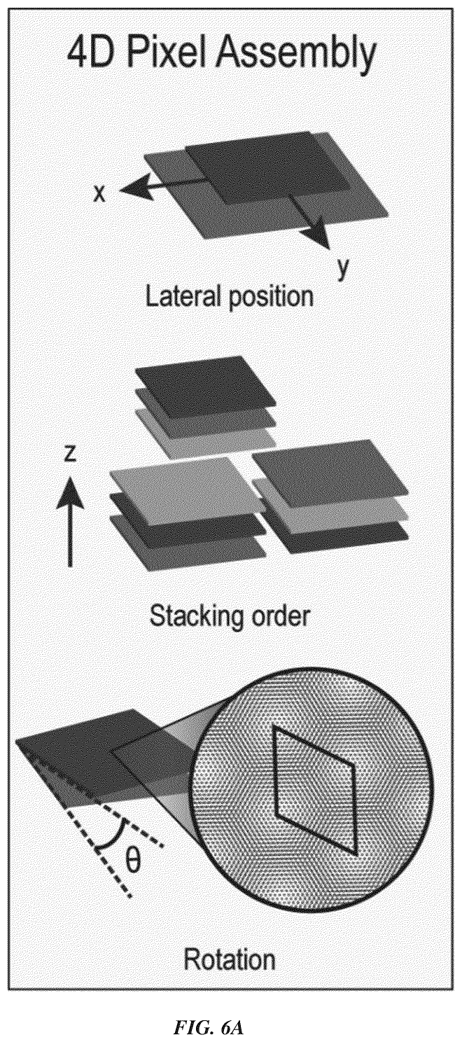

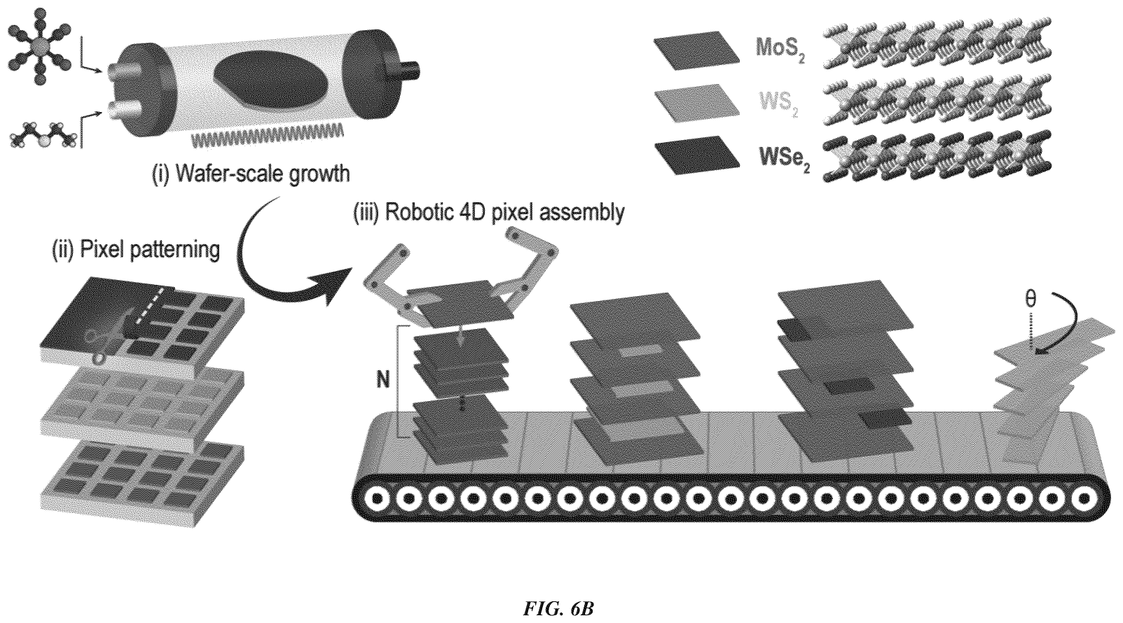

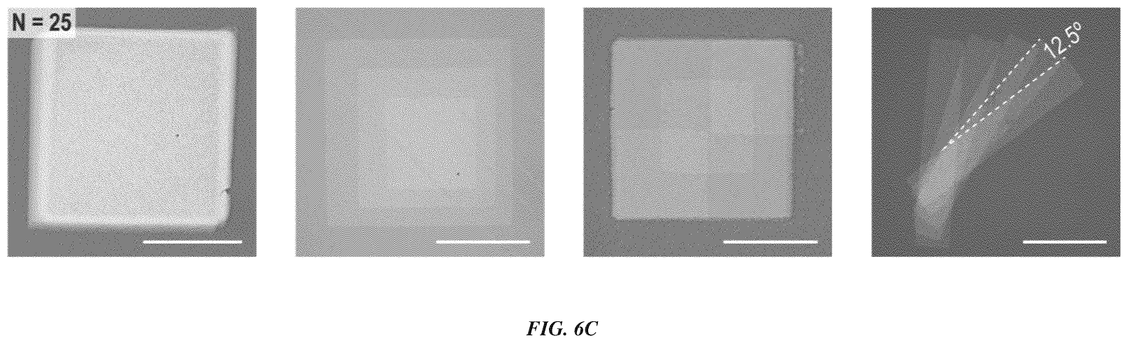

One example of an article in which corresponding edges are arranged according to a common angle of rotation, with a tight tolerance on the variation of the angle of rotation from layer to layer, is shown in FIG. 6B(iii) and the far-right-hand side of FIG. 6C, described in more detail below in Example 1.

In some embodiments, at least two of the layers in the multi-layer stack have edges (e.g., edge 109 of layer 100 in FIG. 1), and the two edges are aligned to within 3° (or to within 2°, to within 10, to within 0.5°, to within 0.2°, to within 0.10, to within 0.05°, to within 0.01°, or to within 0.001°) of parallel. In some embodiments, a relatively large percentage (e.g., at least 20%, at least 40%, at least 60%, at least 80%, at least 90%, or all) of the layers within the multi-layer stack have an edge that is aligned, within 3° (or to within 2°, to within 10, to within 0.5°, to within 0.2°, to within 0.10, to within 0.05°, to within 0.01°, or to within 0.001°) of parallel with at least one other edge of a layer within the multi-layer stack. In some embodiments, a relatively large percentage (e.g., at least 20%, at least 40%, at least 60%, at least 80%, at least 90%, or all) of the layers within the multi-layer stack have an edge that is aligned, within 3° (or to within 2°, to within 10, to within 0.5°, to within 0.2°, to within 0.10, to within 0.05°, to within 0.01°, or to within 0.001°) of parallel with all of the layers of the multi-layer stack that are immediately adjacent to that intermediate layer.

The methods described herein can be used to form multi-layer stacks comprising layers with different lateral dimensions, in some embodiments. For example, as shown in FIG. 4E, intermediate layer 303 and intermediate layer 305 have facial surface areas that are a fraction of the largest facial surface area of the layers within multi-layer stack 300E. Further examples of multi-layer stacks comprising layers with different facial surface areas are shown in FIGS. 6B(iii), 6C, 8B, and 8C and are described in more detail below in Example 1. In some embodiments, at least one of the intermediate layers in the multi-layer stack has a facial surface area that is less than or equal to 75%, less than or equal to 50%, less than or equal to 40%, or less than or equal to 30% of the largest facial surface area of the layers within the multi-layer stack.

Intermediate layers may also, in some embodiments, have facial surface areas that are smaller than the facial surface areas of the first layer and/or the second layer. For example, in FIG. 4F, intermediate layers 303 and 305 each have facial surface areas that are larger than the facial surface areas of first layer 301 and second layer 302. In some embodiments, at least one of the intermediate layers in the multi-layer stack has a facial surface area that is at least 125%, at least 150%, at least 200%, or more of the facial surface area of the first layer and/or of the facial surface area of the second layer.

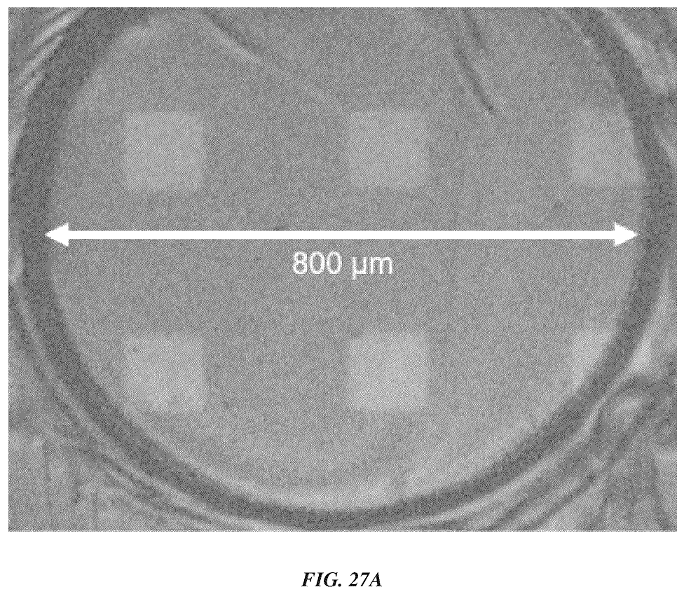

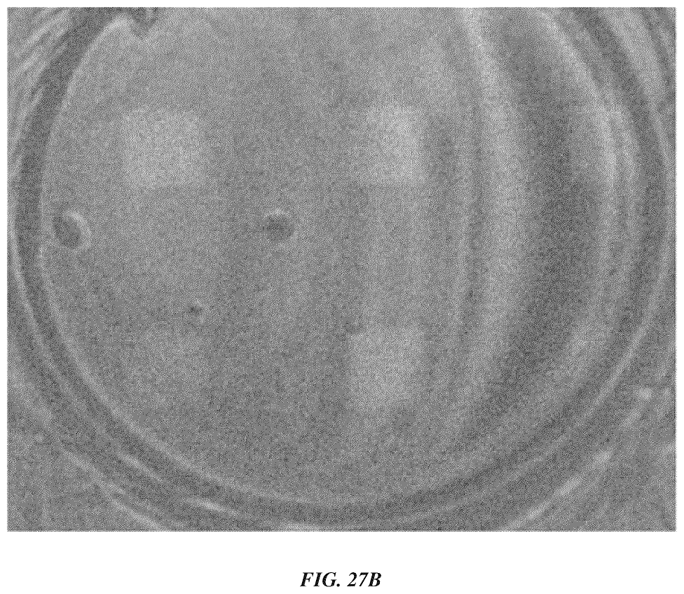

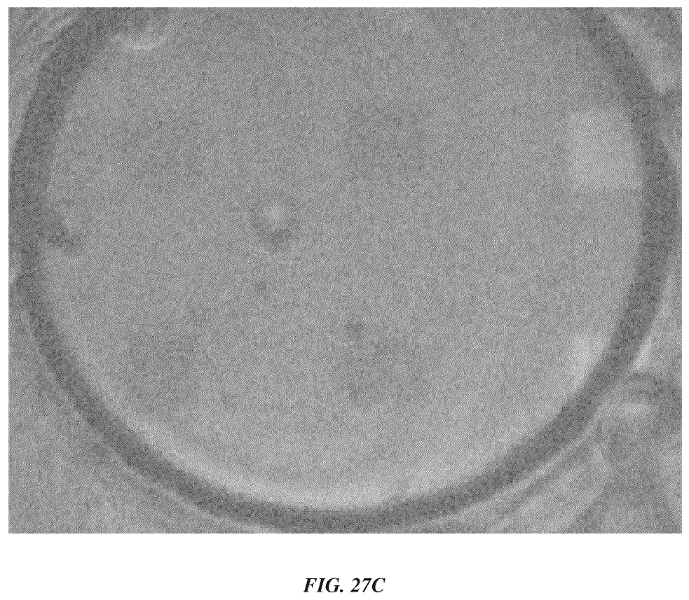

While FIGS. 3A-3O illustrate an embodiment in which a single multi-layer stack is fabricated using the assembly article, in other embodiments, multiple multi-layer stacks can be fabricated simultaneously using the assembly article. In some embodiments, at least two, at least three, at least four, at least five, at least 10, at least 20, or more multi-layer stacks are fabricated simultaneously using the assembly article. In some embodiments, the multi-layer stacks that are fabricated simultaneously using the assembly article are arranged as an array on the adhesion region of the assembly article and subsequently deposited as an array on the target substrate. As one example, FIGS. 27A-27C show an embodiment in which four multi-layered stacks are fabricated simultaneously using a single assembly article.

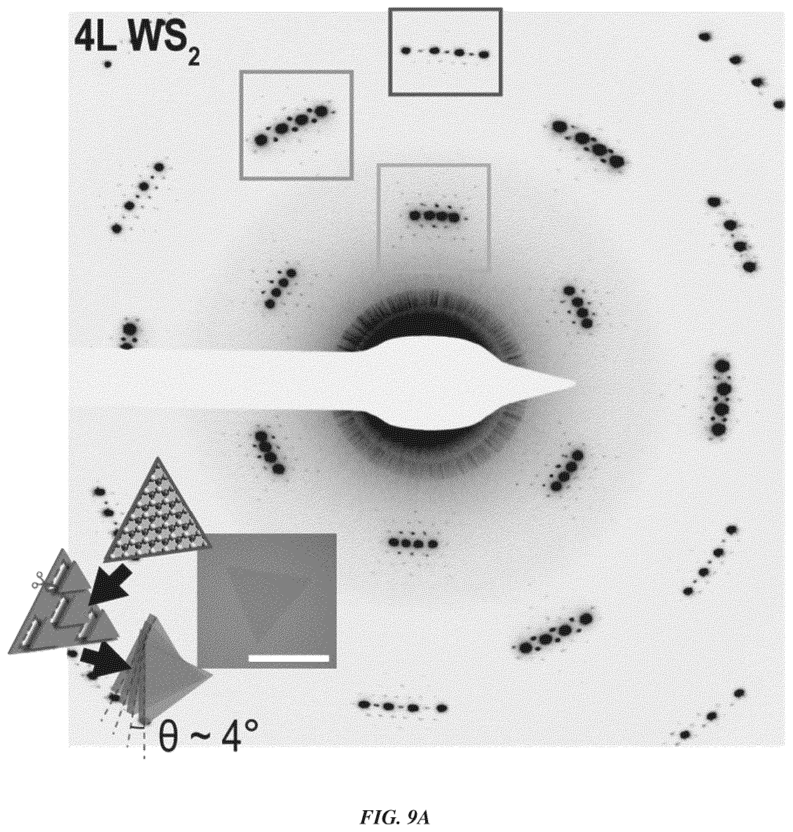

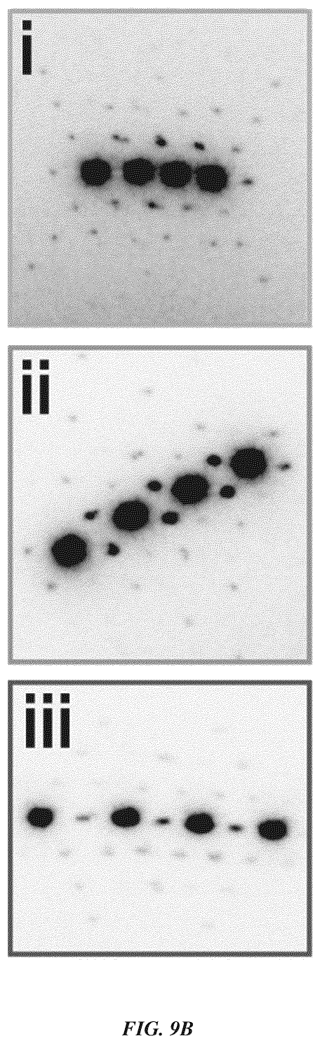

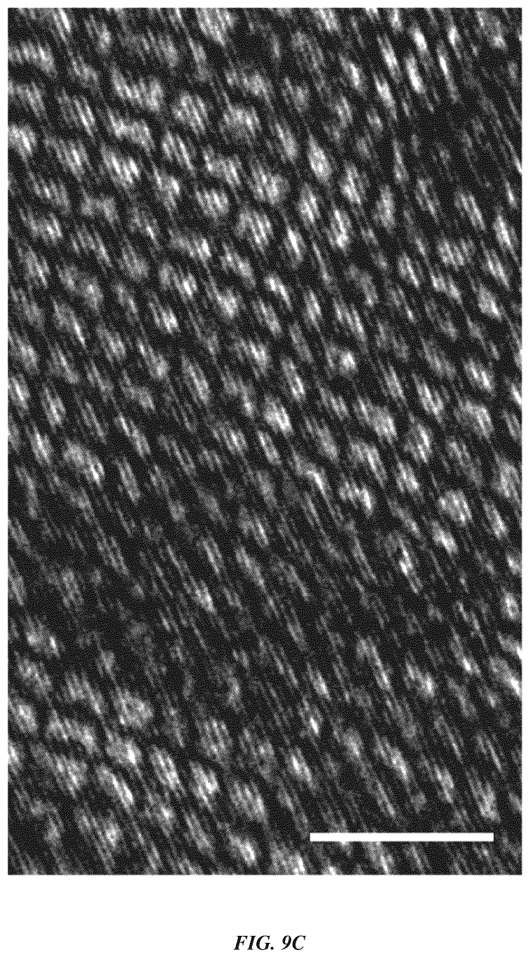

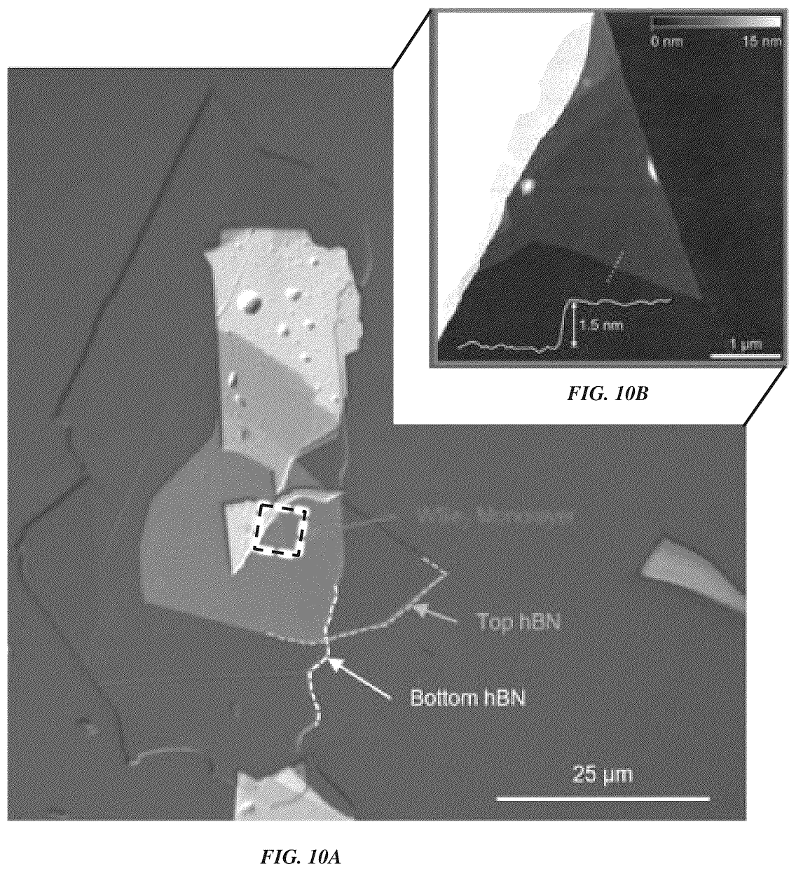

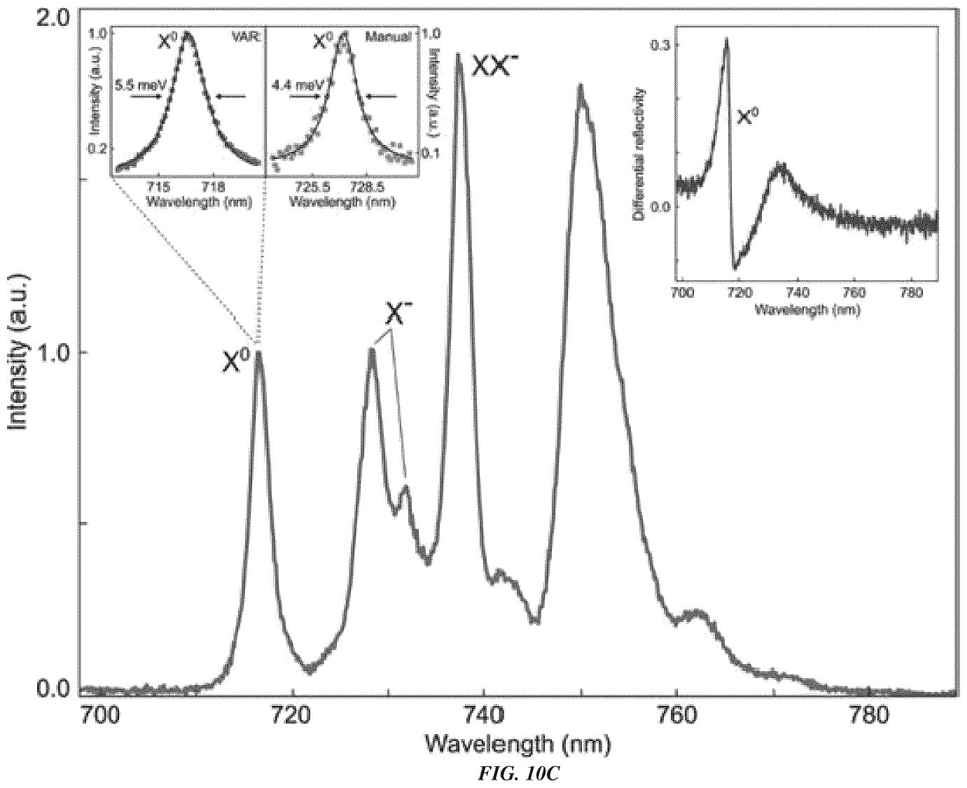

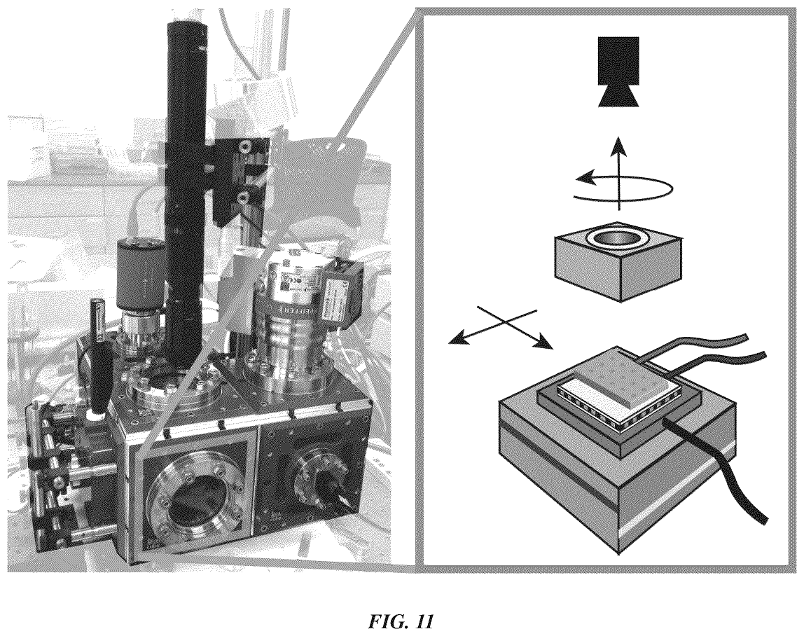

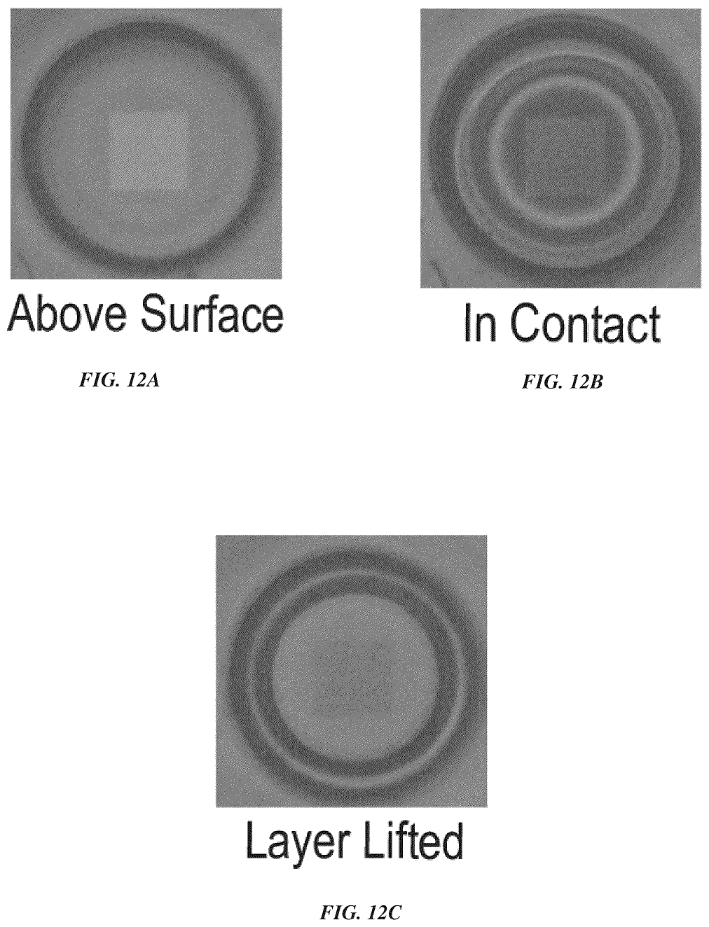

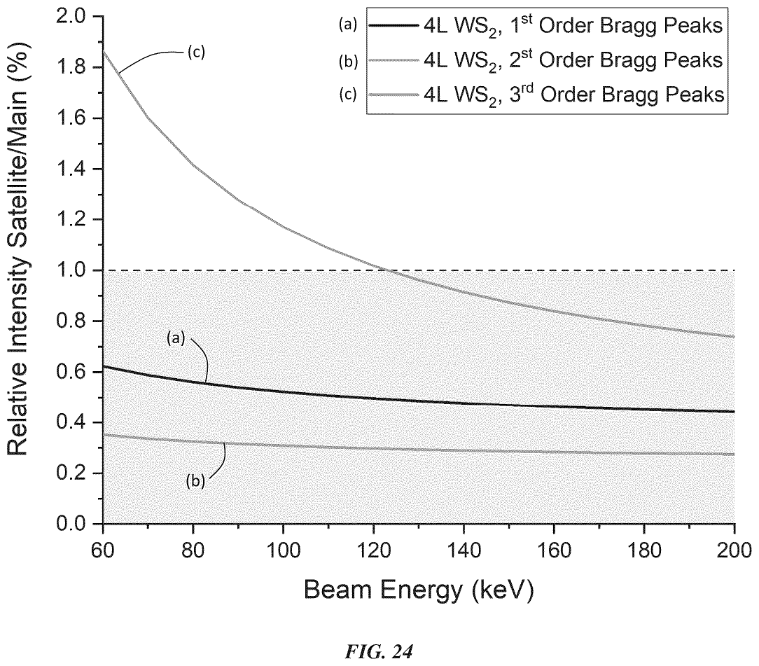

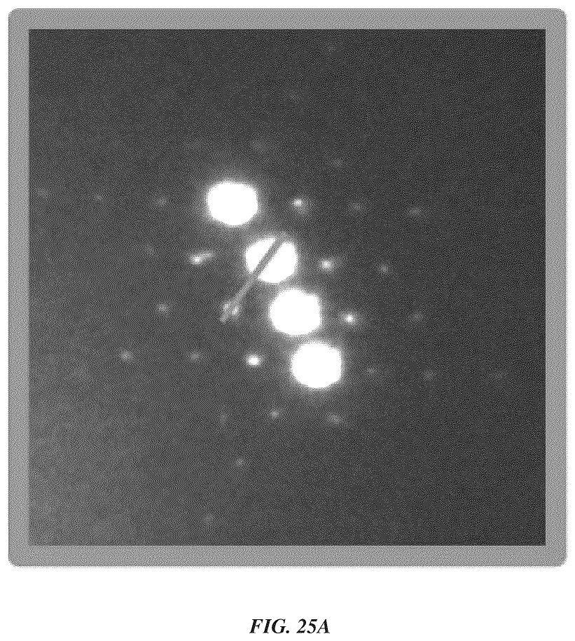

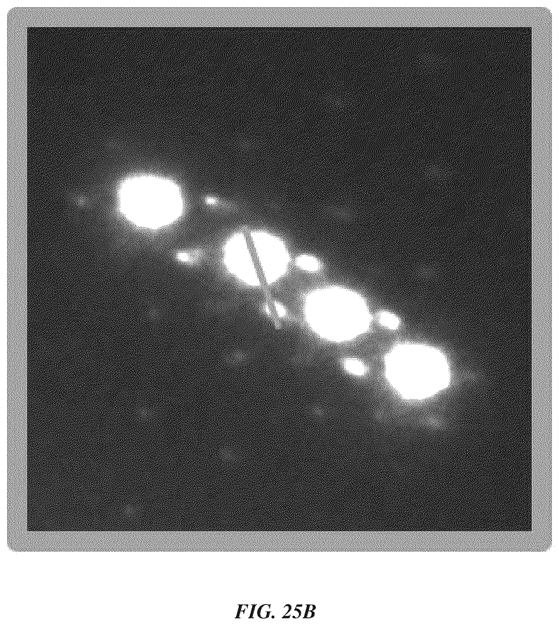

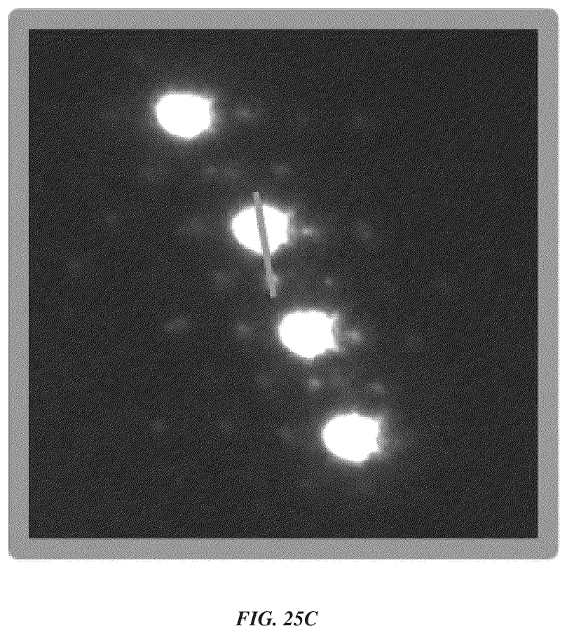

In some embodiments, at least a portion (e.g., at least two, at least three, at least four, at least five, at least 10, at least 15, at least 20, at least 25, at least 30, at least 35, at least 40, at least 45, at least 50, or more) of the layers within the multi-layer stack form a multilayer moiré superlattice. The formation of multilayer moiré superlattices (which is indicative of multilayer structural reconstruction) can be confirmed through characterization techniques which are sensitive to the local atomic arrangement, or through characterization techniques which are sensitive to the reconstruction's modification to the crystal symmetry of the stacked layers. For example, the detection of a multilayer moiré superlattice can be confirmed, in accordance with certain embodiments, using transmission electron microscopy (TEM) to view the sample in a plan geometry (i.e., observing at normal incidence with respect to the sample surface), where observation of superlattice satellite diffraction peaks in selected area diffraction indicates the presence of a multilayer superlattice (see, e.g., FIGS. 9A-9B) for at least one TEM accelerating voltage (e.g., 300 kV, 200 kV, 180 kV, 120 kV, 80 kV, or 60 kV; see, e.g., FIG. 24) selected to achieve satellite peak contrast versus primary lattice diffraction peaks. The presence of satellite peaks between the atomic lattice primary Bragg diffraction peaks associated with each individual layer is a general indication of the formation of a moiré superlattice, and therefore the presence of satellite peaks between multiple adjacent layers confirms the presence a multi-layer moiré superstructure.

The multi-layer stacks described herein may be used in variety of applications. For example, in some embodiments, the multi-layer stack is part of an electronic circuit, such as an integrated circuit. Other applications are also possible. For example, in some embodiments, the multi-layer stack is part of an optical component and/or electromagnetic wave element (e.g., a lens, a waveguide, a light emitting device (e.g., a light-emitting diode, a laser), a photovoltaic device, an absorption coating, a reflective coating, a wavelength filter, and/or an antenna). In certain embodiments, the multi-layer stack is part of a mechanical structure (e.g., a microelectromechanical structure and/or a resonator). In certain embodiments, the multi-layer stack is part of a thermal management device (e.g., thermal insulation and/or heat piping). In some embodiments, the multi-layer stack is part of a chemical sensor (e.g., a gas sensor, for example, using MoS₂ layers), which may optionally be coupled to an electronic circuit element. In some embodiments, the multi-layer stack is part of a plasmonic structure (e.g., stacked gold layers).

U.S. Provisional Patent Application No. 63/284,541, filed Nov. 30, 2021, and entitled “Multi-Layer Stacks of 2D Materials and/or Other Layers and Related Systems and Methods,” is incorporated herein by reference in its entirety for all purposes.

The following examples are intended to illustrate certain embodiments of the present invention, but do not exemplify the full scope of the invention.

### Example 1

This example describes the fabrication of a variety of multi-layer stacks using an assembly article (also sometimes referred to in this example as a “stamp”) comprising an adhesive region, an article substrate, and a release region between the adhesive region and the article substrate, in accordance with certain embodiments. One aspect of this example relates to a new approach for making multi-layer stacks of materials: Robotic 4D Layer Assembly. This approach can be used to rapidly manufacture designer vdW solids while achieving unprecedented speed, area, patternability, and angle control. In this example, robotics were used to assemble prepatterned layers made from atomically-thin 2DM components. Wafer-scale 2DM films are grown; patterned through a clean, contact-free process; and assembled together with engineered adhesive stamps actuated by a high vacuum robot. This technique led to the fabrication of vdW solids having 80 individual layers, having areas of (100 micrometers)², having pre-designed patterned shapes, laterally/vertically programmed compositions, and controlled interlayer angles. Efficient optical spectroscopic assays of vdW solids were achieved, revealing new excitonic and absorbance layer dependencies in MoS₂. Furthermore, this approach allowed for the fabrication of twisted N-layer assemblies, where atomic reconstruction of twisted 4-layer WS₂ at unexpectedly high interlayer twist angles of ≥4° was observed. The vdW solids manufacturing can allow for rapid construction of atomically-resolved quantum materials and will help realize the full potential of vdW heterostructures as a platform for novel physics and advanced electronic technologies.

Precise three-dimensional spatial control of the composition and structure of inorganic crystalline materials like silicon is the foundation for integrated circuitry. Van der Waals (vdW) solids generated by stacking two-dimensional materials (2DMs) are generally not limited by lattice commensurability and interlayer bonding, providing two key advantages over the conventional production of sequentially deposited crystals. First, lattice and chemical flexibility between adjacent layers means that one can produce arbitrary vertical sequences of crystal compositions with layer-tunable electrical, magnetic, and optoelectronic properties. Second, this interlayer flexibility introduces an additional dimension of θ, the interlayer lattice rotation or twist, as a new degree of freedom for controlling the properties of vdW solids. This has been seen in recent demonstrations of momentum-space crystal engineering and superconductivity of twisted bilayer and trilayer 2DMs. Such advantages are complementary to conventional methods of three-dimensional control via patterning and provide a powerful approach for producing solids whose properties can be systematically and precisely designed. Realizing these characteristics of a designer solid requires accurate placement of many 2DM layers (also referred to in this example and elsewhere as “pixels,” i.e., discrete components, not necessarily square-shaped) onto target positions (x, y, z) with a specified interlayer angular orientation (θ). A method that could achieve this would allow for the production of 3D, monolithically integrated solids with parameters such as layer number (N), chemical composition, and crystalline structure that are programmatically dictated and controlled.

Current 2DM processing techniques provide only partial control (principally z and θ) with limited throughput. Conventional 2DMs vdW heterostructure assembly generally relies on the irregularly shaped mono- and multilayers isolated through micro-mechanical exfoliation. While exfoliated materials maintain remarkable quality, their inherent stochastic distribution and small area do not permit the facile production of integrated solids. Emerging wafer-scale growth through chemical vapor deposition (CVD), metal-organic chemical vapor deposition (MOCVD), controlled recrystallization, and solution-based techniques have brought the field closer to vdW solid manufacturing, with electronic properties in the best cases rivaling those of exfoliated materials.

In this example, a versatile high throughput approach for producing designer vdW solids with full, four-dimensional control of x-y-z-θ, as illustrated in FIG. 6B, was employed. For this, the following are combined: (i) wafer-scale synthesis of various 2DMs with two further technical advances: (ii) a contact-free patterning technique to mass produce layer building blocks from wafer-scale synthesized 2DMs and (iii) a high throughput, operator-free Robotic 4D Layer Assembly manufacturing system to assemble these layers under high vacuum. During the assembly step, multiple layers, each pre-designed with a shape, are chosen and stacked with a precise spatial resolution (x-y), atomic scale layer control (z and N), and angle resolution (θ).

The versatility of this method can allow for the design and production of a variety of integrated vdW homo- and hetero-structures. FIG. 6B(iii) illustrates four example structures: a multilayer vdW solid with a large N, an alternating (ABAB . . . ) heterostructure with varying layer sizes, an offset heterostructure with laterally displaced layers, and an angle controlled spiral stack. These structures were successfully produced using the Robotic 4D Layer Assembly described herein, as shown in FIG. 6C, which displays the optical micrographs (from left to right) of a 25-layer stacked WS₂, an alternating 7-layer MoS₂/WS₂ superlattice with shrinking WS₂ layers, an offset MoS₂/WSe₂ heterostructure with three smaller WSe₂ layers diagonally aligned, and a 4-layer WS₂ “spiral staircase” with a constant interlayer θ=12.5°. This deterministic and consistent technique allowed for manufacture of these structures at rates on the order of 30 layers/hour (Table 1), significantly faster than the state-of-the-art for exfoliated materials.

TABLE 1
Calculated time required for stacking
using typical operation parameters.

| Action Performed | Time Required | |
|---|---|---|
| Sample/stamp exchange* | 5 | minutes |
| Vacuum pump down, Alignment* | 5 | minutes |
| Each pick up cycle | 1 | minute/layer |
| Navigation to pick up location | 5-20 | seconds |
| Approach stamp to surface | 10 | seconds |
| Hold in contact | 45 | seconds |
| Lift | About 50 milliseconds | |
| Stack deposition to final substrate* | 5-10 | minutes |

*One-time operation per stack
Example: 16L stack requires total of 5 + 5 + 16*1 + 5 minutes = 31 minutes

At the same time, this technique preserves the quality of the starting material, as demonstrated by the narrow linewidths observed in cryogenic photoluminescence of exfoliated samples (FIGS. 10A-10C). Presented herein is an explanation of these methods in more detail and a presentation of two applications realized using designer vdW solids generated using polycrystalline monolayers (FIGS. 6A-8H) and single crystalline monolayers (FIGS. 9A-9C).

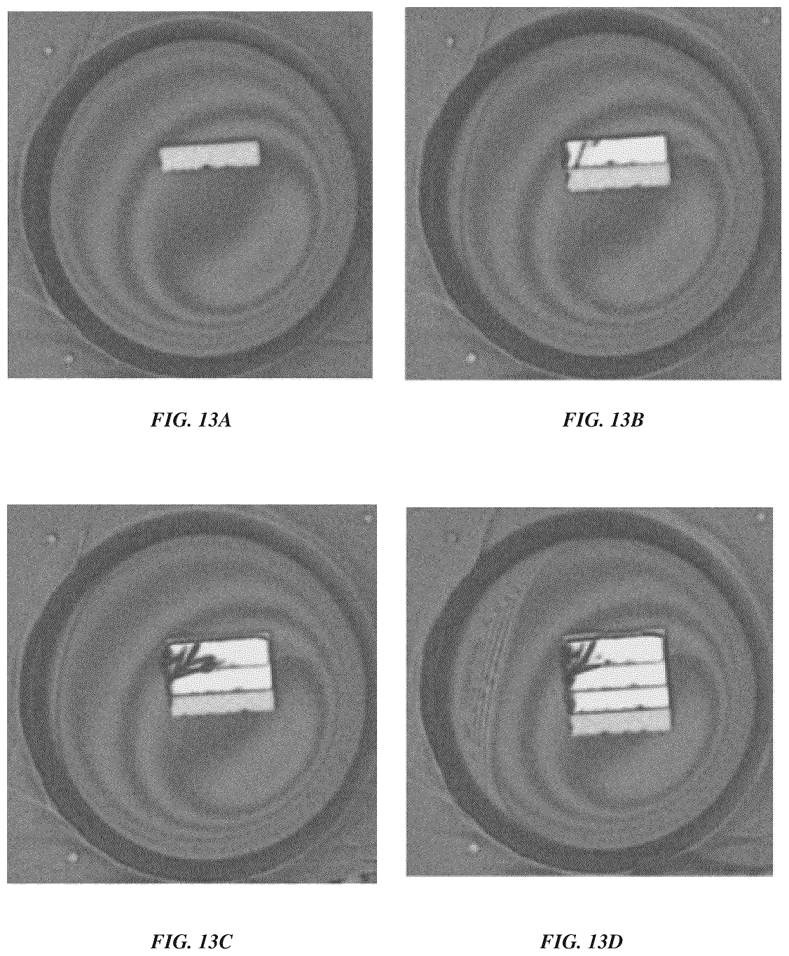

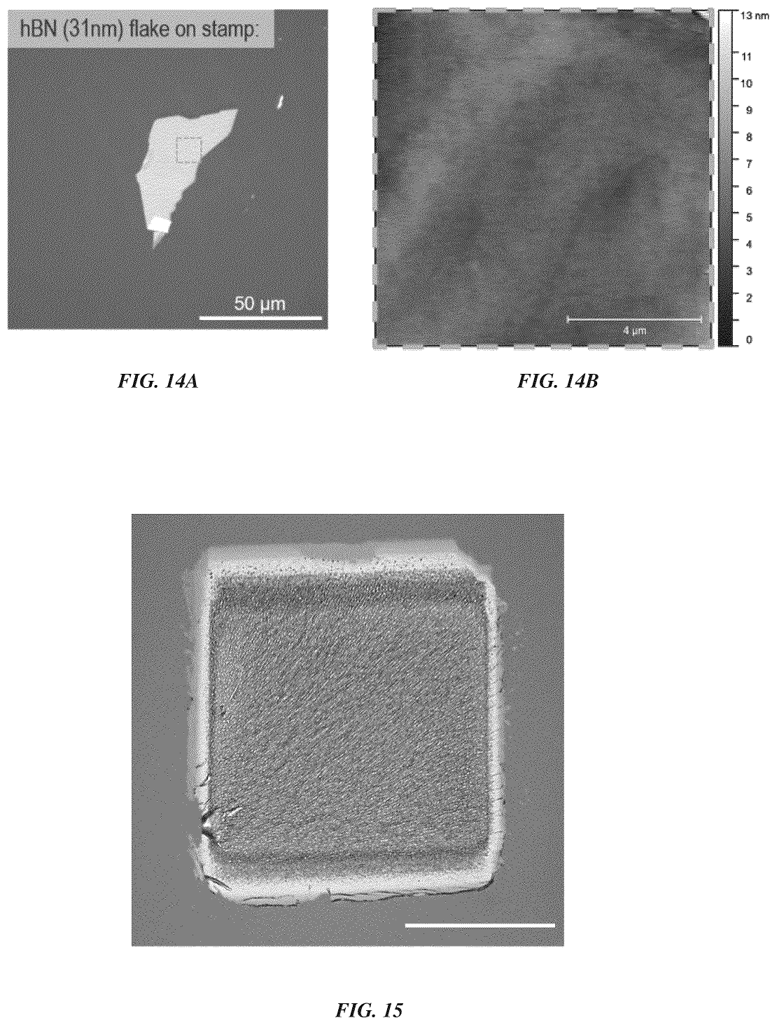

One component of the Robotic 4D Layer Assembly process presented herein is the vacuum assembly robot (VAR, FIG. 7A, FIG. 11). It comprises a heated x-y translation stage that holds multiple ˜1 cm² chips of source material or receiving substrates, and a separate z-θ actuated stacking platform which moves a microstructured polymer stamp (FIG. 7B) for picking up 2DMs to form the stack. The VAR is housed within a desktop-size high vacuum chamber (P_{base}˜10⁻⁶ Torr) to reduce surface contamination, prevent material oxidation, and promote high quality interfaces during assembly. An external optical microscope and digital camera aimed through the top viewport provides lateral alignment and process monitoring, including the detection of stamp/substrate contact to prevent excessive force (FIGS. 12A-12C). The manufacturing process in the VAR (FIG. 7C) comprises two sequential phases:
(i) During assembly, the VAR loops through a process cycle of (1) navigating the stamp to the selected layer for pick-up, (2) placing the stamp into contact, and (3) lifting to pick up the target layer, which is now added to the stacked vdW solid. This process repeats to add additional layers to the stack on the stamp.
(ii) The terminal deposition step involves (1) navigating the stamp to a desired location on the target substrate, (2) contacting the target point with applied release stimulus, typically heat, and (3) releasing the assembled vdW solid by slowly lifting the z-stage.
   A multilayer polymer stamp (FIG. 7B) plays an important role during these two phases. It is designed to exhibit advantageous mechanical properties and thermally-switched adhesion determined by the glass transition temperature, thermolytic release layer decomposition, and viscoelastic relaxation. Details of the VAR assembly process, operational parameters, and stamp fabrication are given in the Methods and Supplementary Discussion, provided below. The VAR assembly works for TMDs, Au thin films (FIGS. 13A-13D), exfoliated flakes of graphite, hBN (FIGS. 14A-14B), and WSe₂ (FIGS. 10A-10C), and is expected to apply to a large variety of materials compatible with vdW stacking. Furthermore, the VAR can be used to produce high quality vdW heterostructures from exfoliated flakes, such as hBN-encapsulated WSe₂, which shows narrow linewidth cryogenic photoluminescence spectra similar to those from manually stacked samples (FIGS. 10A-10C).

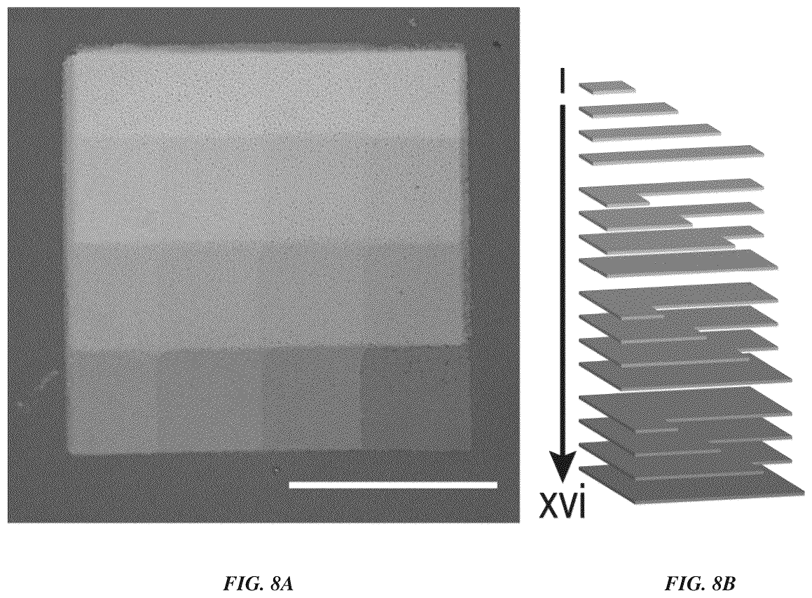

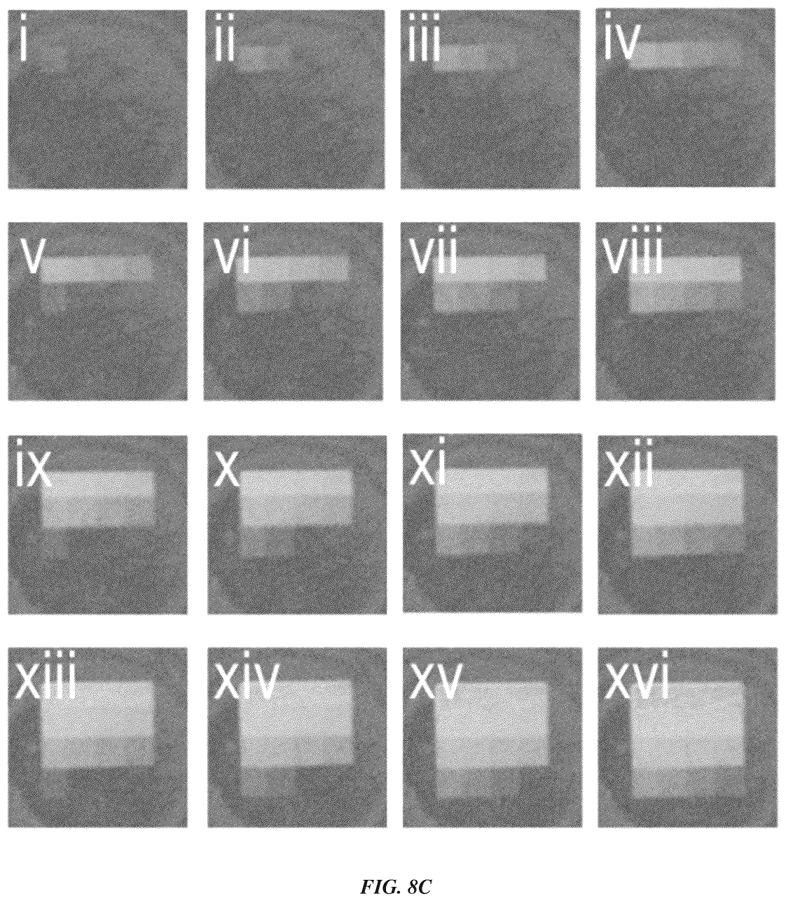

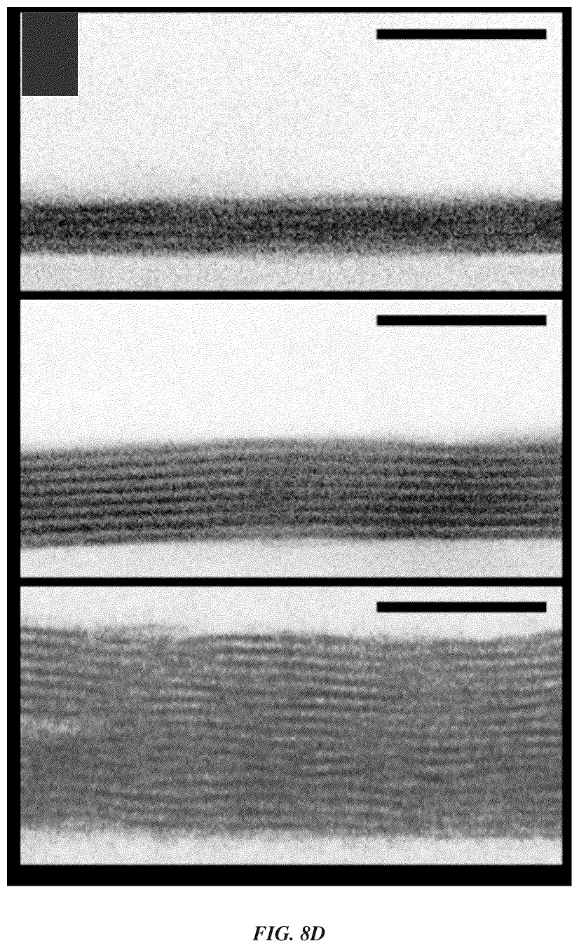

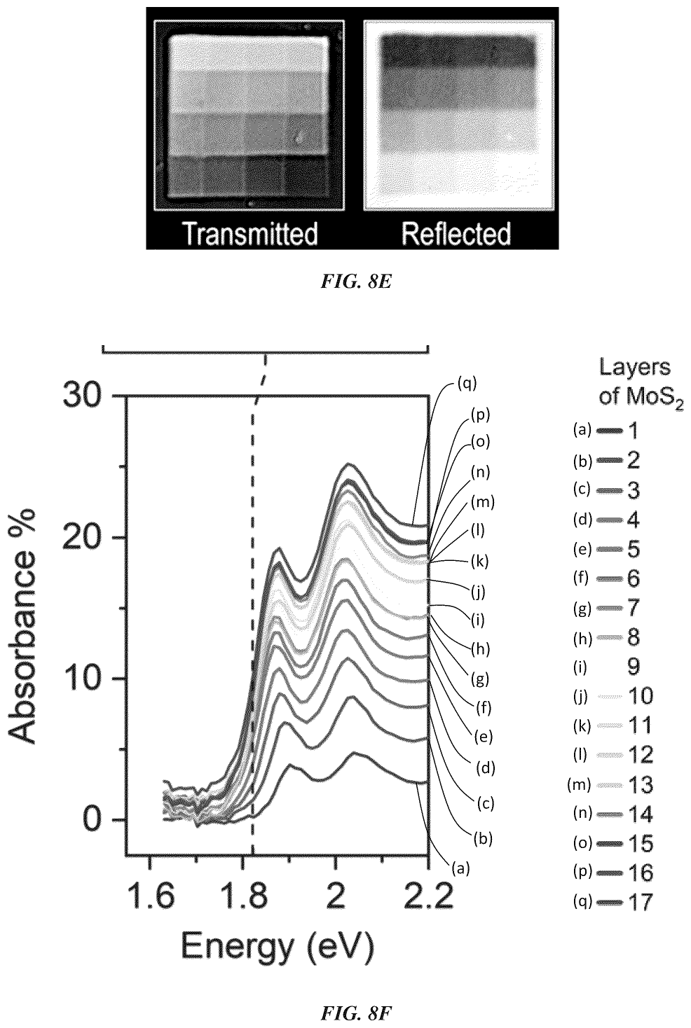

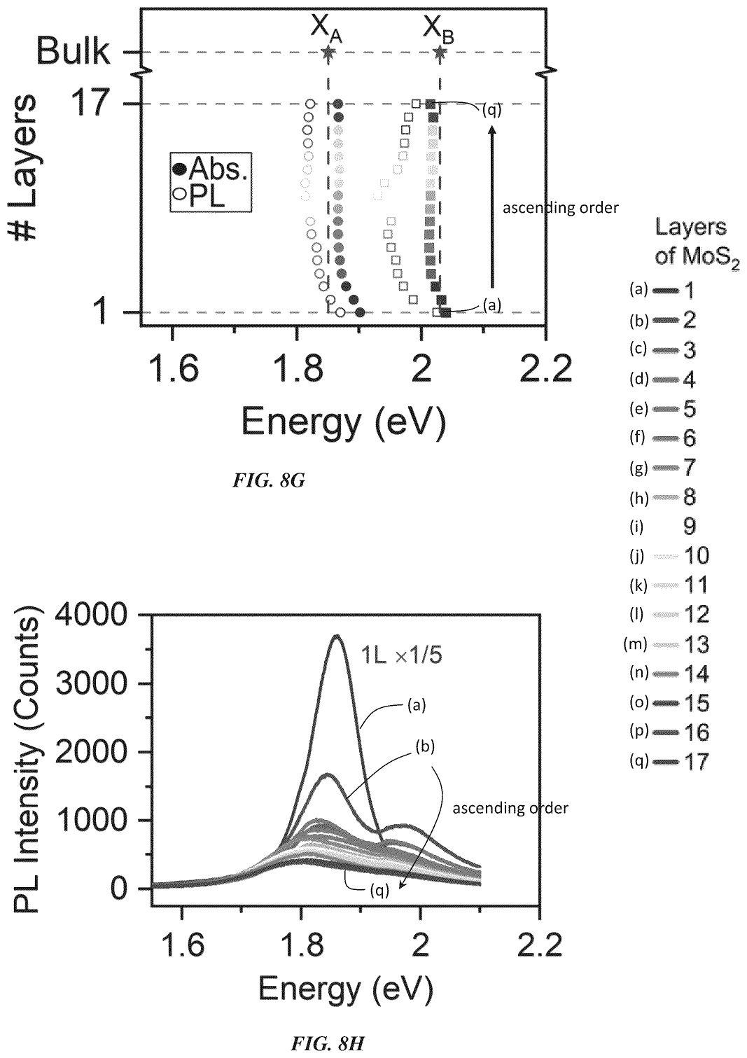

This manufacturing process is computer controlled and the full process, from pick-up of the first layer to transfer of the completed vdW solid, can be fully automated to take advantage of wafer-scale synthetic monolayers. Examples of an automated recipe-driven process are shown in FIG. 8C. One immediate advantage of automation is its high throughput. This is highlighted by the operator-free fabrication of the 80 layer MoS₂ (FIG. 15).

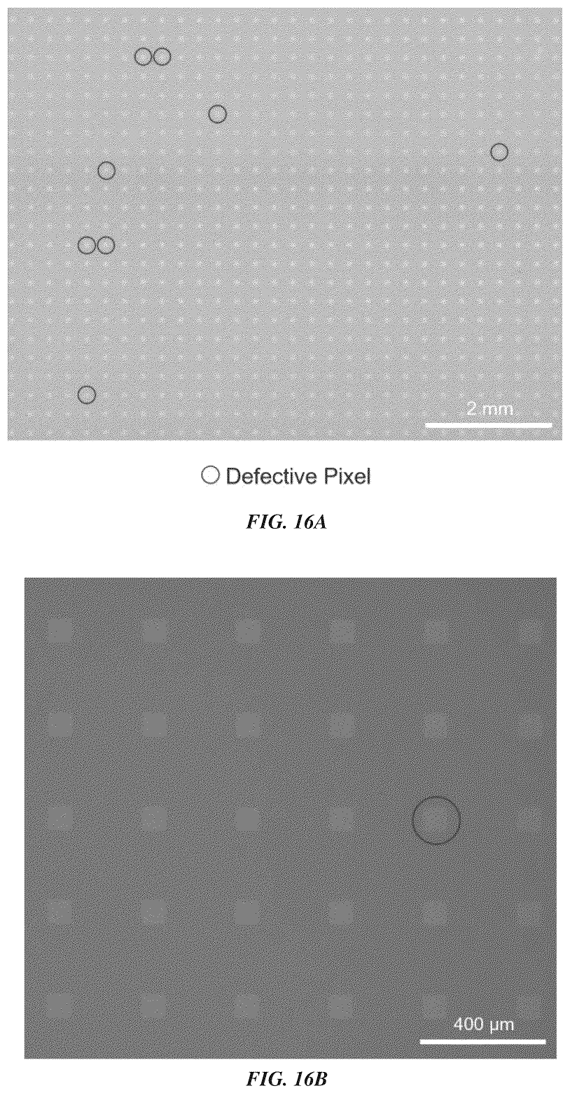

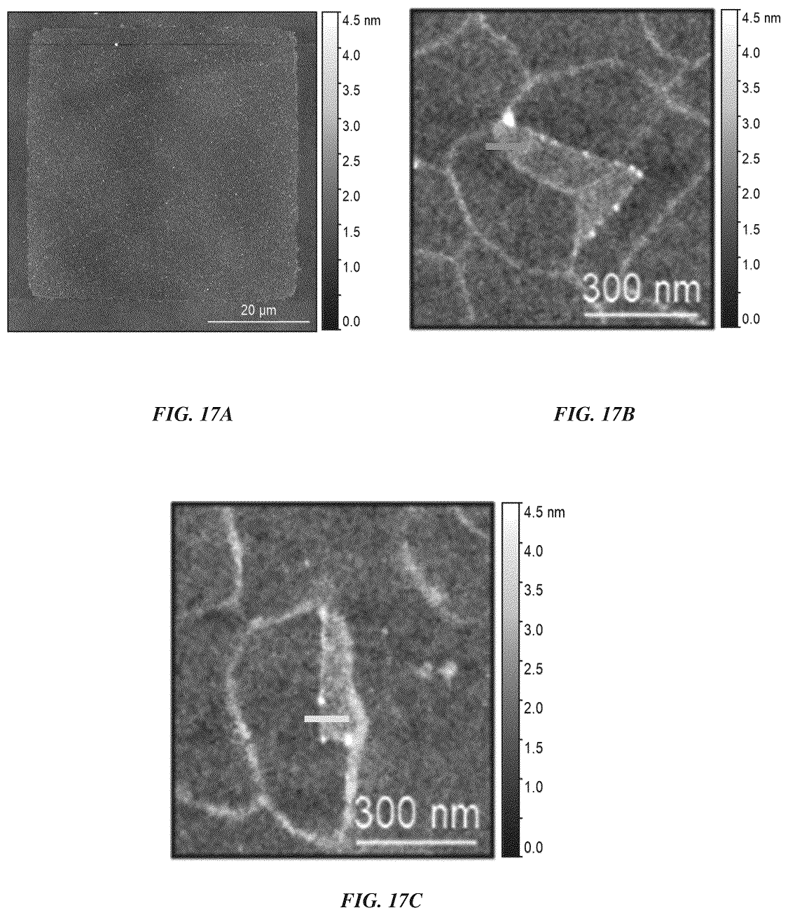

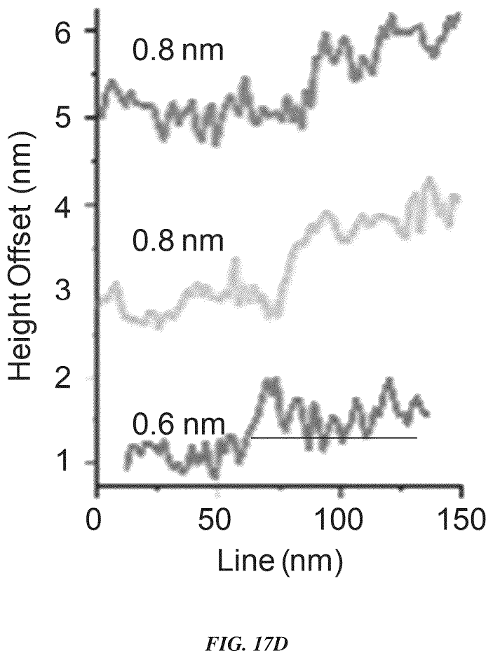

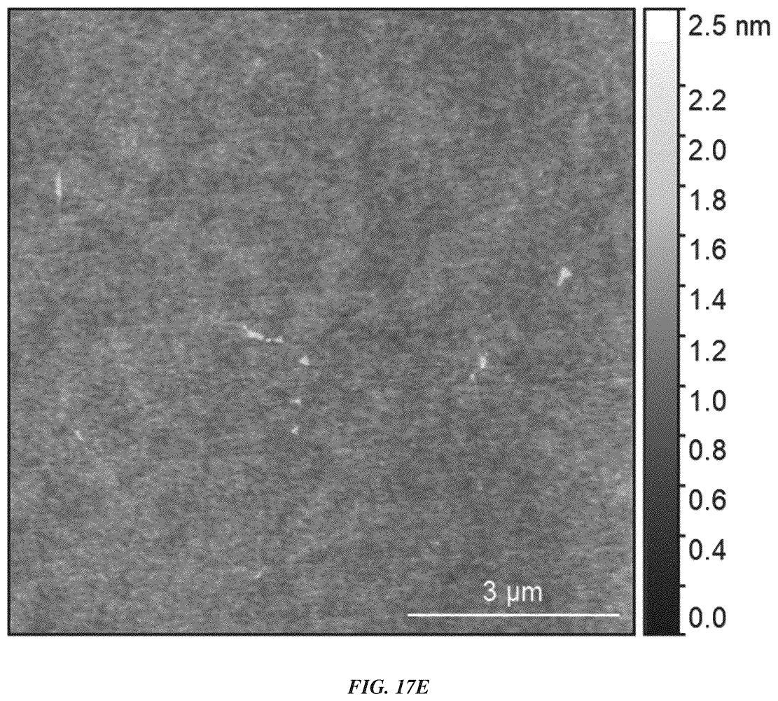

The other key technical advance is the fabrication of patterned 2DM building blocks (FIG. 6B(ii)) through a clean, non-perturbative lithographic technique. Conventional photo- or electron beam lithography processes involve contact with polymers, chemical developers, and solvents, which contaminate vdW interfaces. Instead, template-strip lithography (TSL) was used, an adhesion-based, dry patterning technique for 2DMs (schematic shown in FIG. 7D) that prevents deposition of surface residues by not touching the layer region with the patterning medium. It uses a microstructured template with patterned adhesion regions produced via standard cleanroom lithography; these adhesion regions stick to the 2DM areas, which are then cleaved and stripped away when the template is lifted from the surface leaving the non-contacted 2DM regions behind to generate patterned arrays of 2D layers. Optical images of an example array made from monolayer WS₂ are shown in FIG. 7E, and an MoS₂ array as FIGS. 16A-16B, which show a high yield of 99%. AFM and optical microscopy are used to confirm clean surfaces with no polymer residues after patterning (FIGS. 16A-16B and FIGS. 17A-17E).

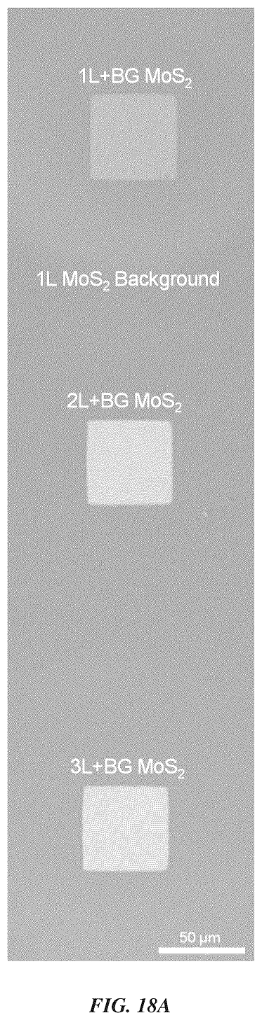

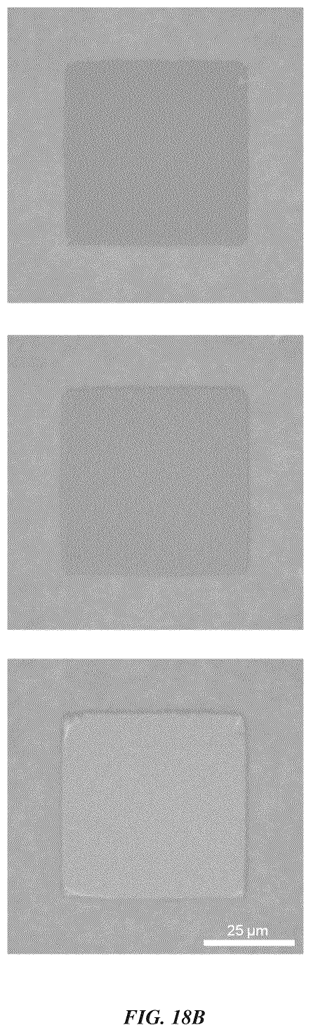

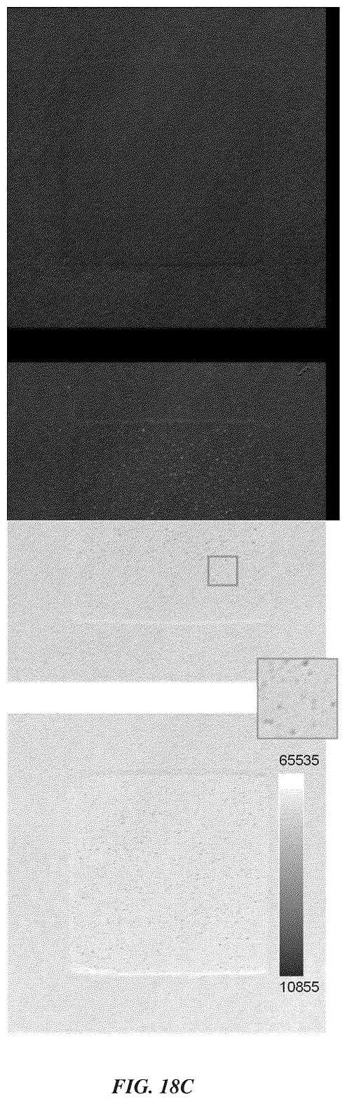

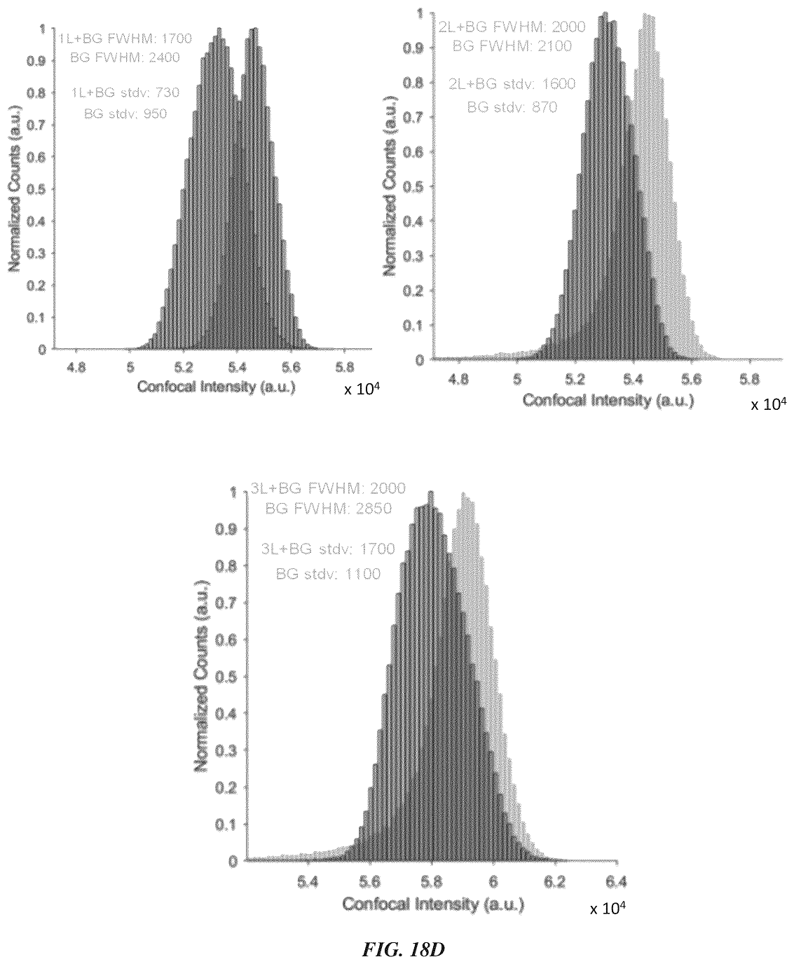

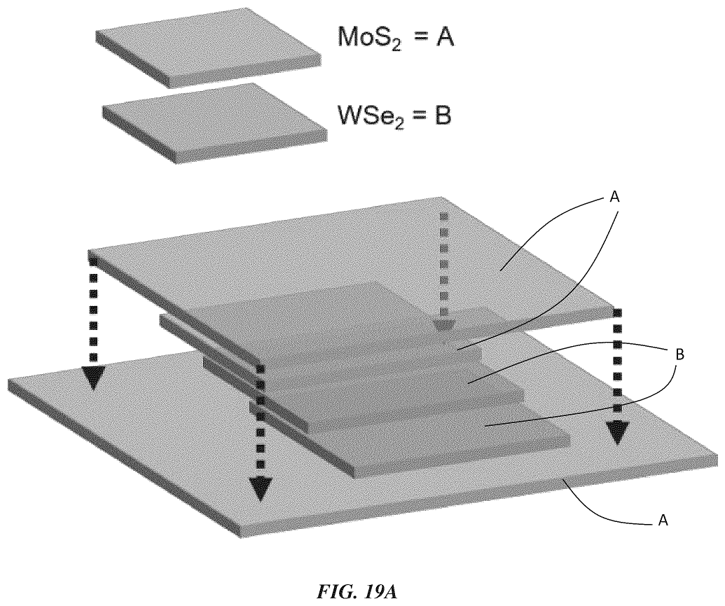

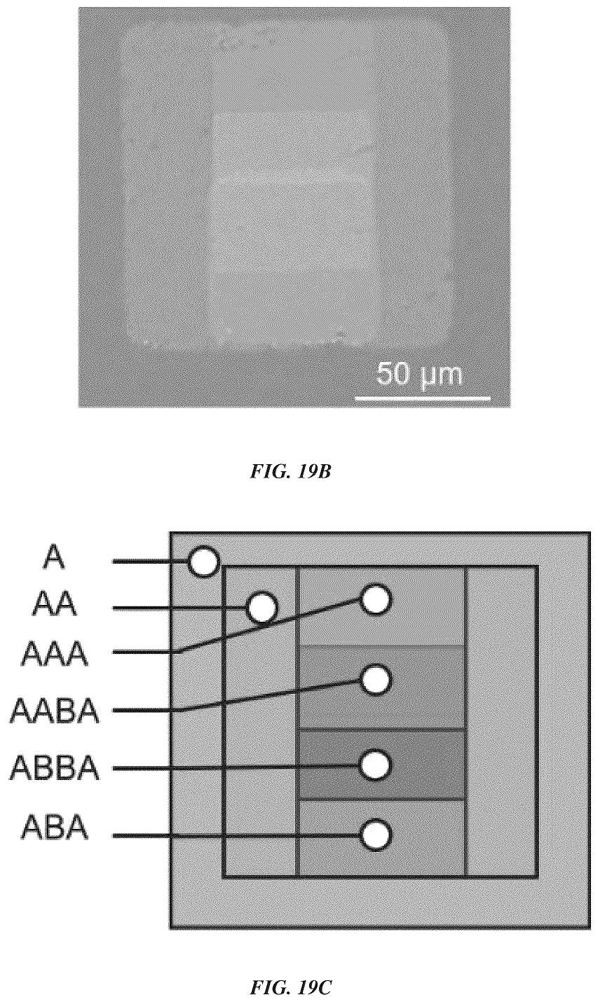

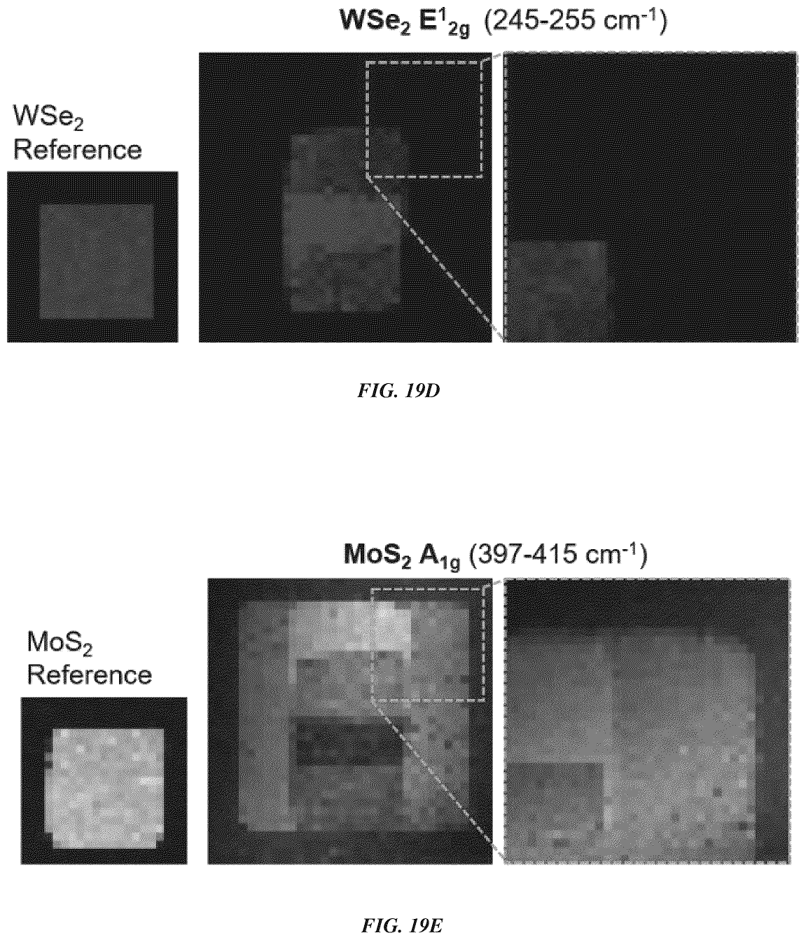

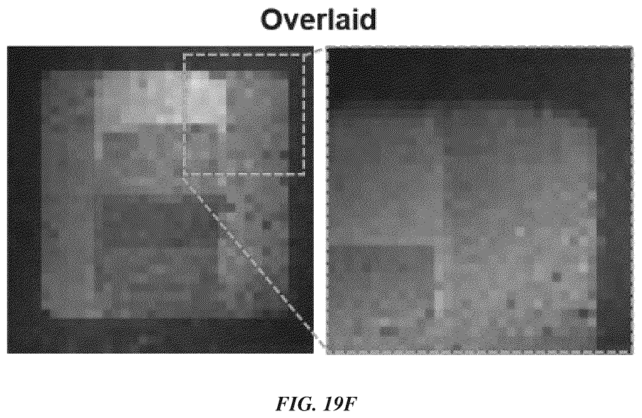

The precise grid spacing within each patterned chip facilitates the calculation of the spatial coordinates of every layer (FIG. 7E and FIGS. 16A-16B). It is therefore no longer necessary to individually search, locate, catalog, and characterize the thickness of stochastically exfoliated materials; the structure of the incorporated layers can be pre-designed. With this deterministic material source as input, the VAR software can interpret scripted recipes of coordinates and stacking conditions to sequentially pick up layers and manufacture a programmed vdW solid. This differentiates the Robotic 4D Layer Assembly process described herein from conventional exfoliated 2DM stacking. Spatially resolved measurements including laser confocal microscopy (FIGS. 18A-18D) and Raman spectroscopic mapping (FIGS. 19A-19F) confirm the uniformity of the assembled samples. Two such experiments were designed, conducted and realized using custom-produced vdW solids: comprehensive optical assay of N-layer stacked MoS₂ (FIGS. 8A-8H) and structural characterization of angle-controlled 4-layer WS₂ (FIGS. 9A-9C).

FIGS. 8A-8H show the first example—a MoS₂ solid (100 by 100 micrometers) that consists of 16 square regions, each with a different N ranging from 1 to 16 (see optical image, FIG. 8A). This 16-tile configuration is specifically designed for one-shot characterization of the N-dependent evolution of the properties of polycrystalline 2DMs, where every interlayer interface has random interlayer rotation. Such information cannot be easily obtained from other samples such as randomly sized exfoliated flakes or multiple samples with statistical thickness fluctuations produced via thin-film growth. This structure is a stack of 16 Tetris-like layers (FIG. 8B), and each layer is specifically patterned and assembled layer-by-layer (see FIG. 8C for the images during assembly) according to the overall design of the solid. The 16-tile solid in this case was deposited onto a uniform MoS₂ substrate layer to yield 1-17 layers (where monolayer properties can be probed outside the tiled region). The high quality of interlayer interfaces was confirmed by cross-sectional scanning transmission electron microscopy (STEM) images (FIG. 8D) taken from different regions (thus different N's) of another similarly produced sample.

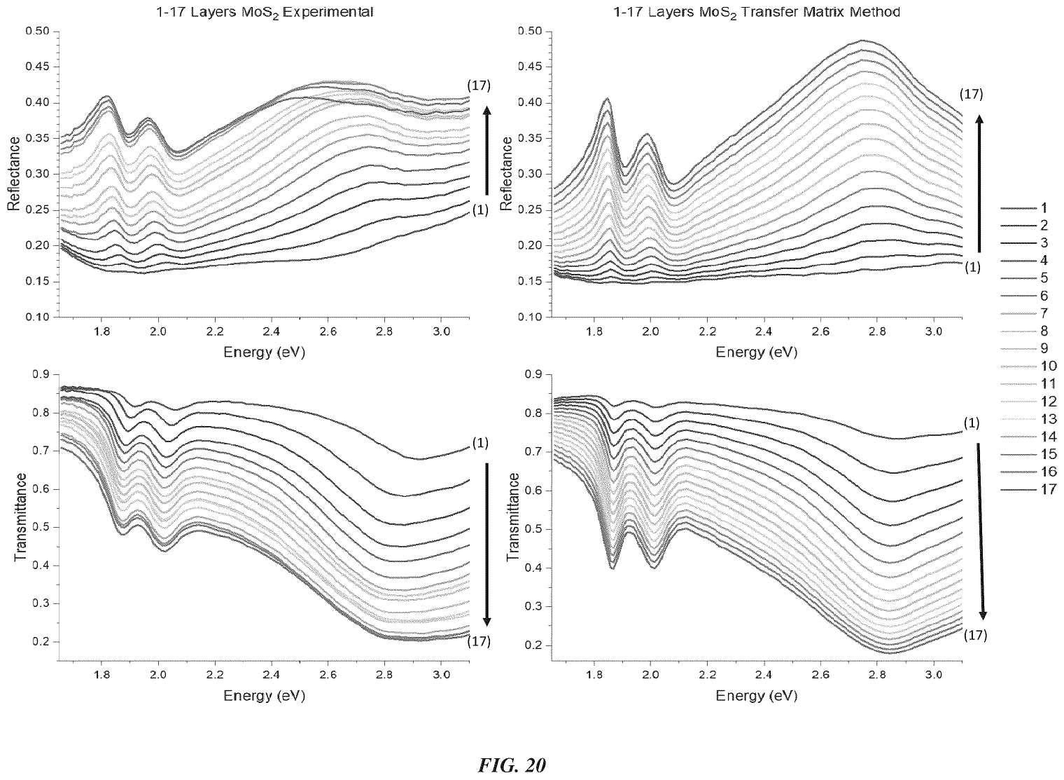

Using hyperspectral microscopy, the transmission (T) and reflection (R) images of this solid were measured at different wavelengths (after the sample was transferred to a sapphire substrate). Example images (=680 nm) are shown in FIG. 8E, which shows uniform contrast in each tile region. By comparing these images with substrate and mirror reference images, the reflection (R (λ, N)) and absorption (A (λ, N)=1−T−R) spectra of the 16-tile optical-assay were measured, each averaged over one tile region. The resulting absorption spectra for N=1-17 are shown in FIG. 8F and display a layer-dependent evolution of the peak positions and magnitude. First, despite the random interlayer orientations present in the samples, these spectra show two clearly resolved absorption peaks near the A- and B-exciton energies. The fitted peak positions (FIG. 8G) for smaller N are close to the values previously observed in mono- and bilayer-MoS₂, and they then decrease and converge near the values of bulk 2H-MoS₂. This suggests that the intralayer direct-gap K-K (or K′-K′) transition, which is insensitive to interlayer rotations, remains dominant in the stacked MoS₂ solid. Second, this also suggests that the magnitude of R (λ, N) and A (λ, N) of stacked MoS₂ can be understood for different N using a simple model without explicitly considering the interlayer rotation angles. It was found that this is indeed the case: the absorption spectra in FIG. 8F can be closely matched for all N using a simple transfer matrix method (TMM) calculation based on monolayer optical constants as the building blocks (FIG. 20). Such insensitivity of R and A to the interlayer rotations has practical implications, as it allows for modeling stacked MoS₂ films as a single material for photonic applications. Another finding is that the reflectance R converges to the 3D-bulk-crystal limit quickly for thin MoS₂ films: even at N=17 (thickness˜10 nm), the stacked film reflects approximately ˜40% of incoming light on average (FIG. 20), close to the reflectivity of bulk MoS₂.

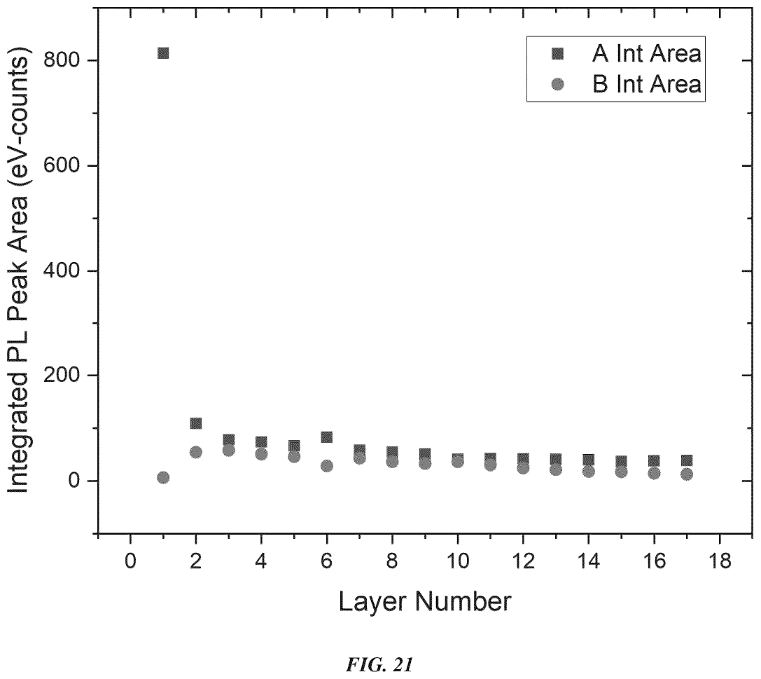

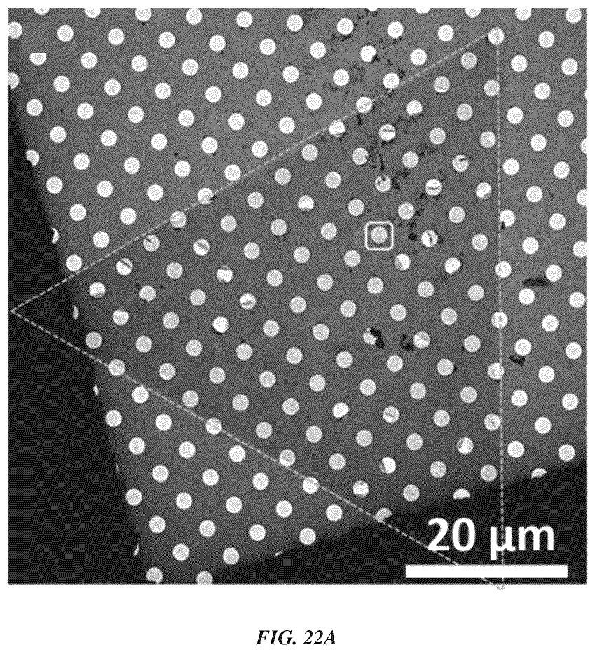

Photoluminescence (PL) taken from the 16-tile optical-assay (FIGS. 8F-8H) also shows N-dependent evolution. There is an 87% decrease in the integrated intensity of the main A-exciton peak from 1L to 2L (FIG. 21), which is comparable to other stacked bilayer samples and explained by direct-to-indirect gap transition. However, when compared to natural 2H-MoS₂ at thicknesses greater than 2L, this assay shows less PL quenching with increasing N and a broadening of the direct A-exciton transition peak. Both observations may result from the modified interlayer hybridization present in the rotationally misaligned layers and multiple domains contributing to the observed signal. Finally, one N-dependent effect was observed in all the measured spectra (R, A, and PL). As N is increased from 1 to ˜5, gradual red-shifts of both A- and B-exciton peaks are observed, which occurs due to enhanced screening.

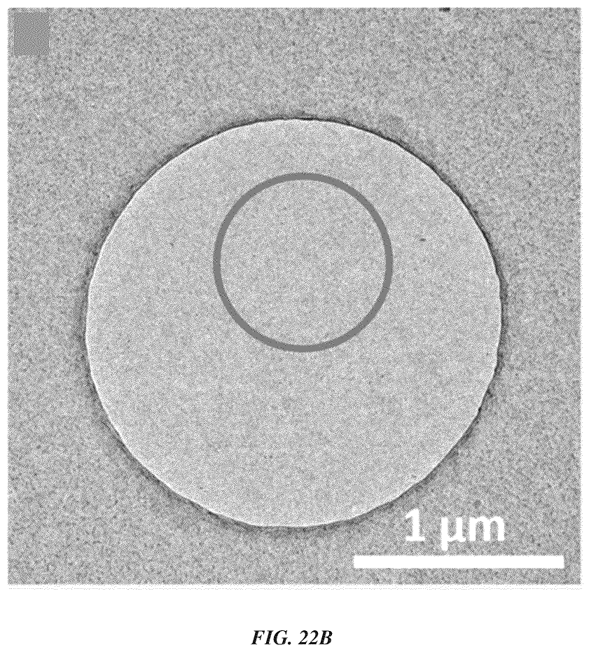

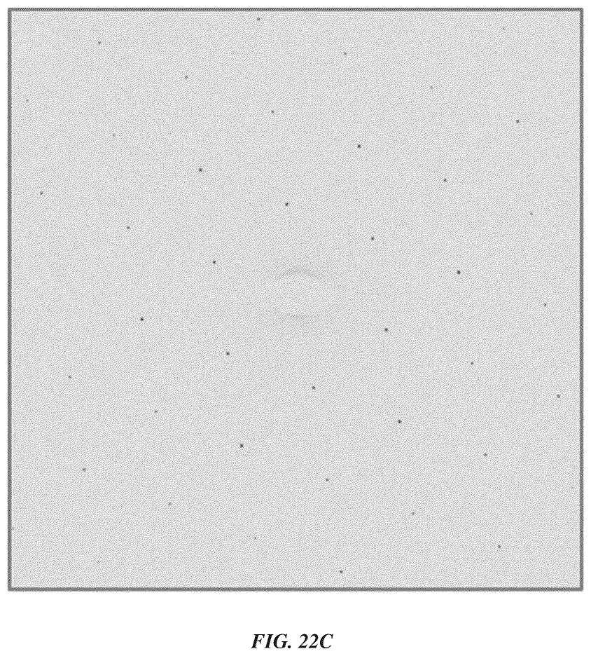

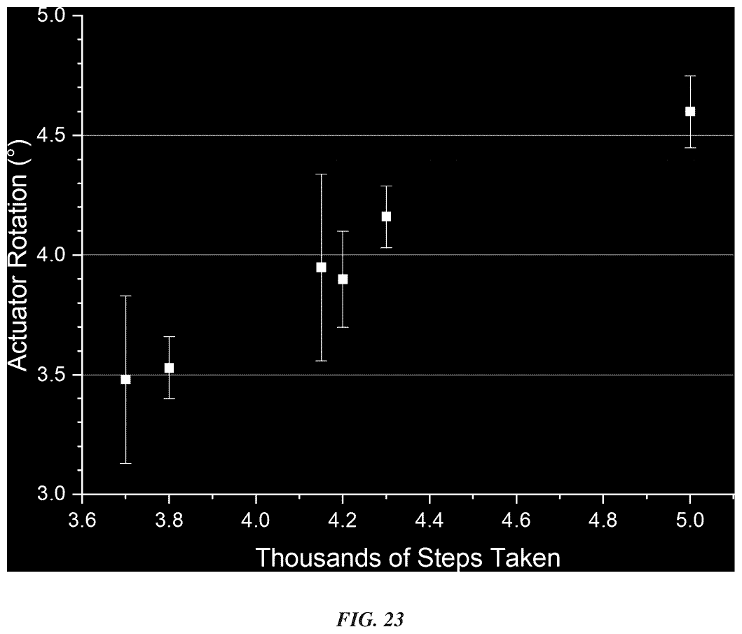

FIGS. 9A-9C present a second demonstration—a multilayer WS₂ solid with precise interlayer rotations. It showcases the angle control of the robotic stacking system. This is an important new capability for designing 2DM-based solids with strongly correlated electronic and excitonic states. FIG. 9A shows selected area electron diffraction (SAED) for a 4-layer WS₂ sample, obtained by the nanomanufacturing technique described herein using large (˜100 micrometers) single-crystal WS₂ grown via MOCVD (inset) as the source. The single crystallinity of this source material is discussed further in FIGS. 22A-22C. Different regions of the triangle were picked up using stamps, piece-by-piece, with interlayer rotation applied between each layer. This allowed for generation of multilayer twisted heterostructures, with every interlayer rotation angle controlled. This method can be generally applied to form more complex stacks using larger single-crystalline or lattice oriented 2DM sources.

The diffraction pattern in FIG. 9A clearly shows 4 sets of primary Bragg peaks, each rotated slightly from the neighboring ones. All three interlayer twist angles (θ₁₂, θ₂₃, θ₃₄) are close to 4.2° (mean of 4.2°±0.2) with θ₁₂ being larger than the other two. The precision of the rotation angle realized in the stack is currently limited by the open-loop mechanical resolution of the angle actuator (±0.2°, FIG. 23), although there could be additional contributions from unintentional movement of each 2DM piece induced during and after the pick-up and small orientation variation within the single crystal source materials.

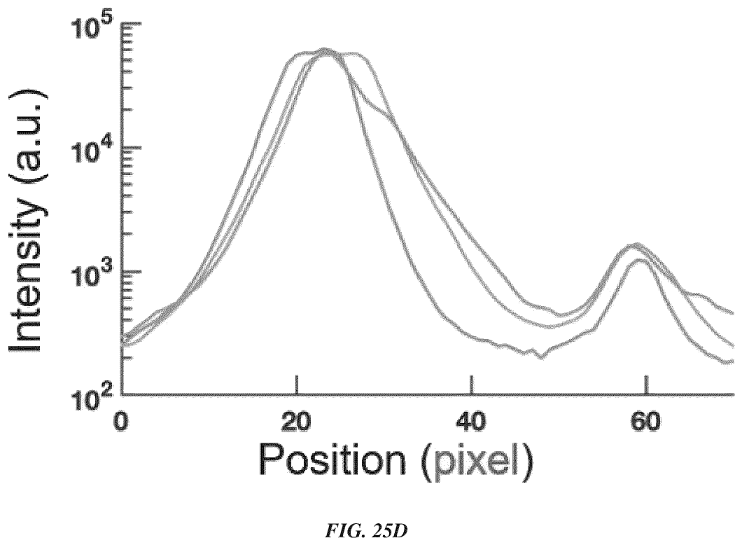

Surprisingly, strong satellite peaks beyond the primary Bragg peaks were observed, as shown by the magnified images (FIG. 9B (i-iii)). FIG. 9C further shows a dark-field TEM image obtained by selecting the 2^{nd} order Bragg peaks and surrounding satellites (from FIG. 9(i)). Larger “fishnet” domains separated by dark boundaries are clearly visible in these images, with their spatial period (of the order of 10 nm) corresponding to the moiré wavelength for θ≈4°. Multi-slice simulation of a rigid 4-layer WS₂ 4.2° rotated structure (FIG. 24) indicates that satellite peaks arising from multiple-scattering would have a nearly undetectable signal. Accordingly, it is believed that the apparent satellite peaks in FIGS. 9A-9B must be evidence of atomic reconstruction. The measured ratio between main Bragg peak to primary satellite peak was 1-2% (FIGS. 25A-25D), nearly twice of what would be expected from rigid lattice multiple scattering. In FIG. 9C, the superimposed striped pattern was also observed. This corresponds to the moiré wavelength of the outer two layers, 3θ≈12°. Together, the fishnet and striping domains indicate that it is likely that the inner two layers are restructuring. However, it is yet unclear whether the reconstruction occurs solely from the interactions between the interior two layers, or whether there are cooperative multilayer interactions.

The observed lattice restructuring at θ≈4.2° was unexpected. It is believed that the lattice reconstruction was driven by a reduction in interfacial energy, which is proportional to the size of the reconstructed domain. As the domain size is inversely proportional to twist angle, reconstruction due to interlayer interactions was previously observed at smaller twist angles (e.g., up to ˜3° for graphene, ˜2° for TMDCs). However, modified interlayer mechanical coupling and strongly correlated states have been observed at twist angles up to ˜5° in bilayer TMDCs, underscoring the importance of understanding atomic reconstruction in these materials. Moreover, atomic-scale engineered chirality applied to 2D semiconductors may potentially allow for efficient photonic and quantum information processing by enhancing the coupling between light helicity and valley polarization or enhanced non-linear optical phenomena.

Robotic 4D Layer Assembly presents a new method for manufacturing precise vdW solids, highlighted by the two demonstrations of one-shot optical assays and twisted multilayer stacking presented herein. Lateral and angular resolution of the VAR could be even further improved by using higher specification closed-loop actuators. The lateral size of the assembled area can be increased by developing a larger stamp that can make contact with optimal and uniform force (FIGS. 27A-27C). Strain formation, especially at high layer counts, could be reduced by minimizing unconstrained thermomechanical stresses on the 2D-polymer interface (See Supplementary Discussion, below).

The large sample size and predominantly monolayer source material used here are challenging compared to the common practice of using a thicker flake of hBN as the top layer, which acts as a mechanical buffer layer and decouples the heterostructure from slight mechanical deformation imparted by the polymeric stamp. Contrasting with existing fabrication methods based on exfoliated materials (where each device is unique), the manufacturing process presented herein could allow for the efficient assembly of identical structures on the same chip. When combined with the growth of large single crystals of 2DMs, this assembly technique could allow for high-throughput investigation of engineered electronic states in more complex, multilayer twisted heterostructures. This also establishes an avenue for harnessing twisted structures in technological applications. Moreover, beyond wafer-scale synthesized TMDs, the processes of large area material synthesis, precise patterning, and automated assembly should generalize to other categories of delaminable materials, such as thin film electrodes, 2D complex oxides or molecular monolayers.

### Supplementary Discussion

### Vacuum Assembly Robot Details

An emphasized photograph of the VAR is shown in FIG. 11. Viewports on the top and front faces allow for the observation of the inside stage. The right side of FIG. 11 shows a schematic of the internal setup. Going from the bottom up, there is the x-y stage, resistive/thermo-electric heaters, and patterned chip of material. The z-θ stage is above that, which holds the polymer stamps. The camera through the top viewport allows for in situ observation of stamping procedure. The optical microscope uses Navitar zoom lenses selected for long working distance to accommodate the chamber geometry, with a nominal resolution of 4.4 micrometers, although optimized optical path design could achieve superior diffraction-limited resolution.

When the stamps make contact with a substrate, the stamp-vacuum-monolayer-substrate optical path becomes stamp-monolayer-substrate, resulting in a significant color change (FIGS. 12A-12C). The VAR uses an image processing algorithm in real-time during the stamp approach to detect the color change in the stamp contact patch. When the color changes significantly, the VAR algorithm considers the stamp to be in contact, and the z stage is halted to avoid excess compression of the stamp against the substrate. Different substrates and different oxide thicknesses will alter the parameters necessary for the color detection algorithm to trigger, so test stamps were done beforehand to determine substrate-specific conditions. After a layer is successfully picked up, the color of the monolayer visibly changes, as it is now on the bottom surface of the stamp.

Different polymer-solvent mixtures used in stamp design are not universally compatible with each other as they exhibit different levels of wettability with previous layers. For example, earlier iterations on stamp polymer selection (e.g., Anisole on PCPCpag and PBzMA, and ethyl lactate on MMA) resulted in poor spin coating uniformity due to incompatibility of solvents in subsequent polymers. The current stamp iteration (cyclohexanone on LOR10B, and anisole on PCPCpag and PBzMA) achieved compatibility between polymer layers. The stamp composition was found to be resilient to significant assembly cycling: the 80 layer MoS² structure (FIG. 15) demonstrates the stamps can survive contacting and lifting 80 times. Additionally, thin layers of gold (FIGS. 13A-13D) and exfoliated hBN flakes (FIGS. 14A-14B) can be picked up.

Heterostructure Assembly and Benchmarking with Exfoliated Materials

As a further demonstration of the versatility of the VAR, high quality van der Waals heterostructures consisting of monolayer tungsten diselenide (WSe₂) encapsulated with hexagonal boron nitride (hBN) were fabricated (FIGS. 10A-10C). Thin hBN flakes and WSe₂ monolayers were manually exfoliated from commercially available bulk crystals. After identifying appropriate WSe₂ monolayers with AFM (FIG. 10B), hBN encapsulation was performed by the VAR (FIG. 10A). The optical quality of the VAR-assembled samples was characterized at low temperature (7 K) through photoluminescence (PL) and reflectivity measurements. A representative PL spectrum with well-resolved excitonic features is displayed in FIG. 10C. In addition to exhibiting prominent neutral exciton (X⁰) and charged biexciton (XX⁻) peaks, the PL captures the negative trion (X⁻) fine structure. Additionally, the X⁰ peak shows a Lorentzian linewidth of 5.5 meV (FIG. 10C, left inset), near the reported homogeneous value. More directly, the VAR-assembled sample was compared with a WSe₂ heterostructure fabricated by a conventional manual transfer method with monolayers exfoliated from the same batch of bulk crystal. The PL spectra were in good agreement. Moreover, the strong neutral exciton resonance was observed in differential reflectivity measurements. Together, these results confirm the high optical quality of the VAR-assembled samples, establishing the VAR as a general platform suitable for designing van der Waals heterostructures.

### Template Strip Lithography Patterning Quality

AFM images of the patterned monolayer material are provided in FIG. 17A. In the AFM topographs, it can be seen that the substrate surface remains clean and flat after TSL patterning. It was observed that rough or dirty substrates reduced the efficacy of stamp-monolayer adhesion, even if most of the stamp did not make significant contact with the bare substrate. An image of an entire patterned chip is shown in FIGS. 16A-16B. A yield of 99% was observed in this sample. Defective layers are the result of aberrations in patterning or particulate debris on top, or adjacent to otherwise functional layers.

### Further Characterization of the 16-Tile MoS₂ Structure

Experimental transmittance and reflectance are shown alongside the extrapolated transfer matrix method calculations in FIG. 20. The extrapolated values match with the experimental results in the A and B exciton range; at higher energy, a slight deviation in the reflectance data was seen, which could be related to the minor chromatic aberration at shorter wavelengths (between 400-450 nm) on the reflection side of the hyperspectral microscope setup. FIG. 21 shows the integrated area of the averaged PL for each thickness of MoS₂. An 87% decrease was seen in PL going from the monolayer to the bilayer. Subsequent layers show a very slow decay in integrated PL area compared to single crystal 2H-MoS₂, in this case, linear rather than exponential decay.

Atomic Reconstruction in Twisted 4L WS₂ The rotation angle between the layers in the twisted 4L WS₂ structure (i.e., 4.2°/4L/WS₂, with 4.2° indicating the interlayer twist between each pair of layers), was limited by the rotation actuator mounted on the z stage (FIG. 23). However, even with the ˜0.2° spread in actuator precision, distinct satellite peaks could be observed at the clusters of the first, second, and third order Bragg peaks in the SAED pattern. The orientations of these satellite peaks in momentum space with respect to the main Bragg peaks agree with what is expected from literature (where the first set of satellite peaks are 600 rotated from the vector connecting adjacent Bragg peaks, the second set of satellite peaks are 300 rotated, and the third set of satellite peaks are collinear).

The presence of satellite peaks in the Bragg clusters is evidence of higher order periodicity that arises from a twisted-angle moiré pattern. The satellite peaks are located exactly at the moiré lattice vectors. Additionally, the satellite peak intensities are stronger surrounding the around higher order Bragg peaks, which is a signature of periodic lattice distortion distinct from multiple scattering or chemical ordering. In general, satellite peaks could occur without atomic reconstruction from multiple scattering in a rigid lattice. However, the signal of satellite peaks in a rigid lattice would be weak and nearly undetectable unless at low acceleration voltages. Multi-slice quantum mechanical electron diffraction simulation of a rigid 4.2°/4L/WS₂ structure indicates the relative intensities of satellite peaks to main peaks are less than 1% (FIG. 24)—lower than the threshold for TEM detection. The relative intensities measured experimentally are 1-2% (FIGS. 25A-25D).

While it would be feasible for the third order Bragg clusters to exhibit satellite peaks in a rigid lattice under lower beam energy, the fact satellite peaks can be detected in the first and second order Bragg clusters at all suggests that the lattice is not rigid. Direct evidence of atomic reconstruction is provided in the real-space dark field TEM images described above.

### Improving Assembled Stack Quality

The final structural quality and physical properties of the assembled heterostructure are determined by two aspects: (1) the initial structure and physical properties of the starting material and (2) how the structure and properties are affected by the stacking process. The goal is to maximize the starting material quality, and minimize the perturbation induced by patterning, assembly, and any subsequent fabrication processes. In the course of this Example, several factors which influence stack outcomes were identified: differential thermal expansion, polymer reflow, and excess mechanical force. It was found that by reducing differential thermal expansion by cooling the stamp while in contact with the target 2DM can lead to less wrinkling during the stamping process.

Source material quality plays an important role in the success of the stacking process. It is beneficial if the material is delaminable from the underlying substrate under vacuum. In this Example, MOCVD-synthesized and exfoliated 2DMs were focused on, but this technique is expected to be more generalizable. The yield of stacking is enhanced once a vdW material layer is on the stamp due to the tendency for strong interactions between 2D vdW materials. The presence of small bilayer regions does not seem to influence the yield of stacking.

The principle of material transfer during the stacking process is that the adhesive force between the sample and the stamp exceeds the force between the sample and the substrate. Highly conformal contact between the polymer stamp and the 2D layer, which maximizes the surface area for adhesive interactions, is advantageous. The primary mechanism of adhesion may involve non-covalent (i.e., van der Waals) interactions between the pendant groups of the PBzMA and the 2D layer. The benzyl groups are expected to be relatively non-polar but highly polarizable, which is well-suited to adhesion with 2D layers.

Differential thermal expansion can pose a significant problem when the stamp and sample change temperature while in contact, especially when this process is repeated cyclically. The stacking process described herein involves contact between a hot sample and a stamp that is typically near room temperature (because it is not actively heated). When the surfaces are pressed together, the stamp will expand significantly more than the 2D layer because the thermal expansion coefficients of typical polymers like PDMS and PMMA is ˜10-100 times the value of monolayer MoS₂. The expansion coefficient increases in a non-linear fashion near the polymer's glass transition temperature (T_{g}). The reflow of the adhesion layer interface will accommodate this strain somewhat but can lead to unpredictable wrinkling due to the soft interface when unconstrained or cooling down. Upon separation between the stamp and sample, the stamp will cool and contract. It will then be pressed into a hot sample again, resulting in another cycle of expansion followed by contraction. It is desirable to minimize these cycles.

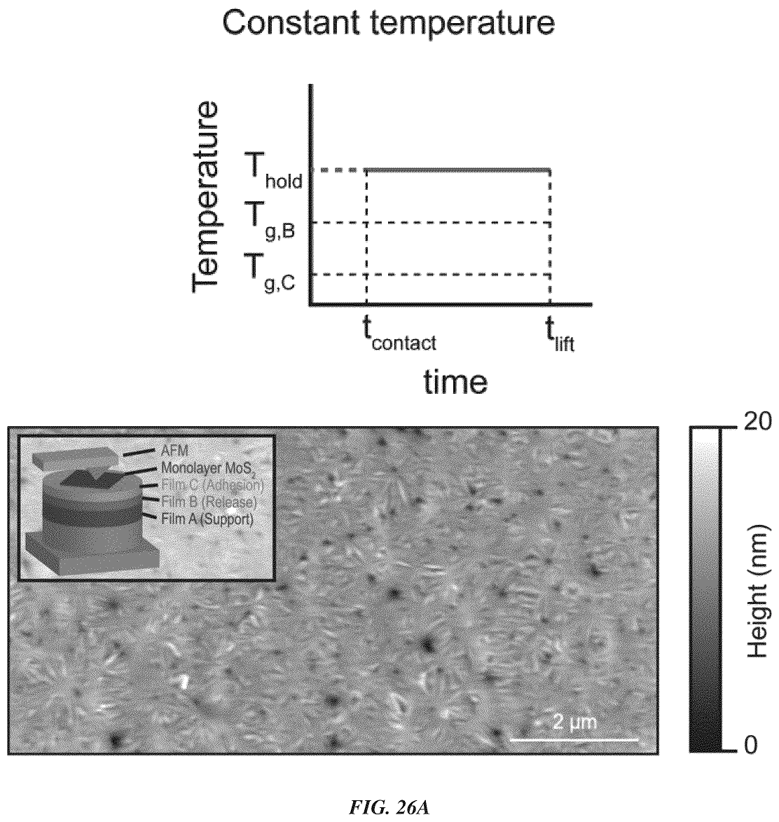

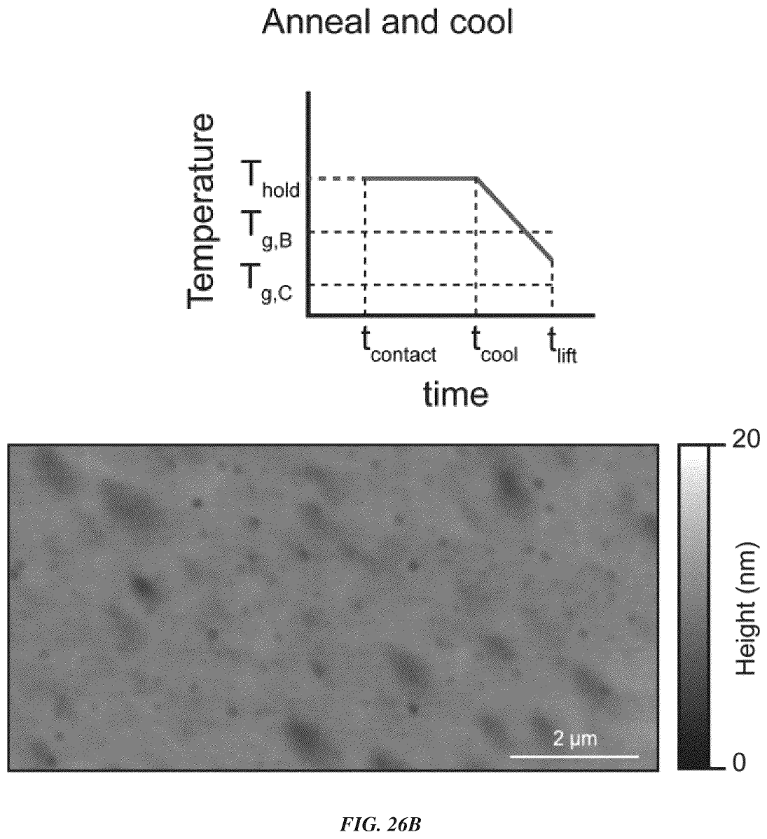

Consequently, there is a significant advantage to cooling the stamp below T_{g} before lifting the stamp and 2D stack from the substrate, to avoid both reflow and differential expansion/contraction deformations after the stamp has been lifted from the substrate. To achieve this, a thermoelectric cooler stage was added to the VAR (FIG. 11) to cool the stamp down faster while in contact with the target 2DM. FIGS. 26A-26B show that by modulating the temperature of the stamp during pick-up, the wrinkles observed in the monolayer films can be minimized. The flat rigid substrate constrains the 2DM and the cooling stamp to minimize thermal strain wrinkling and unintentional deformation. However, it was noted that it was still critical to begin contact of the stamp and 2DM at an elevated temperature >T_{g} to ensure that intimate conformal contact is made between the polymers stamp surface and the 2DM. It was found that stacking solely at the lower temperature would not yield successful pick-up.

It was also found that mechanical deformation induced by uneven contact and excessive force resulted in suboptimal stacking. Imprinting the stamp even 1 micrometer beyond initial color-detectable contact (FIG. 12B) begins to significantly decrease the quality of pick-up. This is especially important when scaling to larger areas stamps, such as for multiplexed assembly (FIGS. 27A-27C), since minor deviations to co-planar alignment between the stamp and sample will impart excessive force due to the uneven contact.

Common methods of assembling vdW heterostructures with exfoliated flakes use an hBN encapsulation layer. This approach yields several benefits beyond simply encapsulating the target heterostructure from the environment within a low-disorder dielectric. The primary benefit is avoiding contact between the active area and the polymer, which reduces disorder from polymer residues while simultaneously minimizing mechanical distortion by avoiding direct contact with the reflowing polymer layer. The thicker hBN flake is less compliant and therefore does not distort as easily. Adhesion of the polymer to the finite edge thickness of the hBN stack enables pick-up at lower temperatures, minimizing differential thermal expansion. Compatibility with this method is demonstrated in FIGS. 10A-10C and FIGS. 14A-14B. Extending this technique to wafer-scale heterostructure fabrication will require improvements in the quality and uniformity of thin-film hBN synthesis.

### Methods

### Wafer-Scale TMDs Synthesis.

Monolayer TMDs (MoS₂, WS₂, and WSe₂) were synthesized using MOCVD. Unless noted otherwise, samples are polycrystalline thin films, composed of complete monolayers or monolayers that are slightly overgrown (having some small bilayer regions nucleated at grain boundaries). Silicon wafers with 300 nm oxide were used as growth substrates. Material was verified to be continuous by atomic force microscopy prior to use.

### Template Strip Lithography (TSL) Patterning.

The majority of the TSL patterning in this Example used PDMS patterned blocks, with voids as the non-contact regions. The molds for casting PDMS TSL templates were fabricated through standard microfluidics techniques. SU8-3050 photoresist was spun coat on 3 inch silicon wafers, lithographically patterned, hard baked, and silanized with trimethylchlorosilane. PDMS (Sylgard-184) was then poured onto the SU8 molds and cured on a level surface for 2 days at room temperature.

For patterning MOCVD TMDs, a MOCVD growth wafer was first cleaved into ˜1 cm² chips. A PDMS TSL block was cut to roughly the same size as the chip cleaved for patterning, then gently placed onto the material such that the patterned relief faces towards the material. This structure was exposed to steam for 4-8 seconds, then immediately after, the TSL block was peeled off the chip. After peeling, the pattern transfers to the material. This method is extremely fast and the PDMS molds are reusable. This method was used for the samples in FIG. 6C (i), FIG. 6C (iii), and FIGS. 8A-8H.

Another method of TSL patterning may employ patterned Au thin films (non-adhesive) embedded in a PMMA thin film. This method was used for the samples shown in FIG. 6C (ii), FIG. 6C (iv), and FIG. 7C.

The patterning process is as follows: (i) utilize cleanroom photolithography to produce a flexible, structured template with an atomically-flat bottom surface and spatially patterned regions of strong adhesion, and (ii) apply this adhesive template to the 2D material to achieve uniform contact between the adhesion regions and the sample, then peel the template off. This results in the cleavage and removal of the 2D material within the adhesion regions, leaving behind layers of patterned material. The patterns in these templates were defined by the non-adhesion regions, voids, or inert materials, with negligible adhesion to 2DMs. In principle, the adhesive force can be tuned widely to accommodate various 2D/substrate combinations through the use of different polymers or the addition of intercalant species (e.g., H₂O).

### Polymer Stamp Fabrication.

The stamp was designed to modulate substrate-layer-stamp adhesion. Lift rate affects the viscoelastic response of the polymer stamp, which manifests as high adhesion when the stamp is lifted from the substrate quickly or low adhesion when peeled off slowly. Temperature dictates adhesion through polymer reflow when the glass transition is exceeded, or release when the decomposition temperature of the release layer is reached.

The stamp begins as a cylindrical PDMS base (50-800 micrometers in diameter) casted through a similar technique as the TSL patterns. A different PDMS formulation (MasterSil 971-LO) was used due to its low outgassing properties. The subsequent polymer layers were all applied to the casted and cured PDMS by spin coating at 2000 RPM for 1 minute.

Structural integrity was provided by a layer of MicroChem Lift-Off Resist (LOR10B). Its high glass transition temperature (190° C.) ensures physical rigidity during the assembly process. This layer improves the surface quality of assembled vdW heterostructures by reducing small-scale surface wrinkles.

The next polymer layer (PCPC-pag) was a polycarbonate derivative dissolved 6 wt % in anisole; additionally, there was 5% of PCPC mass of photoacid generator mixed in. The photoacid compound activates when exposed to either ultraviolet light or elevated temperatures (175° C.), thereby initiating degradation of the release layer and physically separating the two surrounding polymer layers.

The final layer was poly(benzyl methacrylate) (PBzMA), dissolved at 6 wt % in anisole. PBzMA has a low glass transition temperature (50° C.). The VAR operates above the PBzMA glass transition during heterostructure assembly, allowing this layer to relax into conformal contact when pressed against a targeted vdW material.

### Vacuum Assembly Robot (VAR) System Construction.

The vacuum chamber was built from modular components from Ideal Vacuum and the motorized navigation stages were assembled using Newport vacuum-compatible actuators and stages. A 2×-30× variable magnification microscope looks into the top viewport of the vacuum chamber. A vacuum-compatible resistive heater/thermoelectric cooler combination was used as a heating stage to provide fast and reproducible control over the sample temperature. Control over stage actuation, image acquisition, and system temperature was performed through LabView.

### General VAR Manufacturing Process.

Chips of source material were first patterned via TSL and imaged under an Olympus BX51, OLS 5000 LEXT (405 nm laser illumination), or DSX1000 microscope to confirm high-quality patterning before insertion into the VAR. Prior to assembly, the VAR was equipped with a polymer stamp, chips of patterned material, and a final transfer substrate. Then the system was pumped down to high vacuum. VAR assembly was executed as follows:
(1) Translation stage shifted to the user-programmed layer of patterned material.
(2) Imprint platform lowered the polymer stamp toward the targeted layer as an image processing algorithm ran over the in situ camera view (c.f., FIG. 7C (i) and FIG. 11).
(3) When the transparent stamp contacted the substrate, a change in color contrast was detected and the stamp approach was halted (FIG. 12B).
(4) Stamp was held in contact with the heated substrate (145° C.) for 60 seconds. During the hold period, the polymer adhesion layer relaxed into nanoscale conformal contact. Optionally, the stage temperature could be lowered to ˜T_{g} of the adhesion or release layers to reduce the deformation upon separation.
(5) Imprint platform rapidly shifted upward (100 micrometers at nominally 2000 micrometers/s) and the material was picked up from the substrate onto the stamp.
   This approach-hold-lift loop was executed for all layers programmed into the assembly instruction file. After heterostructure assembly was complete, the vdW solid was delaminated from the stamp onto a final transfer substrate. Various final substrates were used, including native oxide silicon, 300 nm silicon oxide, sapphire, and unpatterned MOCVD TMDs. The VAR executes a different operational protocol for final release:
(1) Stamp was brought into contact with the final substrate at the regular stacking temperature. This reduced thermal expansion mismatch at the onset of stamp contact.
(2) Translation stage was heated to 175° C. to activate the photoacid generator in the release layer (FIG. 7C(ii)).
(3) After 5 minutes, the release layer was sufficiently degraded, and the VAR slowly raised the stamp from the substrate (200 nm per second), transferring over the completed heterostructure.

### Post-Processing Manufactured Structures.

Completed structures from VAR manufacturing were solvent cleaned (acetone for 45 minutes, or chloroform for 10+ hours) to remove the remnant polymers from the heterostructure surface. Optionally, some were thermally annealed at 300° C. for >6 hours.

### Focused Ion Beam (FIB) 16-Tile Sample Cross-Section Preparation.

The 16-tile MoS₂ cross-sections were prepared using a Thermo Fisher Helios G4 UX Focused Ion Beam (FIB). The sample chip was positioned such that cross-sections could be cut perpendicular to boundaries between squares of different MoS₂ layer numbers. Protective layers of carbon (˜200 nm) and platinum (˜1 μm) were deposited on the squares expected to have 4, 8, and 15 MoS₂ layers. Cross-sections were milled from these regions at a 90-degree angle from the sample using a Ga ion beam at 30 kV. The cross-sections were then further polished to electron beam transparency with the ion beam at 5 kV.

### Scanning Transmission Electron Microscopy (STEM) 16-Tile Sample Cross-Section Imaging.

The cross-sections were imaged in a Thermo Scientific Titan Themis STEM at 120 kV with a probe convergence angle of 21.4 mrad. The high-angle annular dark field (HAADF) images show bright bands corresponding to the MoS₂ layers and confirm that the vacuum-assembly technique produced clean stacking and correct layer number in each of the three (4L, 8L, 15L MoS₂) cross-sectional samples. All images were analyzed using the open-source software Cornell Spectrum Imager.

### Optical Photoluminescence, Raman, and Hyperspectral Transmittance/Reflectance Microscopy Measurements.

The vdW solids were initially transferred via VAR onto a monolayer MOCVD MoS₂ on 300 micrometers SiO₂/Si substrate. Photoluminescence (PL) of the 16 tile (FIGS. 8A-8H) was taken on a HORIBA LabRAM HR Evolution Confocal Raman Microscope using a 532 nm laser. A 50× objective was used, which roughly had a 2 micrometers laser spot size. On the 16-tile structure, a PL map was taken with a x-y step size of 12.5 micrometers so that each tile position had 4 spectra taken, and the monolayer region had 8 spectra taken. Spectra were taken at room temperature under at 0.5 mW for 2 acquisitions and 1.2 seconds with a grating of 600 lines/mm. Voigt distributions with a zero background were used to fit the A and B peaks.

For Raman mapping (FIGS. 19A-19F), the MoS₂/WSe₂ heterostructure and monolayer references were illuminated under a 532 nm laser at 0.25 mW. Spectra were acquired using the 100× objective with a grating of 1800 lines/mm. Acquisition time per spectra was 1.5 seconds, resulting in 30-40 minutes for each complete map. A flat noise baseline was subtracted from each individual spectrum, and the integrated area of the respective peaks were used in coloring the Raman map, normalized such that the min/max value for each channel were assigned to min/max color intensity respectively.

For hyperspectral microscopy, the 16-tile structure was transferred onto a 330 micrometers double-side polished sapphire substrate by first being spin coated with PMMA, then etched in 1M KOH to remove the vdW solid from the Si, relocated onto water, and controllably water-drain-transferred onto sapphire. The hyperspectral microscope was built with similar specifications to prior work, but with slightly modified reflection and transmission objectives for higher resolution. The light source was a Xe bulb and filtered by a monochromator, within a 4 nm spectral resolution. A parallel photodiode was used to monitor the time-dependent Xe signal fluctuation. The photodiode data was used to normalize the signal during separate spectrum acquisitions. The 2D imaging detector was an Andor iXon+ 885 EMCCD.

Both reflection and transmission were taken with the sample facing incident light, meaning the sample had to be flipped over between the two imaging modes. A bare sapphire substrate spectrum was also taken in order to extract this optical constant. Transmission in air without the sample, reflection by a silver mirror, and background signals without illumination were taken as the max transmission, max reflection, and noise level, respectively. Images for each wavelength were first subtracted by the background dark signal, then transformed into transmittance and reflectance by dividing by the max transmission and max reflection images respectively.

Absorption was calculated as:

A=−T₀(dT)−R₀(dR)

where T₀ is defined as T_{substrate}/Tₐᵢᵣ, R₀ is R_{substrate}/Rₘᵢᵣᵣₒᵣ, dT is the differential transmission of the sample as (Tₛₐₘₚₗₑ−T_{substrate})/T_{substrate} and dR is the differential reflection as (Rₛₐₘₚₗₑ−R_{substrate})/R_{substrate}. The A and B peaks were fit in the 552 nm (2.25 eV) to 708 nm (1.75 eV) range, with a slanted background on two Voigt distributions for the two peaks.

### Transfer Matrix Method Calculation of Optical Response.

The transfer matrix method (TMM) data was calculated using an air-sample-substrate-air system for direct comparison to the experimental data (FIG. 20). The sample portion was treated as individual monolayers (e.g. 3L-MoS₂ region in the 16-tile=1L-MoS₂+1L-MoS₂+1L-MoS₂).

The optical constant of the 330 micron sapphire substrate was extracted by an inverse-TMM-solver. This showed a minor wavelength dependence due to slight chromatic aberration in the microscope reflectivity at low wavelengths (400-450 nm). The extracted wavelength-dependent sapphire optical constant was then used for the substrate in the T and R TMM calculation.

2D materials isolated by different methods will display variations in their complex optical constants because of differing synthesis or processing methodologies. Variation in n and k can be as much as ±25% comparing the values in currently published work. The optical constant used for the MoS₂ for the TMM calculation from published work. A constant prefactor was applied to the n and k values to calibrate for sample variation between the synthesis described herein and the material used in the reference. The optimal result for matching the monolayer MoS₂ T and R to that of the published reference came from multiplying n by 0.85 and k by 0.70. All TMM code was implemented in MATLAB.

Twisted 4L WS₂ Fabrication.

Large, randomly oriented single crystals of WS₂ were synthesized via MOCVD on Si/SiO₂ substrates. Growth substrates were cleaved into ˜1 cm² chips and mounted in the VAR without any TSL patterning. The stamp was used to pick out sub-sections from a large single crystal, with identical numbers of θ-actuator steps taken between layers. The VAR was run in the operator-assisted mode for twisted N-layer fabrication. After picking up all layers, the structure was transferred onto a silicon substrate with 300 nm oxide for inspection. Without further post-processing, the final substrate was spun coat with PMMA, floated in 1M KOH, and transferred onto a 1 μm holey carbon/copper TEM grid. The TEM grid was then solvent cleaned in acetone to remove all polymer.

### Transmission Electron Microscopy for Twisted 4L WS₂.

Dark-field transmission electron microscopy (DF-TEM) and selected area electron diffraction (SAED) of the twisted 4 layer WS₂ sample were performed on TFS Talos (operated at 200 keV) equipped with Gatan OneView Camera. DF-TEM images were formed by placing an objective aperture around the optic axis and tilting beam to achieve two-beam conditions around diffraction peaks of interest.

### Thin Film Source Sample Preparation

Au thin films 20 nm thick were deposited in an AJA-Orion 8E electron beam evaporation system onto native oxide-coated Si wafers.

### Exfoliated Sample Preparation and Cryogenic Photoluminescence Measurements.

Exfoliated flakes of kish graphite, hBN (HQGraphene), and WSe₂ (2D Semiconductors) were deposited onto Si/SiO₂ substrates. For the cryogenic experiment, the source flakes were inserted into the VAR and an hBN/WSe₂/hBN stack was fabricated. The sample was subsequently cleaned of polymer residue via solvent washing and thermal annealing and inserted into a closed cycle optical cryostat for measurement at 7 K. For the PL measurements, the sample was excited above band gap with a diffraction-limited 518 nm pump with power ˜2 μW. For the differential reflectivity measurements, a broadband LED light source was used to measure dR=RWSe₂/R_{hBN}−1, where RWSe₂ (R_{hBN}) is the reflection from the heterostructure collected within (outside) the monolayer region.

### Confocal Laser Scanning Microscopy

An Olympus OLS 5000 LEXT was used to acquire the images for confocal laser scanning microscopy in FIGS. 18A-18D. The 20× objective was used for the low magnification white light image and the 100× objective was used for the high magnification white light image and confocal intensity image. The brightness setting was kept constant for the intensity images. (30 micrometers)² square ROIs centered in the middle of each intensity image was used to create the histograms for the plot in FIG. 18D.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present invention.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

As used herein, “wt %” is an abbreviation of weight percentage. As used herein, “at %” is an abbreviation of atomic percentage.

Some embodiments may be embodied as a method, of which various examples have been described. The acts performed as part of the methods may be ordered in any suitable way. Accordingly, embodiments may be constructed in which acts are performed in an order different than illustrated, which may include different (e.g., more or less) acts than those that are described, and/or that may involve performing some acts simultaneously, even though the acts are shown as being performed sequentially in the embodiments specifically described above.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

It should be understood that when a portion (e.g., layer, structure, region, etc.) is “on,” “adjacent,” “above,” “over,” “overlying,” or “supported by” another portion, it can be directly on the portion, or an intervening portion (e.g., layer, structure, region) may also be present. Similarly, when a portion is “below” or “underneath” another portion, it can be directly below the portion, or an intervening portion (e.g., layer, structure, region) may also be present. A portion that is “directly adjacent,” “directly on,” “immediately adjacent,” “in contact with,” or “directly supported by” another portion means that no intervening portion is present. It should also be understood that when a portion is referred to as being “on,” “above,” “adjacent,” “over,” “overlying,” “in contact with,” “below,” or “supported by” another portion, it may cover the entire portion or a part of the portion.

In the claims, as well as in the specification above, all transitional phrases such as “comprising,” “including,” “carrying,” “having,” “containing,” “involving,” “holding,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A multi-layer stack, comprising:
a first crystalline layer;
a second crystalline layer; and
at least eight intermediate crystalline layers between the first crystalline layer and the second crystalline layer;
wherein:
the first crystalline layer is substantially non-covalently associated with the intermediate crystalline layer in the stack that is adjacent to the first crystalline layer;
the second crystalline layer is substantially non-covalently associated with the crystalline intermediate layer in the stack that is adjacent to the second crystalline layer; and
each intermediate crystalline layer is substantially non-covalently associated with the two crystalline layers of the stack that are adjacent to that intermediate crystalline layer.

2. The multi-layer stack of claim 1, wherein at least a portion of the layers within the multi-layer stack form a multilayer moiré superlattice.

3. The multi-layer stack of claim 1, wherein each of the crystalline layers in the stack has a facial area and has less than or equal to 1×10¹¹ through-thickness defects per cm² of the facial area.

4. The multi-layer stack of claim 1, wherein each of the crystalline layers in the stack has a thickness of less than or equal to 10 micrometers.

5. The multi-layer stack of claim 1, wherein:
the first crystalline layer is a single-crystalline layer; and/or
the second crystallin layer is a single-crystalline layer; and/or
the eight intermediate crystalline layers are single-crystalline layers.

6. The multi-layer stack of claim 1, wherein:
the first crystalline layer is separable from the intermediate crystalline layer in the stack that is adjacent to the first crystalline layer; and/or
the second crystalline layer is separable from the crystalline intermediate layer in the stack that is adjacent to the second crystalline layer; and/or
each intermediate crystalline layer is separable from the two crystalline layers of the stack that are adjacent to that intermediate crystalline layer.

7. The multi-layer stack of claim 1, wherein each intermediate crystalline layer is adhered to at least one adjacent intermediate crystalline layer via van der Waals interactions.

8. The multi-layer stack of claim 1, wherein:
the first crystalline layer is in direct contact with at least one of the intermediate crystalline layers; and/or
each of the intermediate crystalline layers is in direct contact with at least two of the crystalline layers of the stack; and/or
the second crystalline layer is in direct contact with at least one of the intermediate crystalline layers.

9. The multi-layer stack of claim 1, wherein each of the first crystalline layer, the second crystalline layer, and the intermediate crystalline layers comprises a two-dimensional (2D) material.

10. The multi-layer stack of claim 1, wherein at least one of the crystalline layers comprises a transition metal dichalcogenide, graphene, and/or hexagonal boron nitride.

11. The multi-layer stack of claim 1, wherein at least one of the crystalline layers comprises a metal.

12. The multi-layer stack of claim 1, wherein at least one of the crystalline layers comprises an evaporated thin film.

13. The multi-layer stack of claim 1, wherein each of the crystalline layers has at least one lateral dimension of at least 10 micrometers.

14. The multi-layer stack of claim 1, wherein each of the crystalline layers has a facial surface area of at least 100 square micrometers.

15. The multi-layer stack of claim 1, wherein the multi-layer stack comprises at least 23 intermediate crystalline layers.

16. The multi-layer stack of claim 1, wherein at least one of the intermediate crystalline layers in the multi-layer stack has a facial surface area that is less than or equal to 75% of the largest facial surface area of the crystalline layers within the multi-layer stack.

17. The multi-layer stack of claim 1, wherein edges of at least two adjacent crystalline layers within the multi-layer stack are aligned within 3° of parallel.

18. The multi-layer stack of claim 1, wherein:
the multi-layer stack has a common angle of rotation among the edges of the intermediate crystalline layers; and
for each of the intermediate crystalline layers, an edge of the intermediate crystalline layer is arranged such that:
the edge of the intermediate crystalline layer is within 3° of the common angle of rotation relative to the corresponding edge of a crystalline layer that is adjacent to and on a first side of the intermediate crystalline layer; and
the edge of the intermediate crystalline layer is within 3° of the common angle of rotation relative to the corresponding edge of a crystalline layer that is adjacent to and on a second side, opposite the first side, of the intermediate crystalline layer.

19. The multi-layer stack of claim 1, wherein each of the crystalline layers in the multi-layer stack has the same chemical composition.

20-21. (canceled)

22. A method of making a multi-layer stack using an article comprising an adhesion region, an article substrate, and a release region between the adhesion region and the article substrate, the method comprising:
establishing contact between the adhesion region of the article and a first crystalline layer such that the first crystalline layer is adhered to the adhesion region of the article;
subsequently establishing contact between the first crystalline layer and a second crystalline layer while the first crystalline layer remains adhered to the article, such that the second crystalline layer is adhered to the first crystalline layer;
subsequently establishing contact between the second crystalline layer and a third crystalline layer while the first and second crystalline layers remain adhered to the article, such that the third crystalline layer is adhered to the second crystalline layer; and
subsequently altering the release region such that separation is achieved between the article substrate and the first, second, and third crystalline layers.

23-44. (canceled)
